(19) United States
(12) Patent Application Publication
(10) Pub. No.: US 2015/0034915 A1
(43) Pub. Date: Feb. 5, 2015

(54) ORGANIC LIGHT-EMITTING DEVICE

(71) Applicant: Samsung Display Co., Ltd., Yongin-City (KR)

(72) Inventors: Myeong-Suk Kim, Yongin-City (KR); Sung-Wook Kim, Yongin-City (KR); Jae-Hong Kim, Yongin-City (KR); Chang-Woong Chu, Yongin-City (KR); Sam-Il Kho, Yongin-City (KR); Ja-Hyun Im, Yongin-City (KR)

(73) Assignee: Samsung Display Co., Ltd., Yongin-City (KR)

(21) Appl. No.: 14/210,424

(22) Filed: Mar. 13, 2014

(30) Foreign Application Priority Data
Jul. 30, 2013 (KR) 10-2013-0090428

(51) Int. Cl. H01L 51/00; H01L 51/50

(52) U.S. Cl. CPC H01L 51/0072; H01L 51/50
USPC 257/40

(57) ABSTRACT

An organic light-emitting device includes a first electrode, a second electrode, and an organic layer interposed between the first electrode and the second electrode, wherein the organic layer includes an emission layer, the emission layer includes a compound represented by Formula 2 below, and a second layer including a heterocyclic compound represented by Formula 1 below either between the emission layer and the first electrode or between the emission layer and the second electrode.

Formula 1 and Formula 2 are defined in the same manner as described in the detailed description.

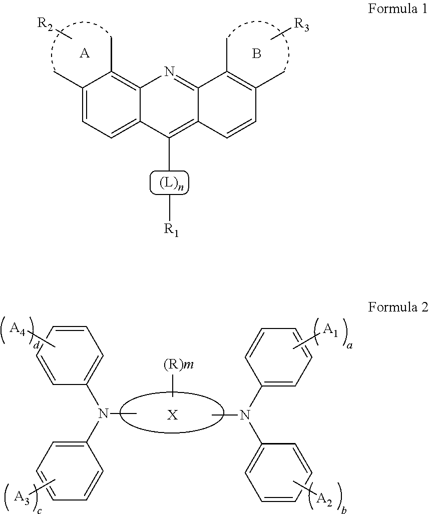

### CROSS-REFERENCE TO RELATED APPLICATION

This application claims priority to and the benefit of Korean Patent Application No. 10-2013-0090428, filed on Jul. 30, 2013, in the Korean Intellectual Property Office, the disclosure of which is incorporated herein in its entirety by reference.

### BACKGROUND

1. Field

One or more embodiments of the present invention relate to an organic light-emitting device.

2. Description of the Related Art

Organic light-emitting devices (OLEDs), which include self-emitting diodes, have advantages such as wide viewing angles, excellent contrast, quick response, high brightness, excellent driving voltage, or providing full color images.

A typical OLED has a structure including a substrate, and an anode, a hole transport layer, an emission layer, an electron transport layer, and a cathode which are sequentially stacked on the substrate. The hole transport layer, the emission layer, and the electron transport layer are organic thin films formed of organic compounds.

A driving principle of an organic light-emitting diode having such a structure is described below.

When a voltage is applied between the anode and the cathode, holes injected from the anode pass the hole transport layer and migrate toward the emission layer, and electrons injected from the cathode pass the electron transport layer and migrate toward the emission layer. The holes and the electrons are recombined with each other in the emission layer to generate excitons. Then, the excitons are transitioned from an excited state to a ground state, thereby generating light.

There is a need to develop a material that has excellent electrical stability, high charge transport capability or luminescent capability, high glass transition temperature, and high crystallization prevention capability (e.g., being highly amorphous), compared to an organic material (e.g., a small molecule organic material) according to the related art.

### SUMMARY

One or more embodiments of the present invention relate to a material that has excellent electric characteristics, a high charge transporting capability, a high light-emitting capability, a high glass transition temperature, and a crystallization-preventing capability, and that is suitable for use as an electron transporting material for a full color, such as red, green, blue, or white, of fluorescent and phosphorescent devices; and an organic light-emitting device that has high efficiency, low driving voltage, high brightness, long lifespan due to the inclusion of the material.

Additional aspects will be set forth in part in the description which follows and, in part, will be apparent from the description, or may be learned by practice of the presented embodiments.

According to an embodiment of the present invention, an organic light-emitting device includes: a first electrode; a second electrode; and an organic layer between the first electrode and the second electrode, wherein the organic layer includes an emission layer, the emission layer includes a compound represented by Formula 2 below; and a second layer (e.g., an electron transport layer) including a heterocyclic compound represented by Formula 1 below either between the emission layer and the first electrode or between the emission layer and the second electrode:

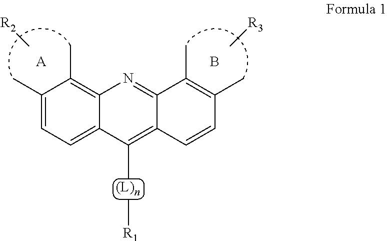

wherein in Formula 1,

R₁ to R₃ are each independently a hydrogen atom, a deuterium atom, a halogen atom, a cyano group, a substituted or unsubstituted C₁-C₆₀ alkyl group, a substituted or unsubstituted C₆-C₆₀ aryl group, a substituted or unsubstituted C₂-C₆₀ heteroaryl group, or a substituted or unsubstituted C₆-C₆₀ condensation polycyclic group;

L is a substituted or unsubstituted C₆-C₆₀ arylene group or a substituted or unsubstituted C₂-C₆₀ heteroarylene group;

n is an integer of 0 to 3; and

A and B are each independently a substituted or unsubstituted C₆-C₆₀ aryl group or a substituted or unsubstituted C₂-C₆₀ heteroaryl group, each of which is fused to the back bone of Formula 1.

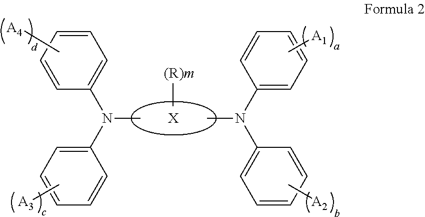

wherein in Formula 2,

A₁ to A₄ and R are each independently a hydrogen atom, a deuterium atom, a cyano group, a halogen atom, a substituted silyl group, a substituted or unsubstituted C₁-C₆₀ alkyl group, a substituted or unsubstituted C₆-C₆₀ aryl group, or a substituted or unsubstituted C₃-C₆₀ cycloalkyl group;

X is a substituted or unsubstituted C₆-C₆₀ arylene group, or a substituted or unsubstituted C₂-C₆₀ heteroarylene group;

a, b, c, d and m are each independently an integer of 1-10.

According to another embodiment of the present invention, a flat panel display apparatus includes the organic light-emitting device, wherein the first electrode of the organic light-emitting device is electrically connected to a source electrode or drain electrode of a thin film transistor.

### BRIEF DESCRIPTION OF THE DRAWINGS

These and/or other aspects will become apparent and more readily appreciated from the following description of the embodiments, taken in conjunction with the accompanying drawings of which:

FIG. 1 is a schematic view of an organic light-emitting device according to an embodiment of the present invention; and

FIG. 2 is a graph showing luminance versus time of organic light-emitting devices manufactured according to Example 1 and Comparative Example 1.

### DETAILED DESCRIPTION

Reference will now be made in more detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description. Expressions such as “at least one of,” when preceding a list of elements, modify the entire list of elements and do not modify the individual elements of the list. Further, the use of “may” when describing embodiments of the present invention refers to “one or more embodiments of the present invention.”

An organic light-emitting device according to an embodiment of the present invention includes: a first electrode; a second electrode; and an organic layer interposed between the first electrode and the second electrode, wherein the organic layer includes an emission layer including a compound represented by Formula 2 below, and a second layer (e.g., an electron transport layer) including a heterocyclic compound represented by Formula 1 below between the emission layer and the first electrode, or between the emission layer and the second electrode:

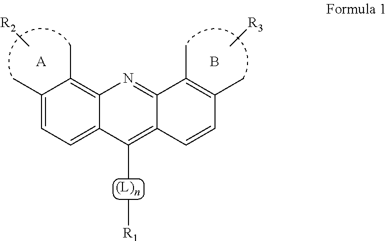

In Formula 1,

R₁ to R₃ are each independently a hydrogen atom, a deuterium atom, a halogen atom, a cyano group, a substituted or unsubstituted C₁-C₆₀ alkyl group, a substituted or unsubstituted C₆-C₆₀ aryl group, a substituted or unsubstituted C₂-C₆₀ heteroaryl group, or a substituted or unsubstituted C₆-C₆₀ condensation polycyclic group;

L is a substituted or unsubstituted C₆-C₆₀ arylene group or a substituted or unsubstituted C₂-C₆₀ heteroarylene group;

n is an integer of 0 to 3; and

A and B are each independently a substituted or unsubstituted C₆-C₆₀ aryl group or a substituted or unsubstituted C₂-C₆₀ heteroaryl group, each of which is fused to the back bone of Formula 1.

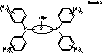

In Formula 2,

A₁ to A₄ and R are each independently a hydrogen atom, a deuterium atom, a cyano group, a halogen atom, a substituted silyl group, a substituted or unsubstituted C₁-C₆₀ alkyl group, a substituted or unsubstituted C₆-C₆₀ aryl group, or a substituted or unsubstituted C₃-C₆₀ cycloalkyl group;

X is a substituted or unsubstituted C₆-C₆₀ arylene group, or a substituted or unsubstituted C₂-C₆₀ heteroarylene group; and

a, b, c, d and m are each independently an integer of 1-10.

The compound of Formula 1 according to an embodiment of the present invention is used as a material for an electron injection layer, an electron transport layer, or a functional layer having both an electron injection capability and an electron transport capability for an organic light-emitting device. Also, the compound of Formula 1 has high glass transition temperature Tg or high melting point due to the introduction of a hetero-ring. Accordingly, a heat resistance against Joule's heat that occurs within an organic layer, between organic layers, or between an organic layer and a metal electrode during emission is improved, and durability under high temperature is also improved. Accordingly, an organic light-emitting device manufactured by using the compound has high durability during preservation (or storage) or driving.

Hereinafter, substituents of the compound of Formula 1 are described in more detail.

According to an embodiment of the present invention, A and B in Formula 1 may be each independently a substituted or unsubstituted phenyl group, a substituted or unsubstituted naphthyl group, or a substituted or unsubstituted pyridine.

According to another embodiment of the present invention, the substituted or unsubstituted naphthyl group may be fused with the back bone of Formula 1 at site 2 and site 3 of Formula 1-1 below:

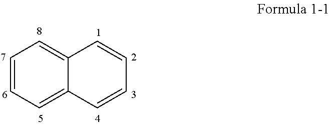

According to another embodiment of the present invention, the substituted or unsubstituted pyridine in Formula 1 may be fused with the back bone of Formula 1 at sites 2 and 3 of Formula 1-2:

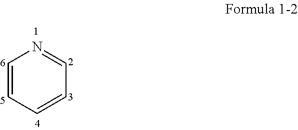

Formulae 1-1 and 1-2 are used to explain where A and B are fused with the back bone of Formula 1, and in Formulae 1-1 and 1-2, substituents are not illustrated.

According to another embodiment of the present invention, R₂ and R₃ in Formula 1 may be each independently a hydrogen atom, a deuterium atom, or Formula 2a below:

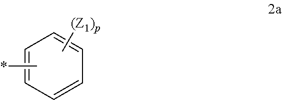

In in Formula 2a, Z₁ is a hydrogen atom, a deuterium atom, a substituted or unsubstituted C₁-C₂₀ alkyl group, a substituted or unsubstituted C₆-C₂₀ aryl group, a substituted or unsubstituted C₂-C₂₀ heteroaryl group, a substituted or unsubstituted C₆-C₂₀ condensed polycyclic group, an amino group substituted with a C₆-C₂₀ aryl group or a C₃-C₂₀ heteroaryl group, a halogen atom, a cyano group, a nitro group, a hydroxyl group, or a carboxy group; p is an integer of 1 to 5; and * indicates a binding site.

According to another embodiment of the present invention, L may be a phenylene group or a pyridine group.

According to another embodiment of the present invention, R₁ may be a hydrogen atom, a deuterium atom, or any one of Formulae 3a to 3g below:

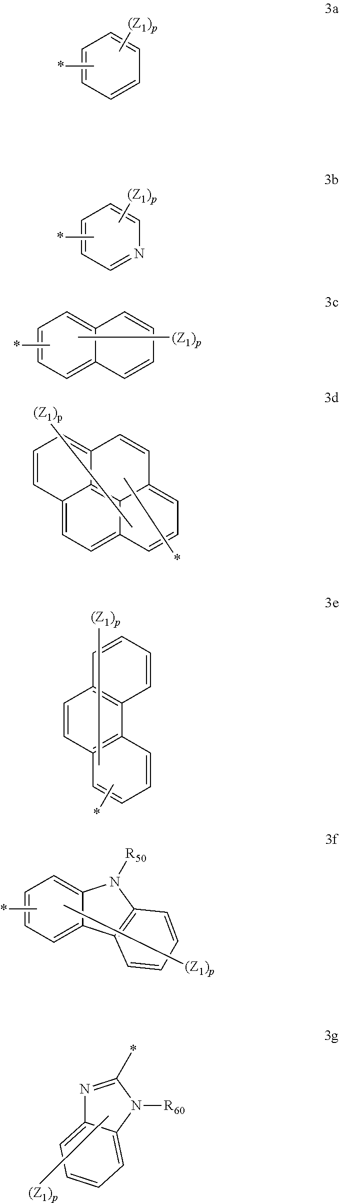

In Formulae 3a to 3g,

Z₁, R₅₀ and R₆₀ are each independently a hydrogen atom, a deuterium atom, a substituted or unsubstituted C₁-C₂₀ alkyl group, a substituted or unsubstituted C₆-C₂₀ aryl group, a substituted or unsubstituted C₆₀-C₂₀ heteroaryl group, a substituted or unsubstituted C₆-C₂₀ condensed polycyclic group, an amino group substituted with a C₆-C₂₀ aryl group or a C₂-C₂₀ heteroaryl group, a halogen atom, a cyano group, a nitro group, a hydroxyl group, or a carboxy group; p is an integer of 1 to 9; and * indicates a binding site.

According to another embodiment of the present invention, R₁ may be represented by Formula 3 below:

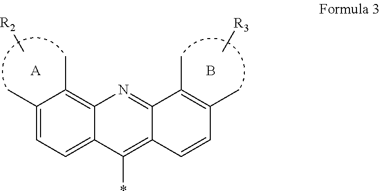

A, B, and R₂-R₃ in Formula 3 are the same as described above.

According to another embodiment of the present invention, X in Formula 2 may be a substituted or unsubstituted pyrene, a substituted or unsubstituted anthracene, a substituted or unsubstituted phenanthroline, a substituted or unsubstituted benzopyrene, or a substituted or unsubstituted chrysene.

According to another embodiment of the present invention, A₁ to A₄ and R in Formula 2 may be each independently a hydrogen atom, a deuterium atom, a halogen atom, a substituted silyl group, a substituted or unsubstituted C₁-C₆₀ alkyl group, a substituted or unsubstituted C₆-C₆₀ aryl group, a substituted or unsubstituted C₂-C₆₀ heteroaryl, or a substituted or unsubstituted C₆-C₆₀ condensation polycyclic group.

According to another embodiment of the present invention, at least one of A₁ to A₄ in Formula 2 may be represented by Formula 4 below:

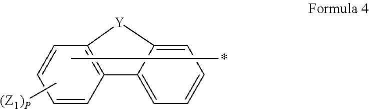

In Formula 4,

Y indicates NR₁₁, —O—, or —S—; Z₁ and R₁₁ are each independently a hydrogen atom, a deuterium atom, a cyano group, a halogen atom, a substituted or unsubstituted C₁-C₄₀ alkyl group, a substituted or unsubstituted C₆-C₄₀ aryl group, or a substituted or unsubstituted C₃-C₄₀ cycloalkyl group; and p is an integer of 1 to 7, and when the number of Z₁ is 2 or more, a plurality of Z₁ may be different from or identical to each other; and

* indicates a binding site.

Hereinafter, example (e.g., representative) substituents from among substituents used in the present specification will be described as follows. The number of carbon atoms in each substituent is non-limiting, and does not limit characteristics of the substituents.

The unsubstituted C₁ to C₆₀ alkyl group used herein may be a linear or branched alkyl group, and non-limiting examples thereof are a methyl group, an ethyl group, a propyl group, an isobutyl group, a sec-butyl group, a pentyl group, an iso-amyl group, a hexyl group, a heptyl, an octyl, a nonyl, and a dodecyl. At least one hydrogen atom of the alkyl group may be substituted with a deuterium atom, a halogen group, a hydroxyl group, a nitro group, a cyano group, an amino group, an amidino group, a hydrazine, a hydrazone, a carboxyl group or a salt thereof, a sulfonic acid or a salt thereof, a phosphoric acid or a salt thereof, a C₁ to C₁₀ alkyl group, a C₁ to C₁₀ alkoxy group, a C₂ to C₁₀ alkenyl group, a C₂ to C₁₀ alkynyl group, a C₆ to C₁₆ aryl group, or a C₄ to C₁₆ heteroaryl group.

The unsubstituted C₂ to C₆₀ alkenyl group used herein refers to an unsubstituted alkyl group having one or more carbon double bonds at a center or end thereof. Examples thereof are ethenyl, propenyl, and butenyl. At least one hydrogen atom of the unsubstituted alkenyl group may be substituted with the same substituents as described in connection with the substituted alkyl group.

The unsubstituted C₂ to C₆₀ alkynyl group used herein refers to an unsubstituted alkyl group having one or more carbon triple bonds at a center or end thereof. Examples thereof are acetylene (or ethynyl), propynyl, phenylacetylene, naphthylacetylene, isopropylacetylene, t-butylacetylene, and diphenylacetylene. At least one hydrogen atom of these alkynyl groups may be substituted with the same substituents as described in connection with the substituted alkyl group.

The unsubstituted C₃ to C₆₀ cycloalkyl group used herein refers to a C₃ to C₆₀ cyclic alkyl group. At least one hydrogen atom of the cycloalkyl group may be substituted with the same substituents as described in connection with the C₁ to C₆₀ alkyl group.

The unsubstituted C₁ to C₆₀ alkoxy group used herein refers to a group having —OA (wherein A is the unsubstituted C₁ to C₆₀ alkyl group), and non-limiting examples thereof are ethoxy, isopropoxy, butoxy, and pentoxy. At least one hydrogen atom of the unsubstituted alkoxy group may be substituted with the same substituents as described in connection with the alkyl group.

The unsubstituted C₆ to C₆₀ aryl group used herein refers to a carbocyclic aromatic system having at least one aromatic ring, and when the number of rings is two or more, the rings may be fused to each other or may be linked to each other via, for example, a single bond. The term ‘aryl’ includes an aromatic system, such as phenyl, naphthyl, or anthracenyl. Also, at least one hydrogen atom of the aryl group may be substituted with the same substituents described in connection with the C₁ to C₆₀ alkyl group.

Examples of a substituted or unsubstituted C₆ to C₆₀ aryl group are a phenyl group, a C₁ to C₁₀ alkylphenyl group (for example, an ethylphenyl group), a halophenyl group (for example, o-, m- and p-fluorophenyl groups, or a dichlorophenyl group), a cyanophenyl group, a dicyanophenyl group, a trifluoromethoxyphenyl group, a biphenyl group, a halobiphenyl group, a cyanobiphenyl group, a C₁ to C₁₀ alkylbiphenyl group, a C₁ to C₁₀ akoxybiphenyl group, o-, m-, and p-tolyl groups, o-, m- and p-cumenyl groups, a mesityl group, a phenoxyphenyl group, a (α,α-dimethylbenzene)phenyl group, a (N,N′-dimethyl)aminophenyl group, a (N,N′-diphenyl)aminophenyl group, a pentalenyl group, an indenyl group, a naphthyl group, a halonaphthyl group (for example, a fluoronaphthyl group), a C₁ to C₁₀ alkylnaphthyl group (for example, methylnaphthyl group), a C₁ to C₁₀ akoxynaphthyl group (for example, methoxynaphthyl group), an anthracenyl group, an azrenyl group, a heptalenyl group, an acenaphthylenyl group, a phenalenyl group, a fluorenyl group, an anthraquinolinyl group, a methylan anthryl group, a phenanthryl group, a triphenylenyl group, a pyrenyl group, a chrysenyl group, an ethyl-chrysenyl group, a picenyl group, a perylenyl group, a chloroperylenyl group, a pentaphenyl group, a pentasenyl group, a tetraphenylenyl group, a hexaphenyl group, a hexacenyl group, a rubicenyl group, a coroneryl group, trinaphthylenyl group, a heptaphenyl group, a heptacenyl group, a piranthrenyl group, and an obarenyl group.

The unsubstituted C₂-C₆₀ heteroaryl group used herein includes at least one hetero atom selected from nitrogen (N), oxygen (O), phosphorous (P), or sulfur (S), and when the group has two or more rings, the rings may be fused to each other or may be linked to each other via, for example, a single bond. Examples of the unsubstituted C₂-C₆₀ heteroaryl group are a pyrazolyl group, an imidazolyl group, a oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, and a dibenzothiophene group. Also, at least one hydrogen atom of the heteroaryl may be substituted with the same substituents described in connection with the C₁ to C₆₀ alkyl group.

The unsubstituted C₆ to C₆₀ aryloxy group used herein refers to a group represented by —OA₁, wherein A₁ is the C₆ to C₆₀ aryl group. An example of the aryloxy group is a phenoxy group. Also, at least one hydrogen atom of the aryloxy group may be substituted with the same substituents described in connection with the C₁ to C₆₀ alkyl group.

The unsubstituted C₆ to C₆₀ arylthio group used herein refers to a group represented by —SA₁, wherein A₁ is the C₆ to C₆₀ aryl group. Examples of the arylthio group are a benzenethio group and a naphthylthio group. At least one hydrogen atom of the arylthio group may be substituted with the same substituents described in connection with the C₁ to C₆₀ alkyl group.

The unsubstituted C₆ to C₆₀ condensed polycyclic group used herein refers to a substituent having two or more rings formed by fusing at least one aromatic ring and at least one non-aromatic ring, or a substituent in which a unsaturated group is present in a ring but a conjugated system does not exist, and the condensed polycyclic group overall does not have an orientation, which is how the condensed polycyclic group is distinguished from the aryl group or the heteroaryl group.

Detailed examples of the compound represented by Formula 1 are compounds illustrated below, but are not limited thereto.

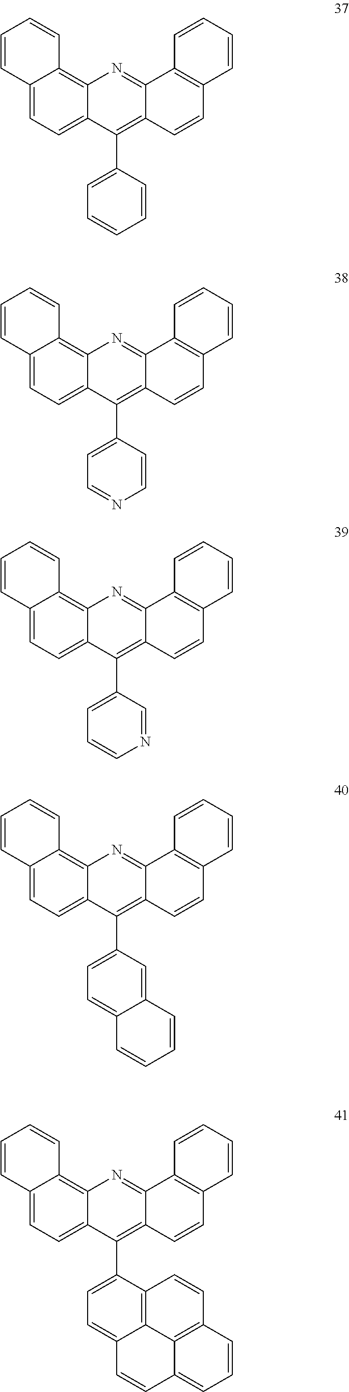 [SMILES: c1ccc(-c2c3ccc4ccccc4c3nc3c2ccc2ccccc23)cc1 ; c1ccc2c(c1)ccc1c(-c3ccncc3)c3ccc4ccccc4c3nc12 ; c1cncc(-c2c3ccc4ccccc4c3nc3c2ccc2ccccc23)c1 ; c1ccc2cc(-c3c4ccc5ccccc5c4nc4c3ccc3ccccc34)ccc2c1 ; c1ccc2c(c1)ccc1c(-c3ccc4ccc5cccc6ccc3c4c56)c3ccc4ccccc4c3nc12]

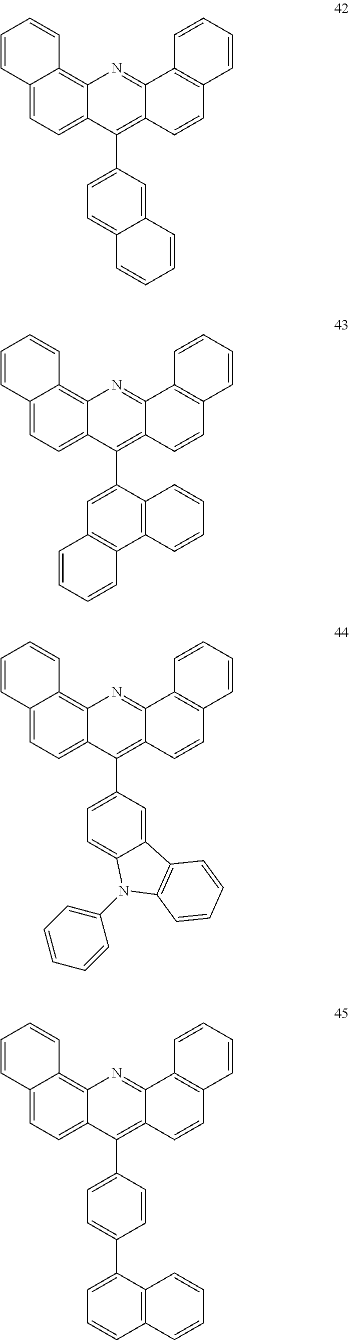 [SMILES: c1ccc2cc(-c3c4ccc5ccccc5c4nc4c3ccc3ccccc34)ccc2c1 ; c1ccc2c(c1)cc(-c1c3ccc4ccccc4c3nc3c1ccc1ccccc13)c1ccccc12 ; c1ccc(-n2c3ccccc3c3cc(-c4c5ccc6ccccc6c5nc5c4ccc4ccccc45)ccc32)cc1 ; c1ccc2c(-c3ccc(-c4c5ccc6ccccc6c5nc5c4ccc4ccccc45)cc3)cccc2c1]

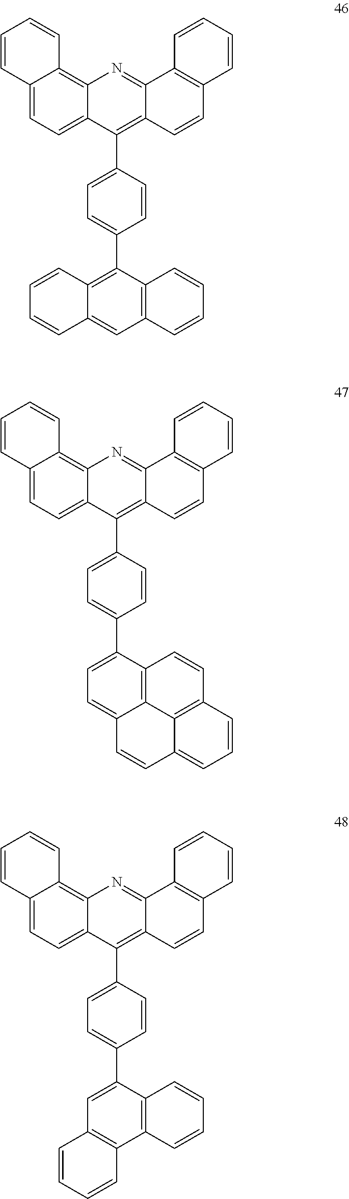 [SMILES: c1ccc2c(-c3ccc(-c4c5ccc6ccccc6c5nc5c4ccc4ccccc45)cc3)c3ccccc3cc2c1 ; c1ccc2c(c1)ccc1c(-c3ccc(-c4ccc5ccc6cccc7ccc4c5c67)cc3)c3ccc4ccccc4c3nc12 ; c1ccc2c(c1)cc(-c1ccc(-c3c4ccc5ccccc5c4nc4c3ccc3ccccc34)cc1)c1ccccc12]

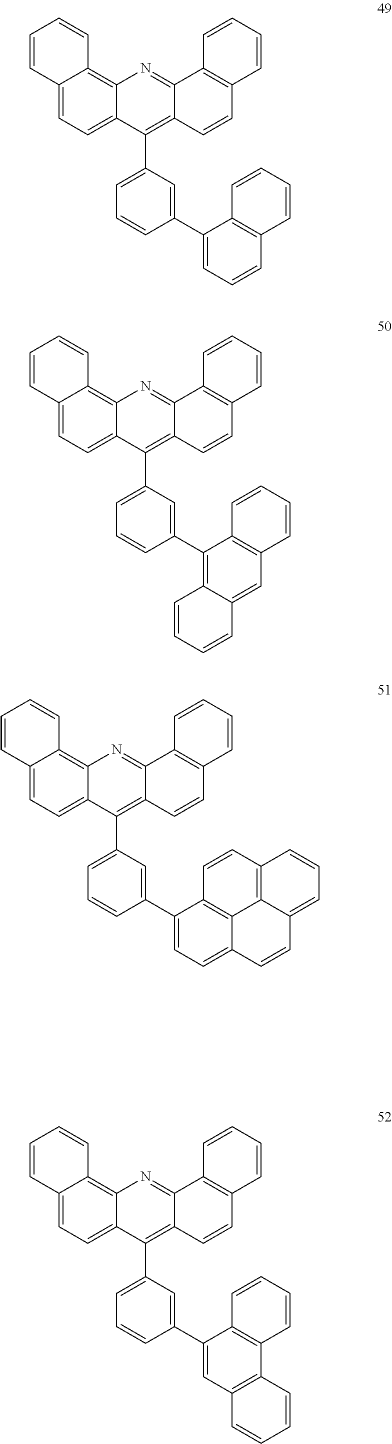 [SMILES: c1cc(-c2cccc3ccccc23)cc(-c2c3ccc4ccccc4c3nc3c2ccc2ccccc23)c1 ; c1cc(-c2c3ccccc3cc3ccccc23)cc(-c2c3ccc4ccccc4c3nc3c2ccc2ccccc23)c1 ; c1cc(-c2c3ccc4ccccc4c3nc3c2ccc2ccccc23)cc(-c2ccc3ccc4cccc5ccc2c3c45)c1 ; c1cc(-c2cc3ccccc3c3ccccc23)cc(-c2c3ccc4ccccc4c3nc3c2ccc2ccccc23)c1]

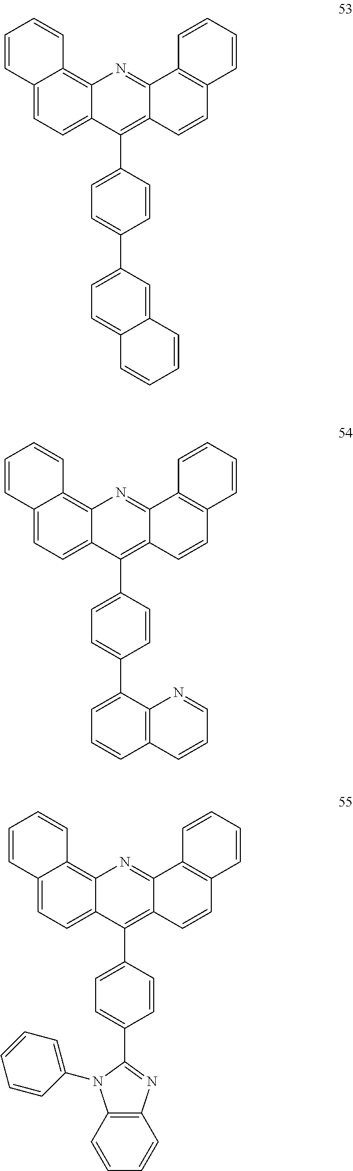 [SMILES: c1ccc2cc(-c3ccc(-c4c5ccc6ccccc6c5nc5c4ccc4ccccc45)cc3)ccc2c1 ; c1cnc2c(-c3ccc(-c4c5ccc6ccccc6c5nc5c4ccc4ccccc45)cc3)cccc2c1 ; c1ccc(-n2c(-c3ccc(-c4c5ccc6ccccc6c5nc5c4ccc4ccccc45)cc3)nc3ccccc32)cc1]

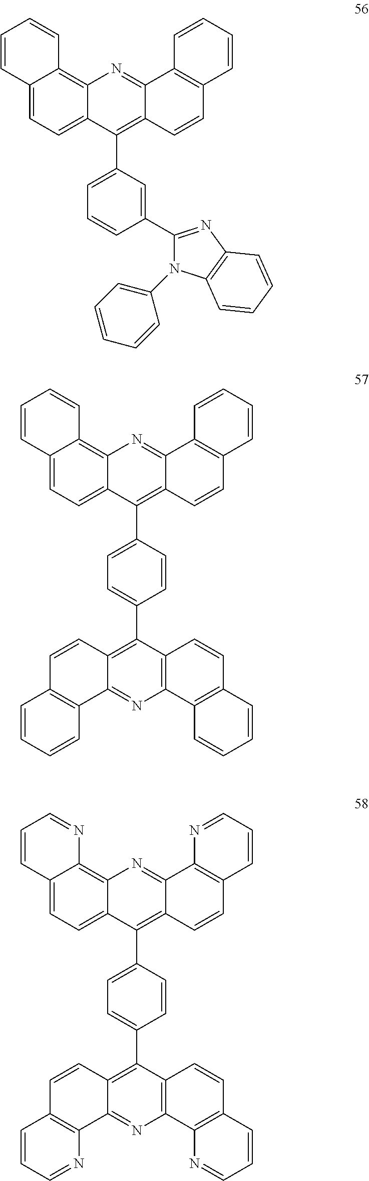 [SMILES: c1ccc(-n2c(-c3cccc(-c4c5ccc6ccccc6c5nc5c4ccc4ccccc45)c3)nc3ccccc32)cc1 ; c1ccc2c(c1)ccc1c(-c3ccc(-c4c5ccc6ccccc6c5nc5c4ccc4ccccc45)cc3)c3ccc4ccccc4c3nc12 ; c1cnc2c(c1)ccc1c(-c3ccc(-c4c5ccc6cccnc6c5nc5c4ccc4cccnc45)cc3)c3ccc4cccnc4c3nc12]

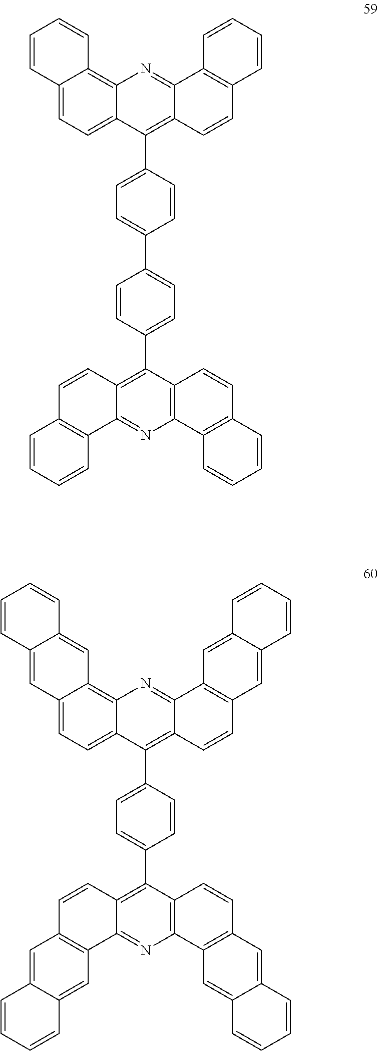 [SMILES: c1ccc2c(c1)ccc1c(-c3ccc(-c4ccc(-c5c6ccc7ccccc7c6nc6c5ccc5ccccc56)cc4)cc3)c3ccc4ccccc4c3nc12 ; c1ccc2cc3c(ccc4c(-c5ccc(-c6c7ccc8cc9ccccc9cc8c7nc7c6ccc6cc8ccccc8cc67)cc5)c5ccc6cc7ccccc7cc6c5nc43)cc2c1]

Detailed examples of the compound represented by Formula 2 are compounds illustrated below, but are not limited thereto.

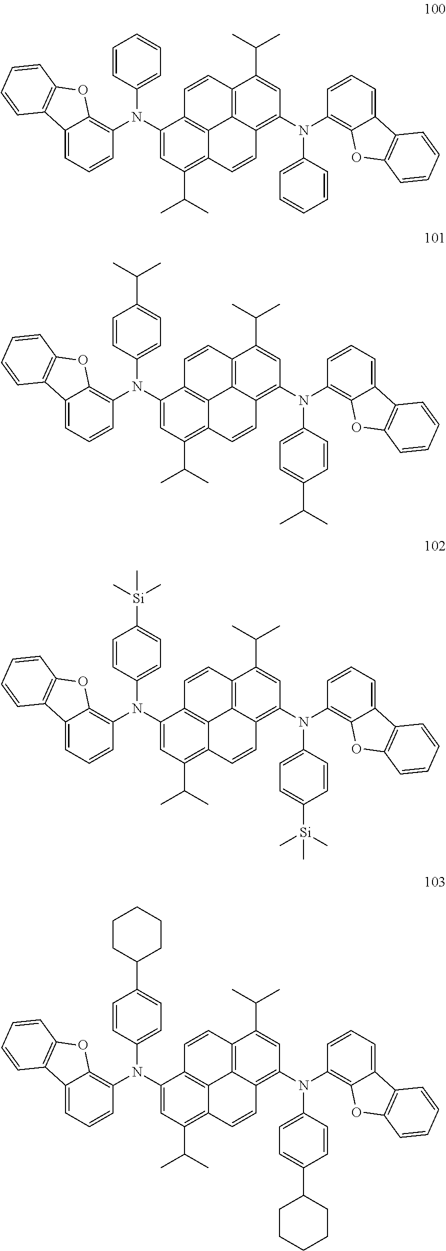 [SMILES: CC(C)c1cc(N(c2ccccc2)c2cccc3c2oc2ccccc23)c2ccc3c(C(C)C)cc(N(c4ccccc4)c4cccc5c4oc4ccccc45)c4ccc1c2c34 ; CC(C)c1ccc(N(c2cc(C(C)C)c3ccc4c(N(c5ccc(C(C)C)cc5)c5cccc6c5oc5ccccc56)cc(C(C)C)c5ccc2c3c54)c2cccc3c2oc2ccccc23)cc1 ; CC(C)c1cc(N(c2ccc([Si](C)(C)C)cc2)c2cccc3c2oc2ccccc23)c2ccc3c(C(C)C)cc(N(c4ccc([Si](C)(C)C)cc4)c4cccc5c4oc4ccccc45)c4ccc1c2c34 ; CC(C)c1cc(N(c2ccc(C3CCCCC3)cc2)c2cccc3c2oc2ccccc23)c2ccc3c(C(C)C)cc(N(c4ccc(C5CCCCC5)cc4)c4cccc5c4oc4ccccc45)c4ccc1c2c34]

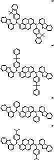 [SMILES: CC1(C)c2ccccc2-c2ccc(N(c3ccc4ccc5c(N(c6ccc7c(c6)C(C)(C)c6ccccc6-7)c6cccc7c6oc6ccccc67)ccc6ccc3c4c65)c3cccc4c3oc3ccccc34)cc21 ; CC(C)(c1ccccc1)c1ccc(N(c2ccc3ccc4c(N(c5ccc(C(C)(C)c6ccccc6)cc5)c5cccc6c5oc5ccccc56)ccc5ccc2c3c54)c2cccc3c2oc2ccccc23)cc1 ; c1ccc(N(c2ccc3ccc4c(N(c5ccccc5)c5cccc6c5oc5ccccc56)ccc5ccc2c3c54)c2cccc3c2oc2ccccc23)cc1 ; CC(C)c1ccc(N(c2ccc3ccc4c(N(c5ccc(C(C)C)cc5)c5cccc6c5oc5ccccc56)ccc5ccc2c3c54)c2cccc3c2oc2ccccc23)cc1]

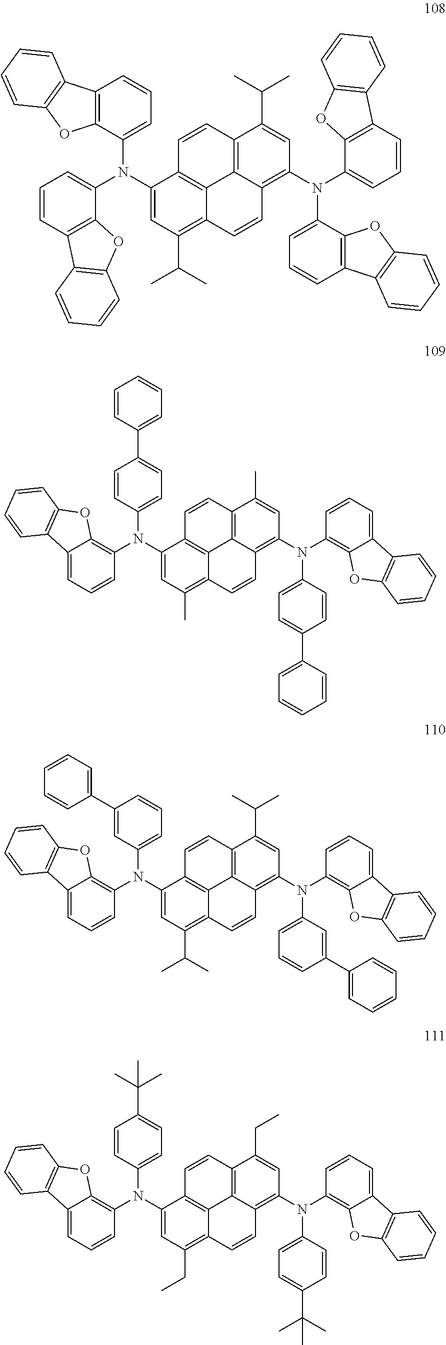 [SMILES: CC(C)c1cc(N(c2cccc3c2oc2ccccc23)c2cccc3c2oc2ccccc23)c2ccc3c(C(C)C)cc(N(c4cccc5c4oc4ccccc45)c4cccc5c4oc4ccccc45)c4ccc1c2c34 ; Cc1cc(N(c2ccc(-c3ccccc3)cc2)c2cccc3c2oc2ccccc23)c2ccc3c(C)cc(N(c4ccc(-c5ccccc5)cc4)c4cccc5c4oc4ccccc45)c4ccc1c2c34 ; CC(C)c1cc(N(c2cccc(-c3ccccc3)c2)c2cccc3c2oc2ccccc23)c2ccc3c(C(C)C)cc(N(c4cccc(-c5ccccc5)c4)c4cccc5c4oc4ccccc45)c4ccc1c2c34 ; CCc1cc(N(c2ccc(C(C)(C)C)cc2)c2cccc3c2oc2ccccc23)c2ccc3c(CC)cc(N(c4ccc(C(C)(C)C)cc4)c4cccc5c4oc4ccccc45)c4ccc1c2c34]

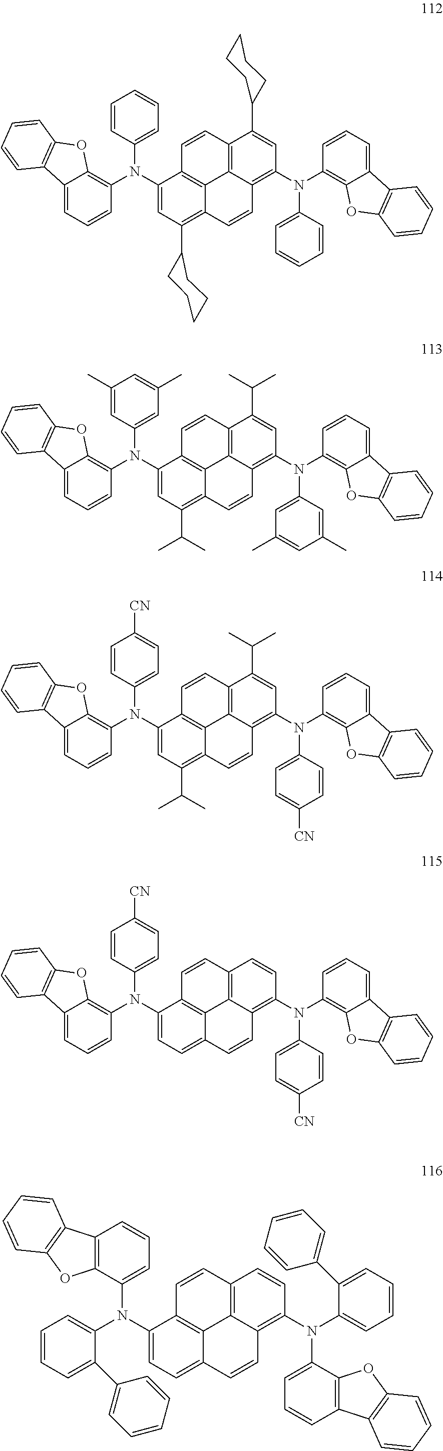

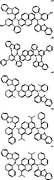

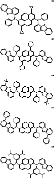

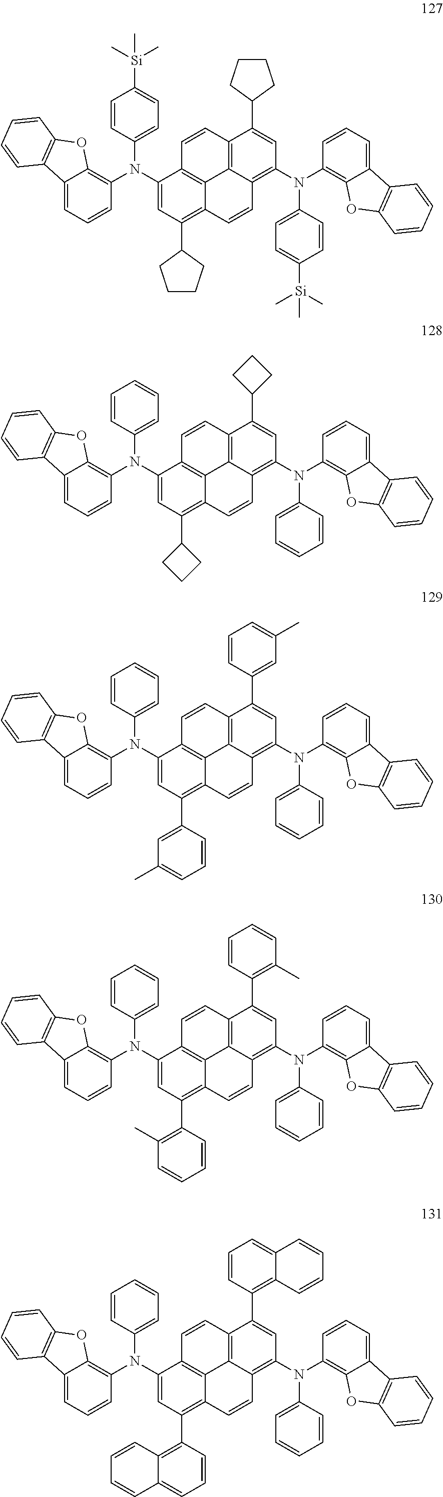

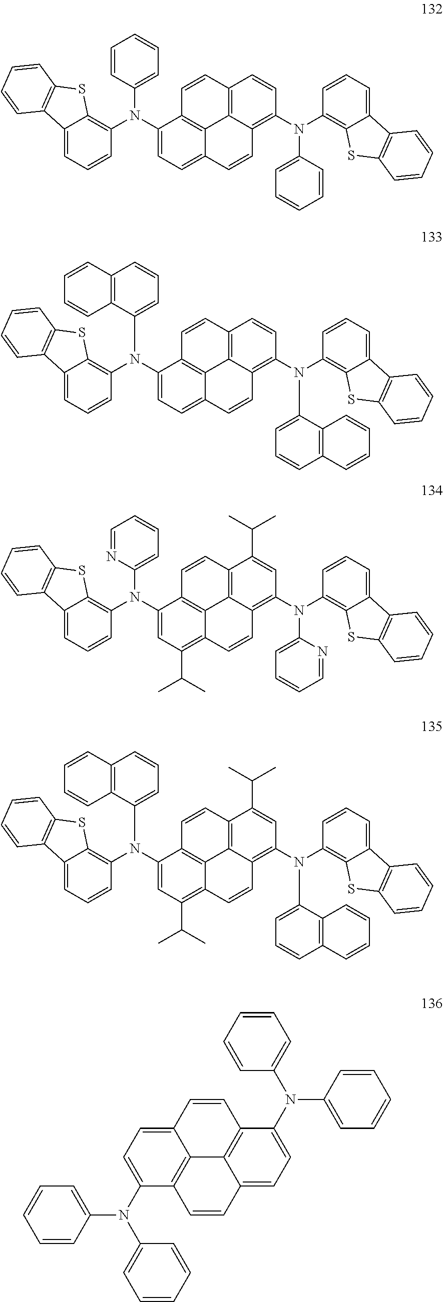 [SMILES: c1ccc(N(c2ccc3ccc4c(N(c5ccccc5)c5cccc6c5sc5ccccc56)ccc5ccc2c3c54)c2cccc3c2sc2ccccc23)cc1 ; c1ccc2c(N(c3ccc4ccc5c(N(c6cccc7ccccc67)c6cccc7c6sc6ccccc67)ccc6ccc3c4c65)c3cccc4c3sc3ccccc34)cccc2c1 ; CC(C)c1cc(N(c2ccccn2)c2cccc3c2sc2ccccc23)c2ccc3c(C(C)C)cc(N(c4ccccn4)c4cccc5c4sc4ccccc45)c4ccc1c2c34 ; CC(C)c1cc(N(c2cccc3ccccc23)c2cccc3c2sc2ccccc23)c2ccc3c(C(C)C)cc(N(c4cccc5ccccc45)c4cccc5c4sc4ccccc45)c4ccc1c2c34 ; c1ccc(N(c2ccccc2)c2ccc3ccc4c(N(c5ccccc5)c5ccccc5)ccc5ccc2c3c54)cc1]

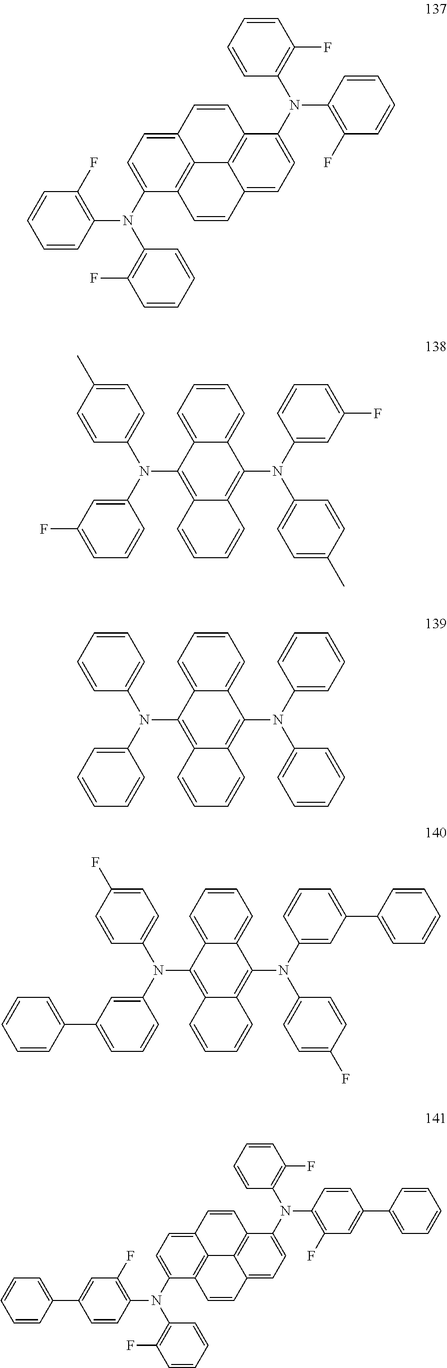 [SMILES: Fc1ccccc1N(c1ccccc1F)c1ccc2ccc3c(N(c4ccccc4F)c4ccccc4F)ccc4ccc1c2c43 ; Cc1ccc(N(c2cccc(F)c2)c2c3ccccc3c(N(c3ccc(C)cc3)c3cccc(F)c3)c3ccccc23)cc1 ; c1ccc(N(c2ccccc2)c2c3ccccc3c(N(c3ccccc3)c3ccccc3)c3ccccc23)cc1 ; Fc1ccc(N(c2cccc(-c3ccccc3)c2)c2c3ccccc3c(N(c3ccc(F)cc3)c3cccc(-c4ccccc4)c3)c3ccccc23)cc1 ; Fc1ccccc1N(c1ccc(-c2ccccc2)cc1F)c1ccc2ccc3c(N(c4ccccc4F)c4ccc(-c5ccccc5)cc4F)ccc4ccc1c2c43]

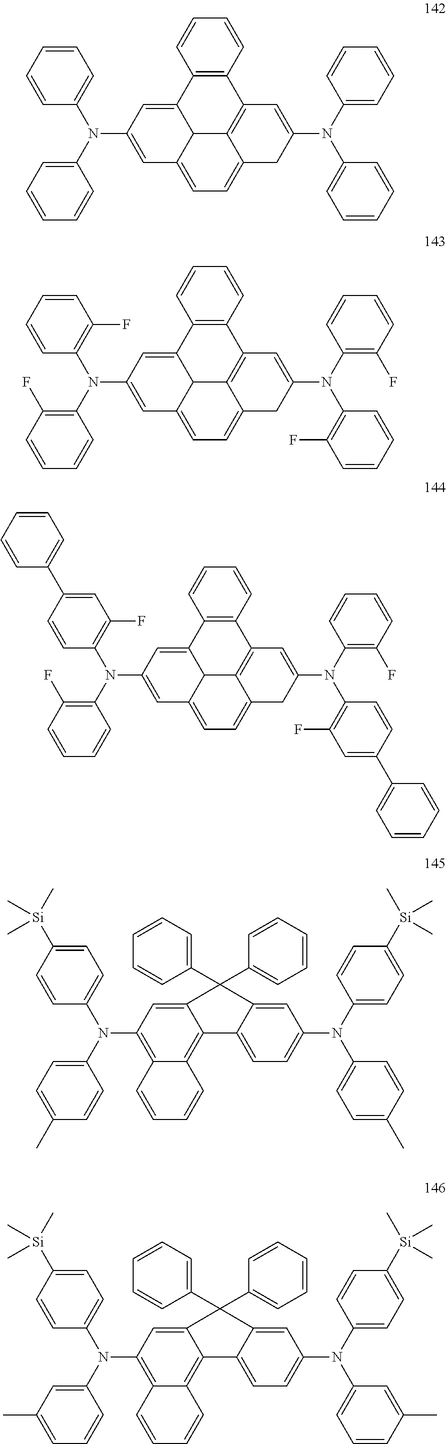

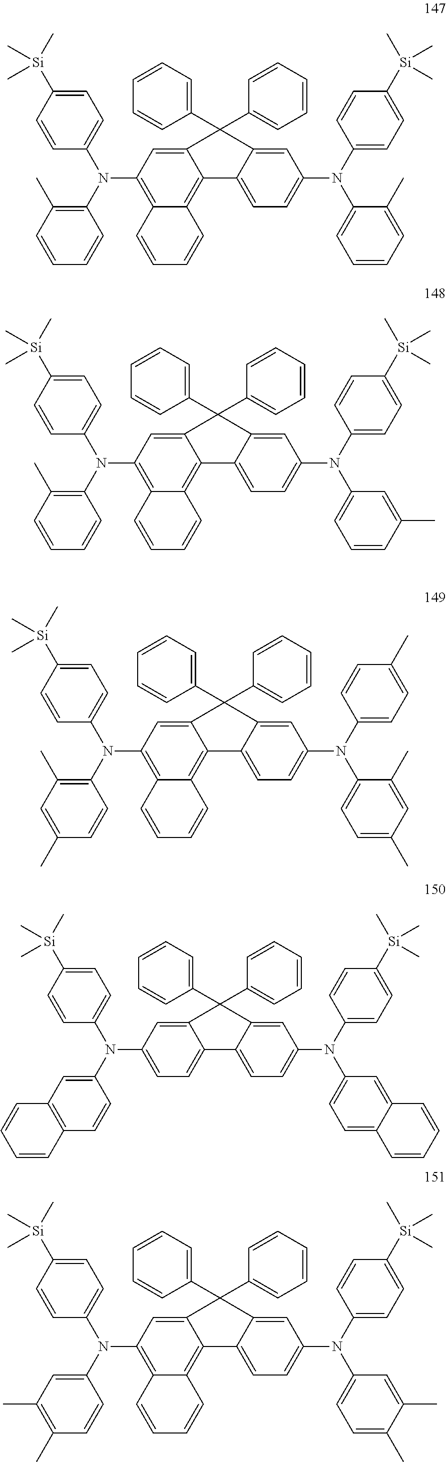

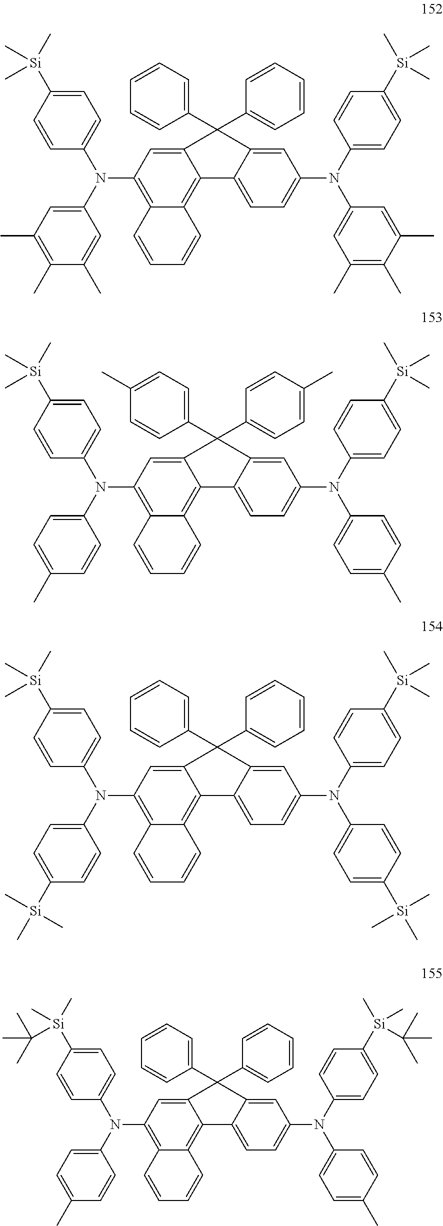

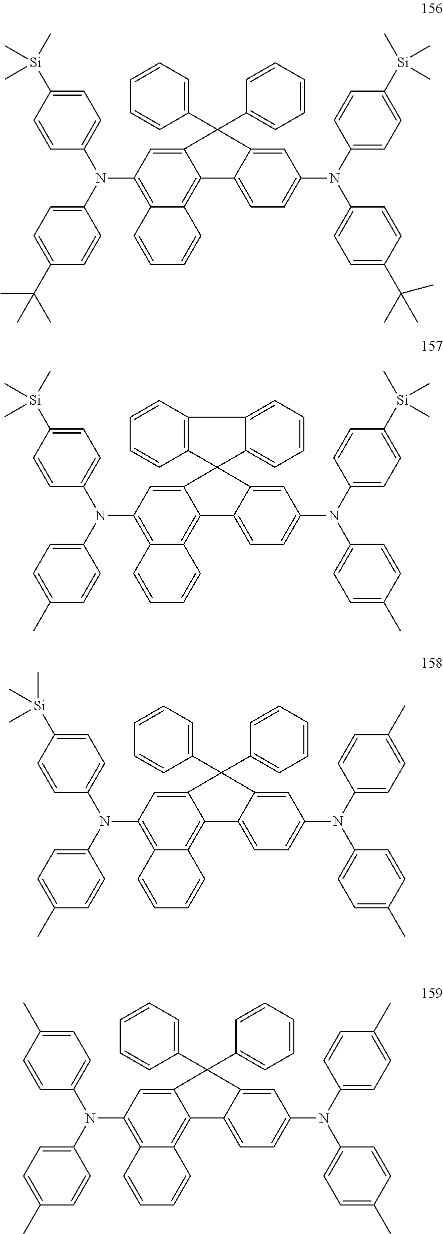

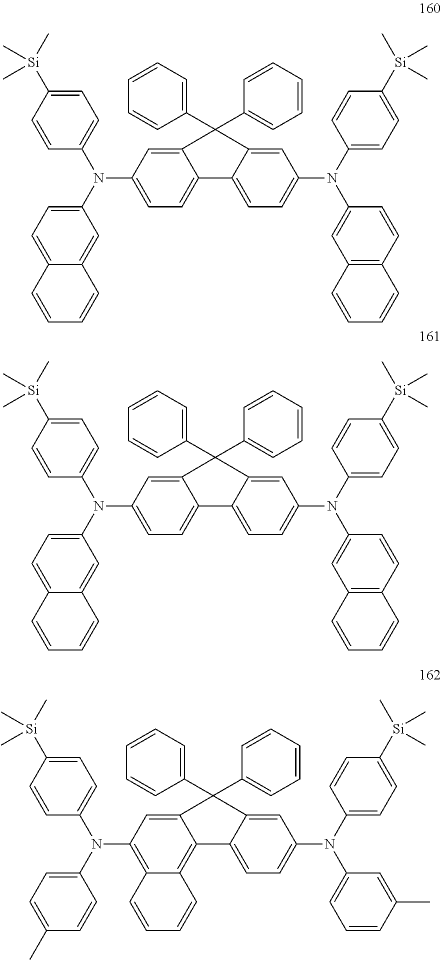

The organic layer may include at least one layer selected from a hole injection layer, a hole transport layer, a functional layer (hereinafter referred to as “H-functional layer”) having a hole injection capability and a hole transport capability, a buffer layer, an electron blocking layer, an emission layer, a hole blocking layer, an electron transport layer, an electron injection layer, or a functional layer (hereinafter referred to as “E-functional layer”) having an electron transport capability and an electron injection capability. The emission layer may be a blue emission layer.

For example, a second layer including the heterocyclic compound represented by Formula 1 may be an electron injection layer, an electron transport layer, or an E-functional layer. For example, the layer may be an electron transport layer.

According to an embodiment of the present invention, the organic light-emitting device may include an emission layer, a hole injection layer, a hole transport layer, or an H-functional layer, and the emission layer may include an anthracene-based compound, an arylamine-based compound, or a styryl-based compound.

According to another embodiment of the present invention, the organic light-emitting device may include an emission layer, a hole injection layer, a hole transport layer, or an H-functional layer, and the emission layer may include a red layer, a green layer, a blue layer, and a white layer. Any one of these layers may include a phosphorescent compound. The hole injection layer, the hole transport layer, or the H-functional layer may include a charge-generation material. Also, the charge-generation material may be a p-dopant, and the p-dopant may be a quinone derivative, a metal oxide, or a cyano group-containing compound.

According to another embodiment of the present invention, the organic layer may include an electron transport layer that includes the compound of Formula 1. The electron transport layer may further include a metal complex. The metal complex may be a Li complex.

The term “organic layer” used herein refers to a single layer and/or a plurality of layers disposed between the first electrode and the second electrode of an organic light-emitting device.

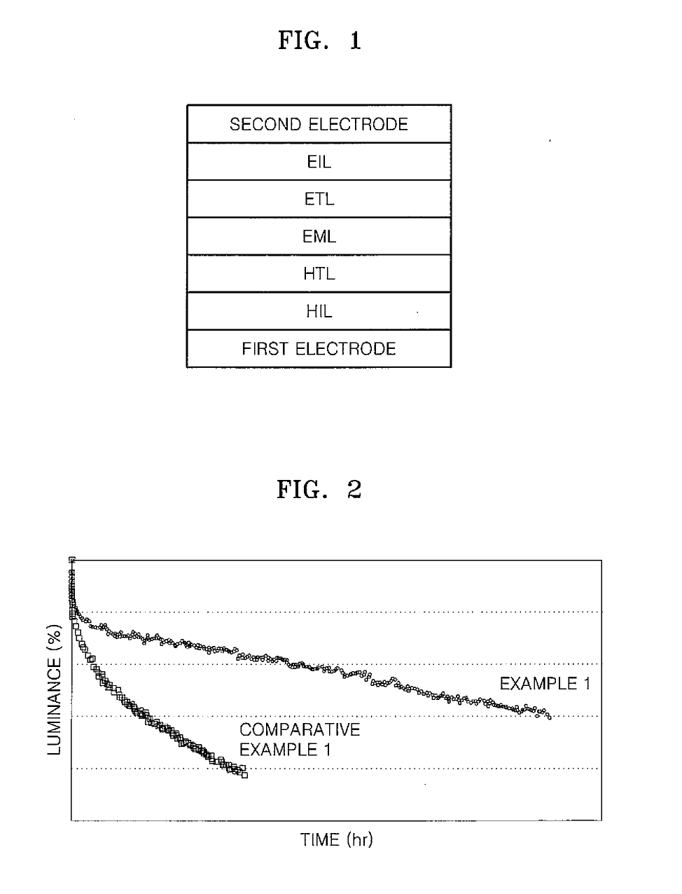

FIG. 1 is a schematic cross-sectional view of an organic light-emitting device according to an embodiment of the present invention. Hereinafter, with reference to FIG. 1, the structure of an organic light-emitting device according to an embodiment of the present invention will be described.

A substrate may be any one of various suitable substrates that are used in a known organic light-emitting device, and may be a glass substrate or a transparent plastic substrate, with excellent mechanical strength, thermal stability, transparency, surface smoothness, ease of handling, and water repellency.

A first electrode may be formed by providing a first electrode material on a substrate by deposition or sputtering. When the first electrode is an anode, the material for the first electrode may be selected from materials with a high work function to make holes easily injected. The first electrode may be a reflective electrode or a transmission electrode. Suitable material for the first electrode may be a transparent and highly conductive material, and examples of such a material are indium tin oxide (ITO), indium zinc oxide (IZO), tin oxide (SnO₂), and zinc oxide (ZnO). According to another embodiment of the present invention, to form the first electrode as a reflective electrode, magnesium (Mg), aluminum (Al), aluminum-lithium (Al—Li), calcium (Ca), magnesium-indium (Mg—In), or magnesium-silver (Mg—Ag) may be used.

The first electrode may have a single- or multi-layered structure. For example, the first electrode may have a three-layered structure of ITO/Ag/ITO, but the structure of the first electrode is not limited thereto.

An organic layer is disposed on the first electrode.

The organic layer may include a hole injection layer, a hole transport layer, a buffer layer, an emission layer, an electron transport layer, or an electron injection layer.

A hole injection layer (HIL) may be formed on the first electrode by using various methods, such as vacuum deposition, spin coating, casting, langmuir-blodgett (LB) deposition, or the like.

When the HIL is formed by vacuum deposition, the deposition conditions may vary according to a material that is used to form the HIL, and the structure and thermal characteristics of the HIL. For example, the deposition conditions may include a deposition temperature of about 100 to about 500° C., a vacuum pressure of about 10⁻⁸ to about 10⁻³ torr, and a deposition rate of about 0.01 to about 100 Å/sec. However, the deposition conditions are not limited thereto.

When the HIL is formed using spin coating as a wet process, coating conditions may vary according to the material used to form the HIL, and the structure and thermal properties of the HIL. For example, a coating speed may be from about 2000 rpm to about 5000 rpm, and a temperature at which a heat treatment is performed to remove a solvent after coating may be from about 80° C. to about 200° C. However, the coating conditions are not limited thereto.

For use as a hole injection material, a suitable hole injection material may be used, and such a suitable hole injection material may be, for example, N,N′-diphenyl-N,N′-bis-[4-(phenyl-m-tolyl-amino)-phenyl]-biphenyl-4,4′-diamine (DNTPD), a phthalocyanine compound such as copper phthalocyanine, 4,4′,4″-tris (3-methylphenyiphenylamino)triphenylamine (m-MTDATA), N,N′-di(1-naphthyl)-N,N′-diphenylbenzidine (NPB), TDATA, 2-TNATA, a polyaniline/dodecylbenzenesulfonic acid (pani/DBSA), poly(3,4-ethylenedioxythiophene)/poly(4-styrenesulfonate) (PEDOT/PSS), polyaniline/camphor sulfonicacid (pani/CSA), or (polyaniline)/poly(4-styrenesulfonate) (PANI/PSS), but is not limited thereto.

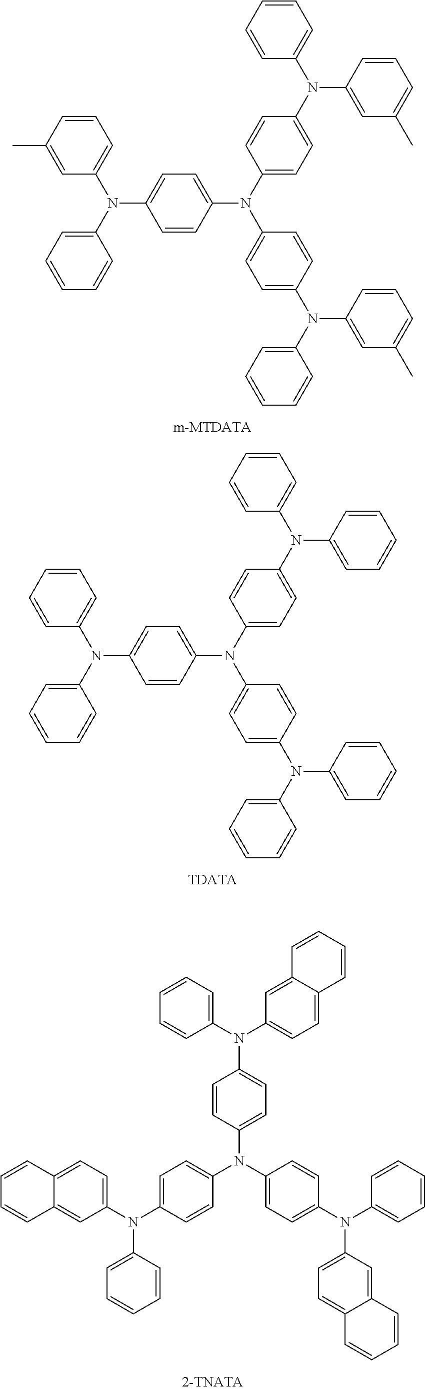

A thickness of the HIL may be from about 100 Å to about 10000 Å, for example, about 100 Å to about 1000 Å. In one embodiment, when the thickness of the HIL is within the ranges described above, excellent electron injection characteristics are obtained without a substantial increase in driving voltage.

Then, a hole transport layer (HTL) may be formed on the HIL by using vacuum deposition, spin coating, casting, LB deposition, or the like. When the HTL is formed by vacuum deposition or spin coating, the deposition or coating conditions may be similar to those applied to form the HIL although the deposition or coating conditions may vary according to the material that is used to form the HTL.

For use as a hole transport material, any suitable hole transport material may be used. Examples of a suitable hole transport material are a carbazole derivative, such as N-phenylcarbazole or polyvinylcarbazol, N,N′-bis(3-methylphenyl)-N,N′-diphenyl-[1,1-biphenyl]-4,4′-diamine (TPD), 4,4′,4″-tris(N-carbazolyl)triphenylamine (TCTA), and N,N′-di(1-naphthyl)-N,N′-diphenylbenzidine (NPB), but are not limited thereto.

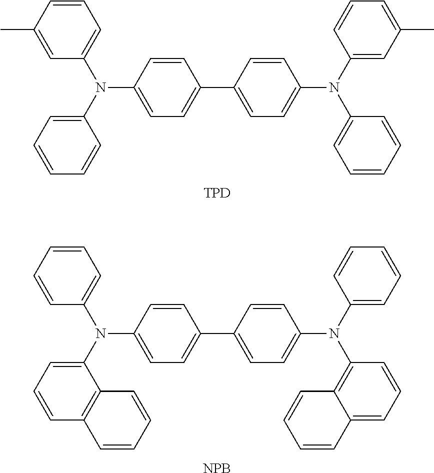

A thickness of the HTL may be from about 50 Å to about 2000 Å, for example, about 100 Å to about 1500 Å. In one embodiment, when the thickness of the HTL is within the ranges described above, excellent electron injection characteristics are obtained without a substantial increase in driving voltage.

The H-functional layer may include at least one material selected from the HIL materials and the HTL materials, and a thickness of the H-functional layer may be in a range of about 500 Å to about 10000 Å, for example, about 100 Å to about 1000 Å. In one embodiment, when the thickness of the H-functional layer is within these ranges, the H-functional layer has satisfactory hole injection and transport characteristics without a substantial increase in driving voltage.

In addition, at least one layer of the HIL, the HTL, and the H-functional layer may include at least one of a compound represented by Formula 300 below or a compound represented by Formula 350 below:

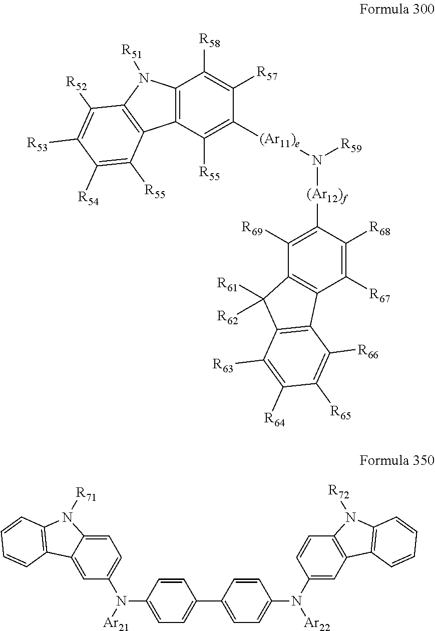

Ar₁₁, Ar₁₂, Ar₂₁, and Ar₂₂ in Formulae 300 and 350 are each independently a substituted or unsubstituted C₅-C₆₀ arylene group.

e and f in Formula 300 may be each independently an integer of 0 to 5, or 0, 1 or 2. For example, e may be 1 and f may be 0, but e and f are not limited thereto.

R₅₁-R₅₈, R₆₁-R₆₉ and R₇₁ and R₇₂ in Formulae 300 and 350 are each independently a hydrogen atom, a deuterium atom, a halogen atom, a hydroxyl group, a cyano group, a nitro group, an amino group, an amidino group, a hydrazine, a hydrazone, a carboxylic group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ aryl group, a substituted or unsubstituted C₅-C₆₀ aryloxy, or a substituted or unsubstituted C₅-C₆₀ arylthio group. For example, R₅₁-R₅₈, R₆₁-R₆₉, and R₇₁ and R₇₂ may be each independently a hydrogen atom; a deuterium atom; a halogen atom; a hydroxyl group; a cyano group; a nitro group; an amino group; an amidino group; a hydrazine; a hydrazone; a carboxylic group or a salt thereof; a sulfonic acid group or a salt thereof; a phosphoric acid group or a salt thereof; a C₁-C₁₀ alkyl group, for example, a methyl group, an ethyl group, a propyl group, a butyl group, a pentyl group, a hexyl group; a C₁-C₁₀ alkoxy group, for example, a methoxy group, an ethoxy group, a propoxy group, a buthoxy group, or a penthoxy group; a C₁-C₁₀ alkyl group or a C₁-C₁₀ alkoxy group, each substituted with at least one selected from a deuterium atom, a halogen atom, a hydroxyl group, a cyano group, a nitro group, an amino group, an amidino group, a hydrazine, a hydrazone, a carboxylic group or a salt thereof, a sulfonic acid group or a salt thereof, or a phosphoric acid group or a salt thereof; a phenyl group; a naphthyl group; an anthryl group; or a fluorenyl group; a pyrenyl group; a phenyl group, a naphthyl group, an anthryl group, a fluorenyl group, or a pyrenyl group, each substituted with at least one selected from a deuterium atom, a halogen atom, a hydroxyl group, a cyano group, a nitro group, an amino group, an amidino group, a hydrazine, a hydrazone, a carboxylic group or a salt thereof, a sulfonic acid group or a salt thereof, a phosphoric acid group or a salt thereof, a C₁-C₁₀ alkyl group, or a C₁-C₁₀ alkoxy group, but are not limited thereto.

R₅₉ in Formula 300 may be a phenyl group; a naphthyl group; an anthryl group; a biphenyl group; a pyridyl group; or a phenyl group, a naphthyl group, an anthryl group, a biphenyl group, or a pyridyl group, each substituted with at least one selected from a deuterium atom, a halogen atom, a hydroxyl group, a cyano group, a nitro group, an amino group, an amidino group, hydrazine, hydrazone, a carboxylic group or a salt thereof, a sulfonic acid group or a salt thereof, a phosphoric acid group or a salt thereof, a substituted or unsubstituted C₁-C₂₀ alkyl group, or a substituted or unsubstituted C₁-C₂₀ alkoxy group.

According to an embodiment of the present invention, the compound represented by Formula 300 may be represented by Formula 300A below, but is not limited thereto:

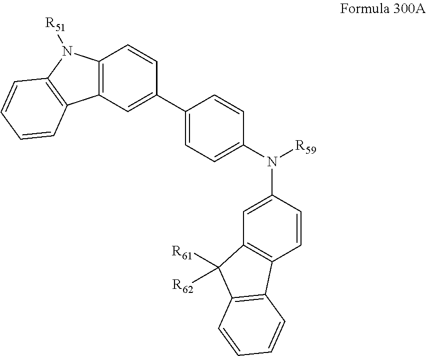

Detailed description about R₅₁, R₆₂, R₆₁, and R₅₉ in Formula 300A are as already described above.

For example, at least one layer of the HIL, the HTL, and the H-functional layer may include at least one of Compounds 301 to 320 below, but may instead include other materials.

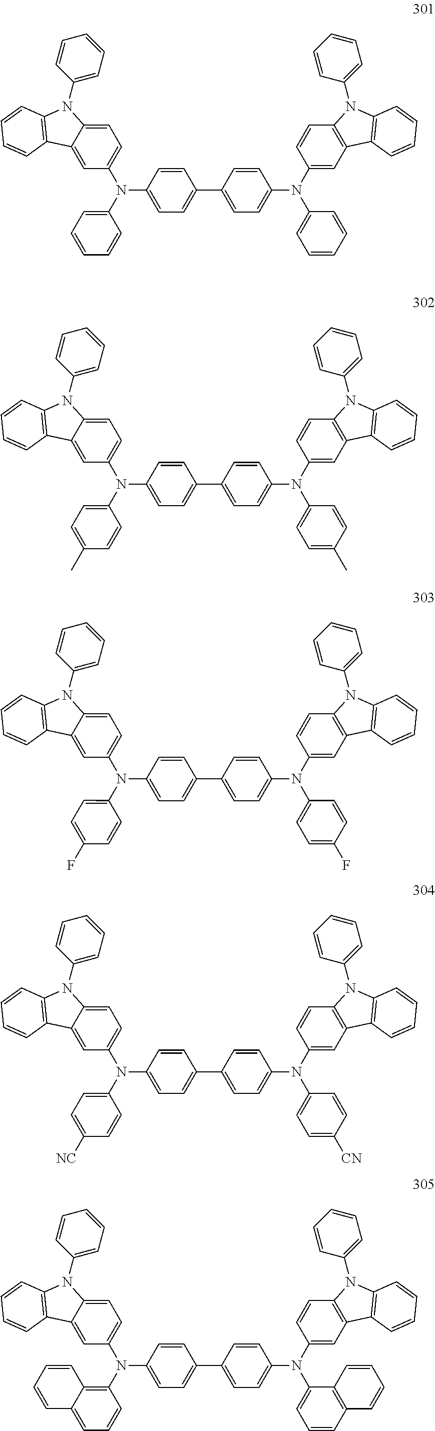

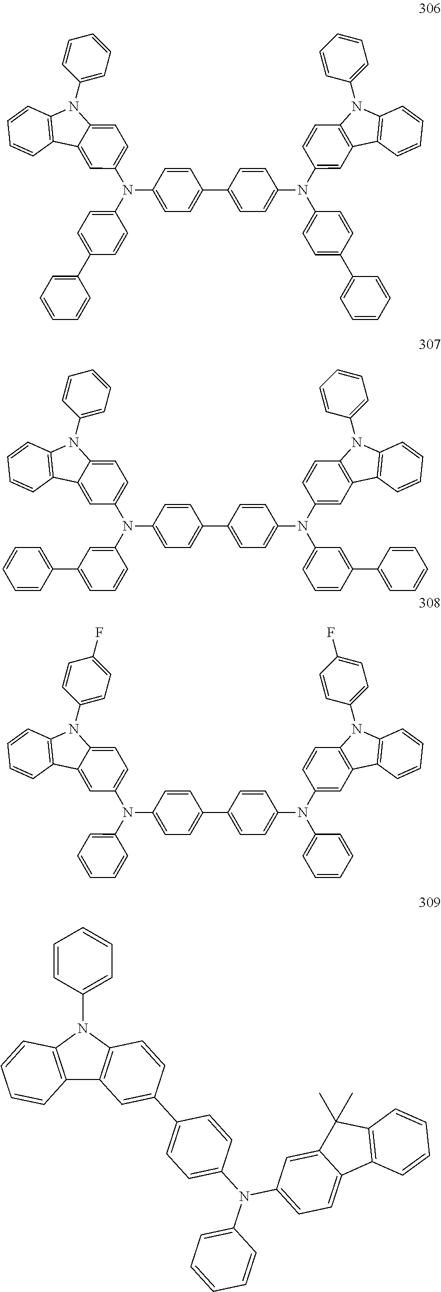 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; CC1(C)c2ccccc2-c2ccc(N(c3ccccc3)c3ccc(-c4ccc5c(c4)c4ccccc4n5-c4ccccc4)cc3)cc21]

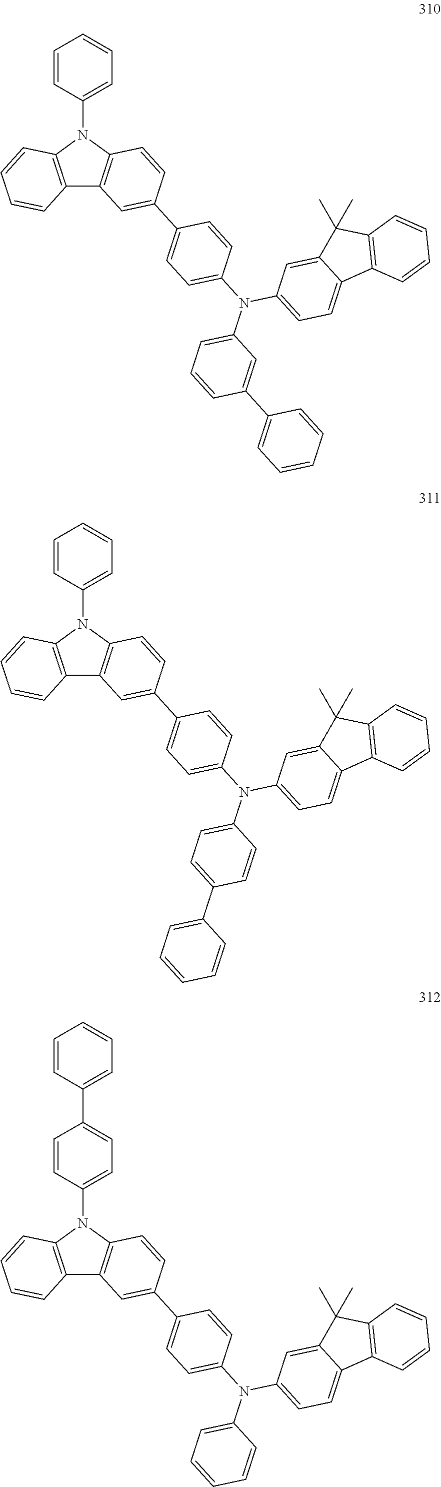 [SMILES: CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

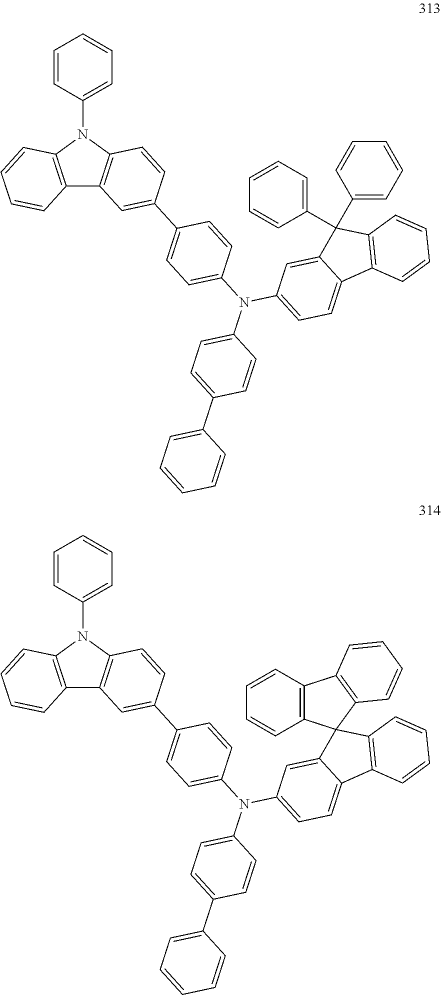 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

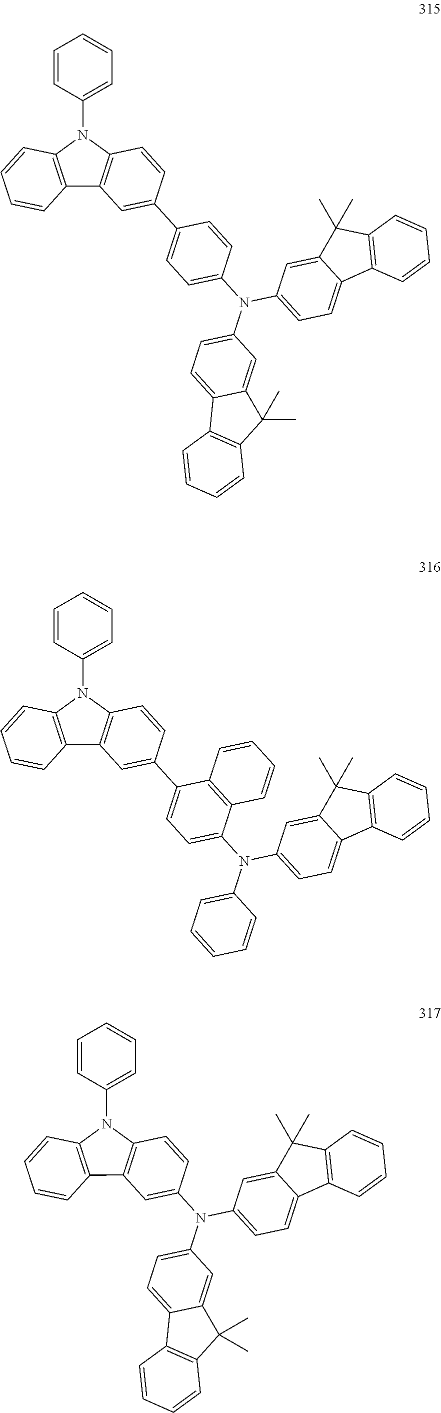 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

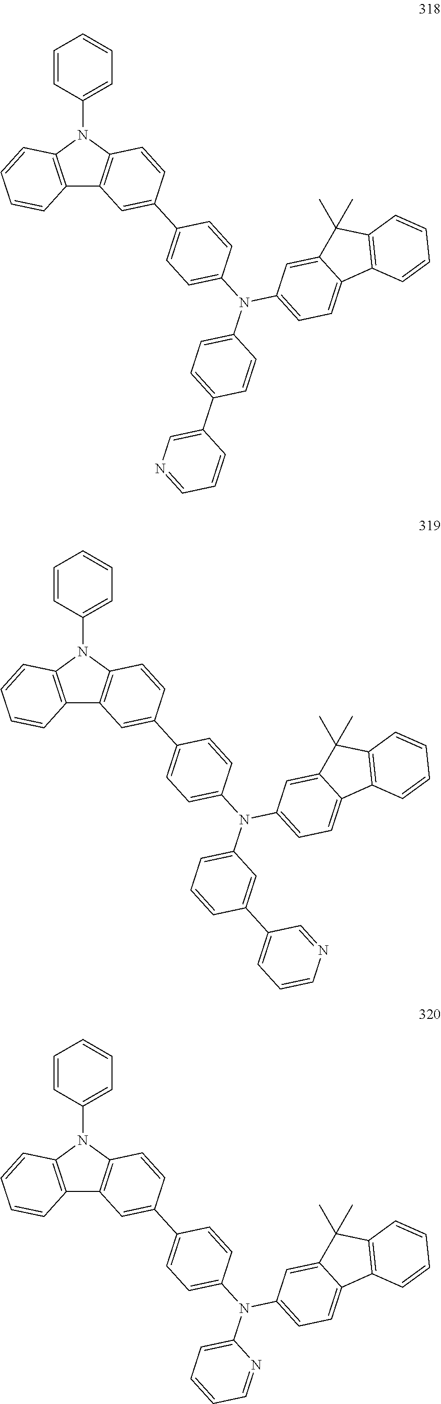 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

At least one of the HIL, the HTL, and the H-functional layer may further include a charge-generation material to increase the conductivity of a layer, in addition to such suitable hole injecting materials, suitable hole transport materials, and/or materials having both hole injection and hole transport capabilities.

The charge-generation material may be, for example, a p-dopant. The p-dopant may be one of a quinone derivative, a metal oxide, or a cyano group-containing compound, but is not limited thereto. For example, non-limiting examples of the p-dopant are a quinone derivative, such as tetracyanoquinonedimethein (TCNQ), 2,3,5,6-tetrafluoro-tetracyano-1,4-benzoquinonedimethein (F4-TCNQ), or the like; a metal oxide, such as a tungsten oxide or a molybdenum oxide; and a cyano group-containing compound, such as Compound 200 below, but are not limited thereto.

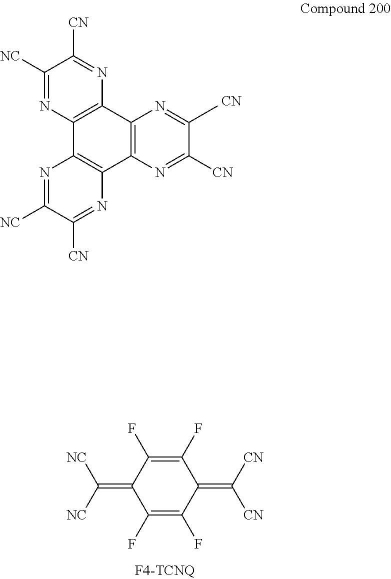

When the HIL, the HTL or the H-functional layer further includes a charge-generation material, the charge-generation material may be homogeneously dispersed or non-homogeneously distributed in the HIL, the HTL, or the H-functional layer.

A buffer layer may be disposed between at least one of the HIL, the HTL, or the H-functional layer, and an emission layer. Also, the buffer layer may compensate for an optical resonance distance according to a wavelength of light emitted from the emission layer, therefore, efficiency of a formed organic light-emitting diode may be improved. The buffer layer may include a suitable hole injection material and a hole transportation material. Also, the buffer layer may include a material that is identical to one of materials included in the HIL, the hole transport layer, and or H-functional layer formed under the buffer layer.

Subsequently, an emission layer (EML) may be formed on the HTL, the H-functional layer, or the buffer layer by spin coating, casting, or a LB method. When the EML is formed by vacuum deposition or spin coating, the deposition or coating conditions may be similar to those for the formation of the HIL, though the conditions for deposition or coating may vary according to the material that is used to form the EML.

The EML may include the compound of Formula 2 according to an embodiment of the present invention or any suitable compound for the EML.

The EML may further include, in addition to the compound, a host.

As the host, Alq₃, 4,4′-N,N′-dicarbazole-biphenyl (CBP), poly(n-vinylcarbazole) (PVK), 9,10-di(naphthalene-2-yl)anthracene (ADN), TCTA, 1,3,5-tris(N-phenylbenzimidazole-2-yl)benzene (TPBI), 3-tert-butyl-9,10-di(naphth-2-yl) anthracene (TBADN), E3, distyrylarylene (DSA), dmCBP (see the following chemical structure), Compounds 501 to 509 illustrated below, or the like may be used, but other materials may instead be used as the host.

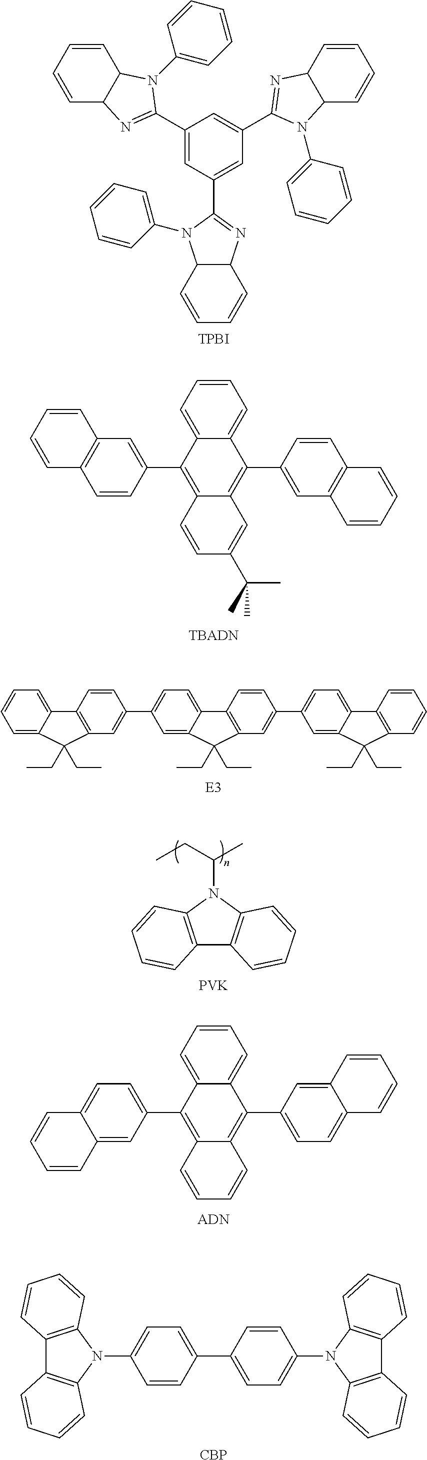

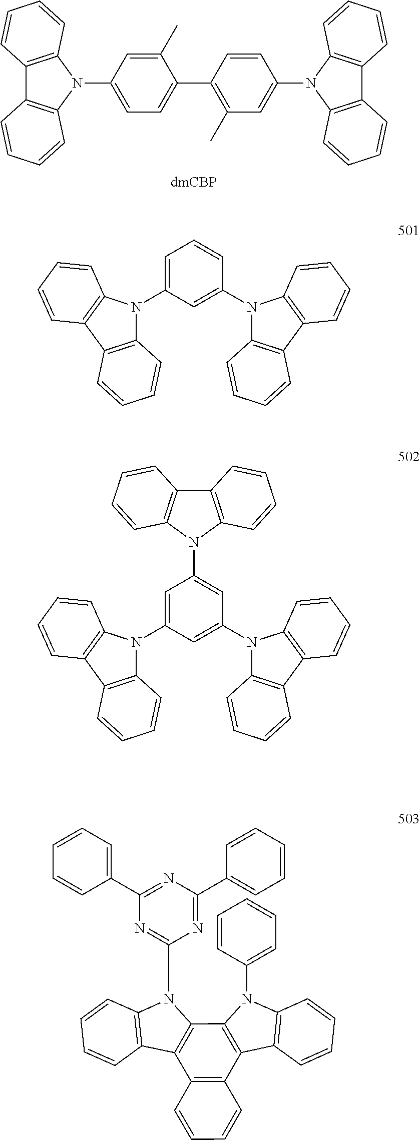 [SMILES: Cc1cc(-n2c3ccccc3c3ccccc32)ccc1-c1ccc(-n2c3ccccc3c3ccccc32)cc1C ; "dmCBP" ; c1cc(-n2c3ccccc3c3ccccc32)cc(-n2c3ccccc3c3ccccc32)c1 ; c1ccc2c(c1)c1ccccc1n2-c1cc(-n2c3ccccc3c3ccccc32)cc(-n2c3ccccc3c3ccccc32)c1 ; c1ccc(-c2nc(-c3ccccc3)nc(-n3c4ccccc4c4c5ccccc5c5c6ccccc6n(-c6ccccc6)c5c43)n2)cc1]

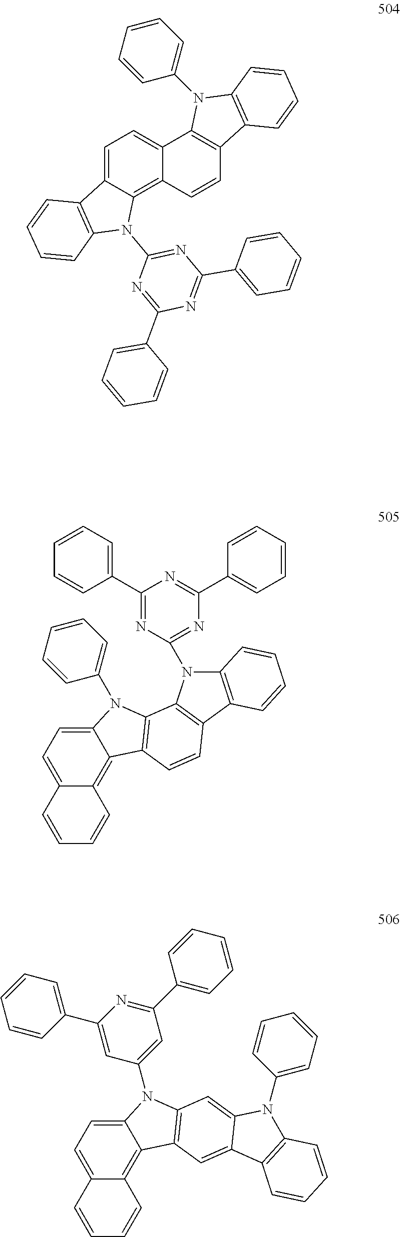 [SMILES: c1ccc(-c2nc(-c3ccccc3)nc(-n3c4ccccc4c4ccc5c(ccc6c7ccccc7n(-c7ccccc7)c65)c43)n2)cc1 ; c1ccc(-c2nc(-c3ccccc3)nc(-n3c4ccccc4c4ccc5c6c7ccccc7ccc6n(-c6ccccc6)c5c43)n2)cc1 ; c1ccc(-c2cc(-n3c4cc5c(cc4c4c6ccccc6ccc43)c3ccccc3n5-c3ccccc3)cc(-c3ccccc3)n2)cc1]

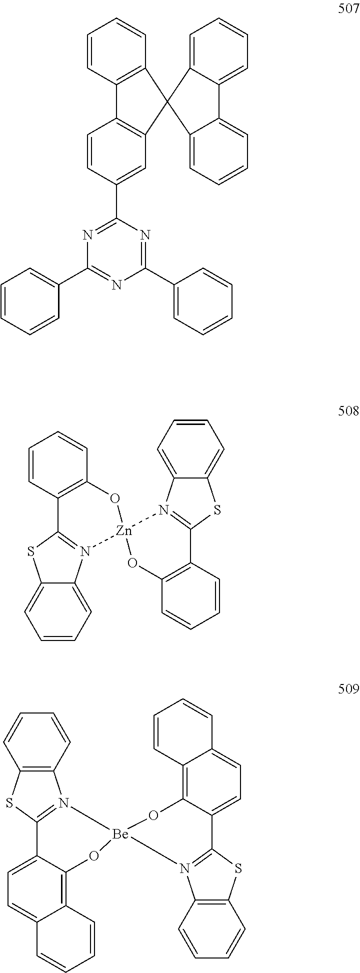

According to another embodiment of the present invention, the host may be an anthracene-based compound represented by Formula 400 below:

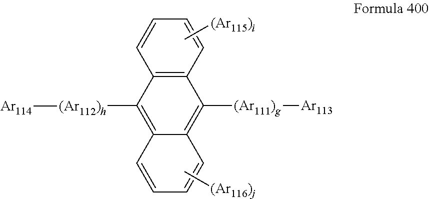

In Formula 400, Ar₁₁₁ and Ar₁₁₂ are each independently a substituted or unsubstituted C₅-C₆₀ arylene group; Ar₁₁₃-Ar₁₁₆ are each independently a substituted or unsubstituted C₁-C₁₀ alkyl group or a substituted or unsubstituted C₅-C₆₀ aryl group; and g, h, i and j are each independently an integer of 0 to 4.

For example, Ar₁₁₁ and Ar₁₁₂ in Formula 400 may be a phenylene group, a naphthylene group, a phenanthrenyl group, or a pyrenyl group; or a phenylene group, a naphthylene group, a phenanthrenyl group, a fluorenyl group, or a pyrenyl group, each substituted with at least one selected from a phenylene group, a naphthylene group, or a phenanthrenyl group, but are not limited thereto.

g, h, i and j in Formula 400 may be each independently 0, 1, or 2.

Ar₁₁₃ to Ar₁₁₆ in Formula 400 may be each independently a C₁-C₁₀ alkyl group substituted with at least one selected from a phenyl group, a naphthyl group, or an anthryl group; a phenyl group; a naphthyl group; an anthryl group; a pyrenyl group; a phenanthrenyl group; a fluorenyl group; a phenyl group, a naphthyl group, an anthryl group, a pyrenyl group, a phenanthrenyl group, or a fluorenyl group, each substituted with at least one selected from a deuterium atom, a halogen atom, a hydroxyl group, a cyano group, a nitro group, an amino group, an amidino group, a hydrazine, a hydrazone, a carboxylic group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthryl group, a pyrenyl group, a phenanthrenyl group, or a fluorenyl group; or

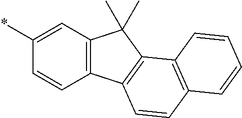 [SMILES: *c1ccc2c(c1)C(C)(C)c1c-2ccc2ccccc12]

, but are not limited thereto.

For example, the anthracene-based compound represented by Formula 400 below may be any one of compounds illustrated below, but is not limited thereto.

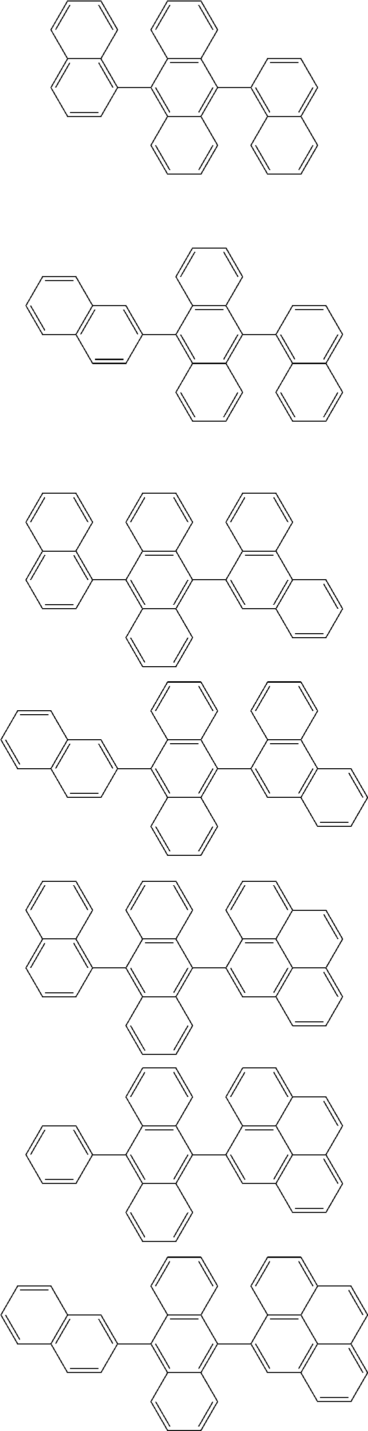

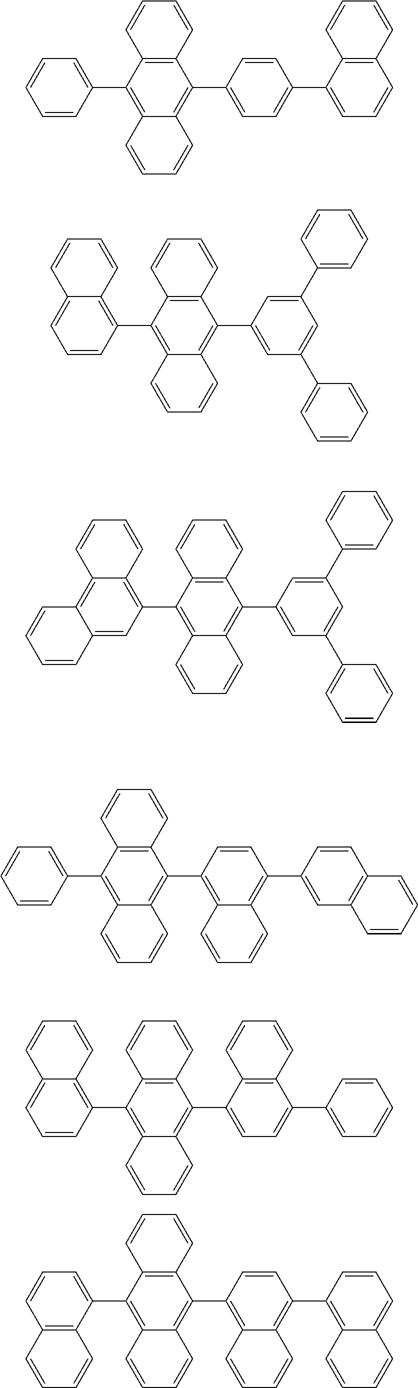

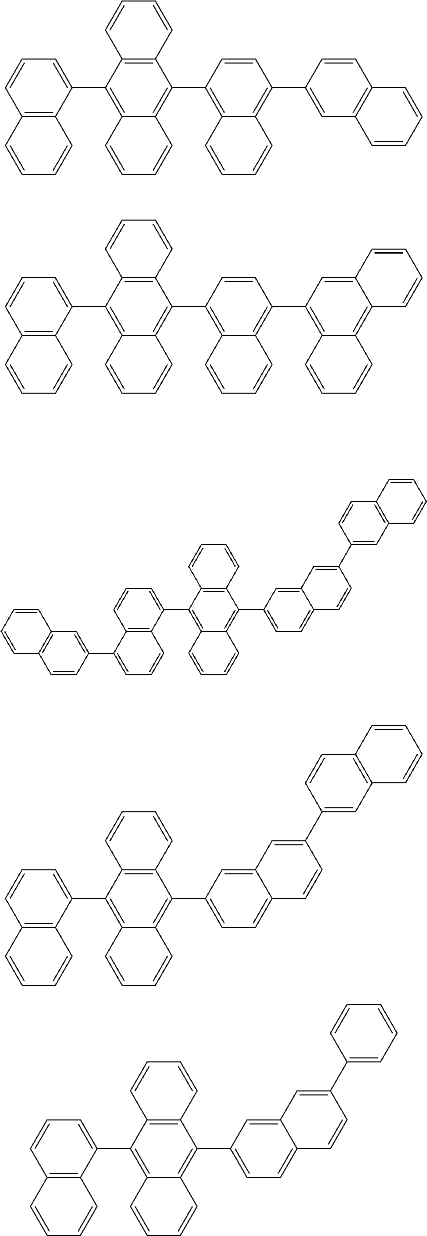

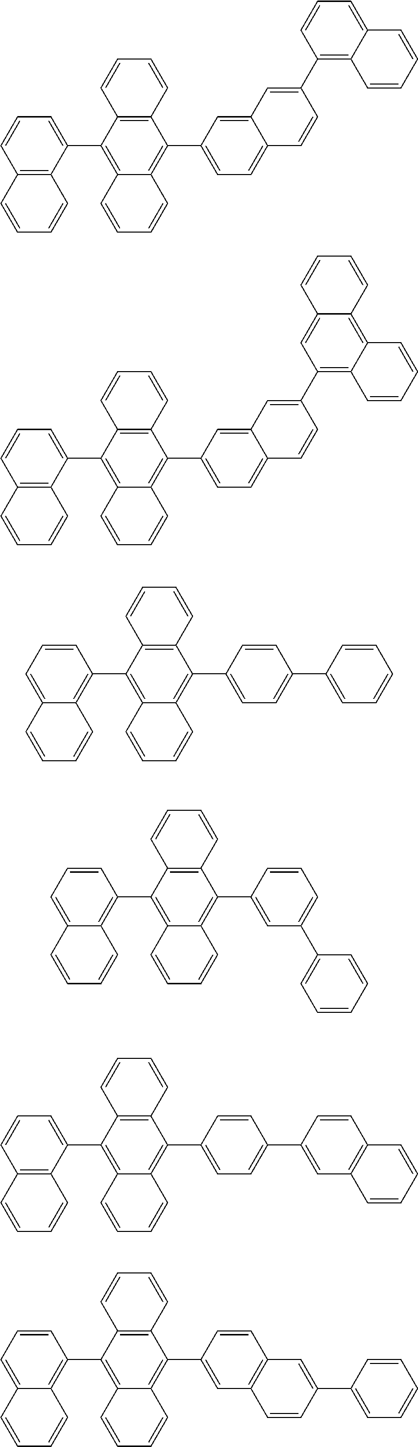

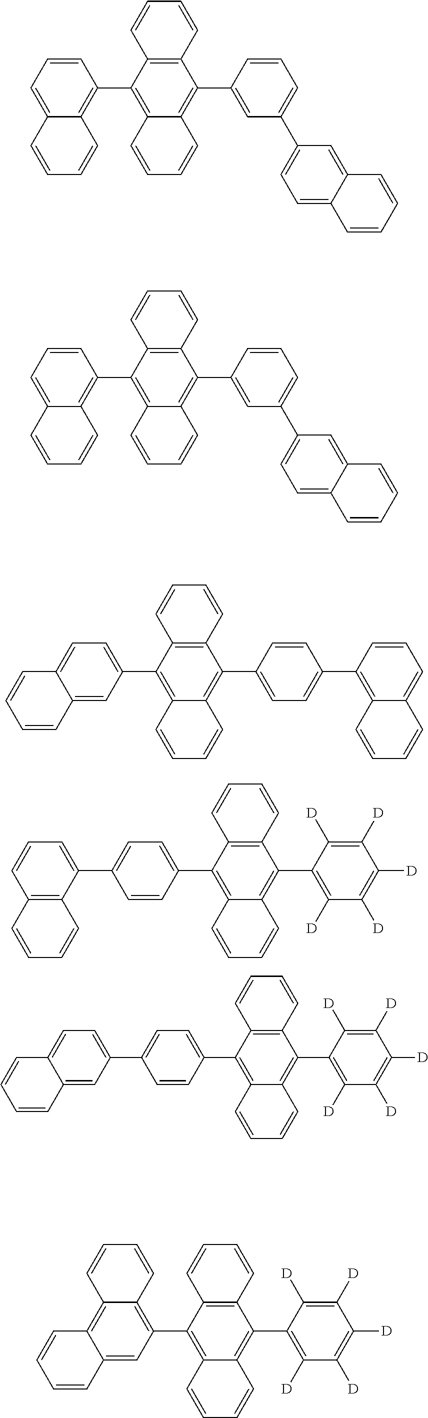

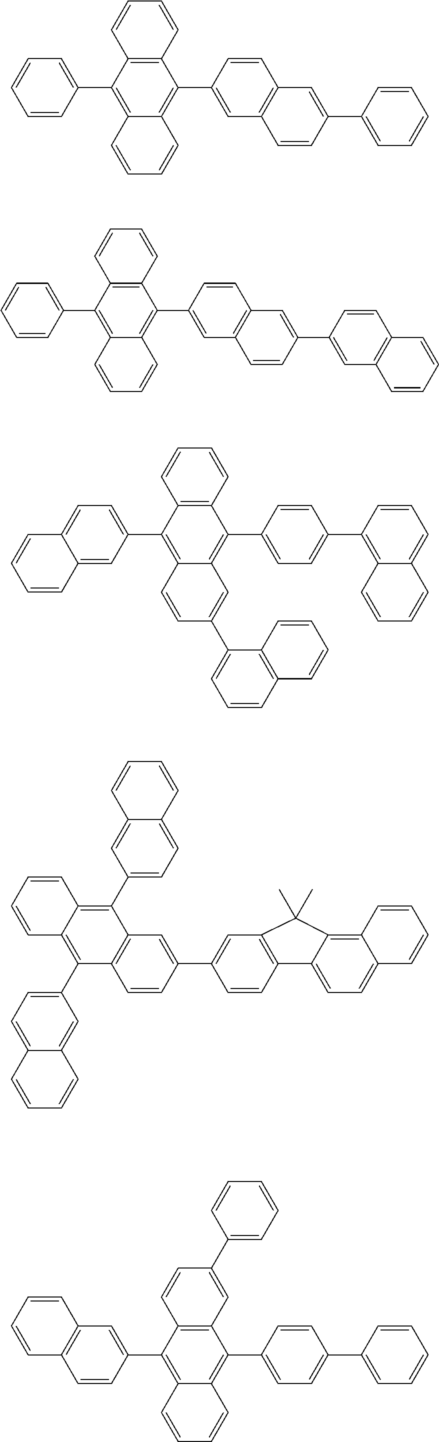

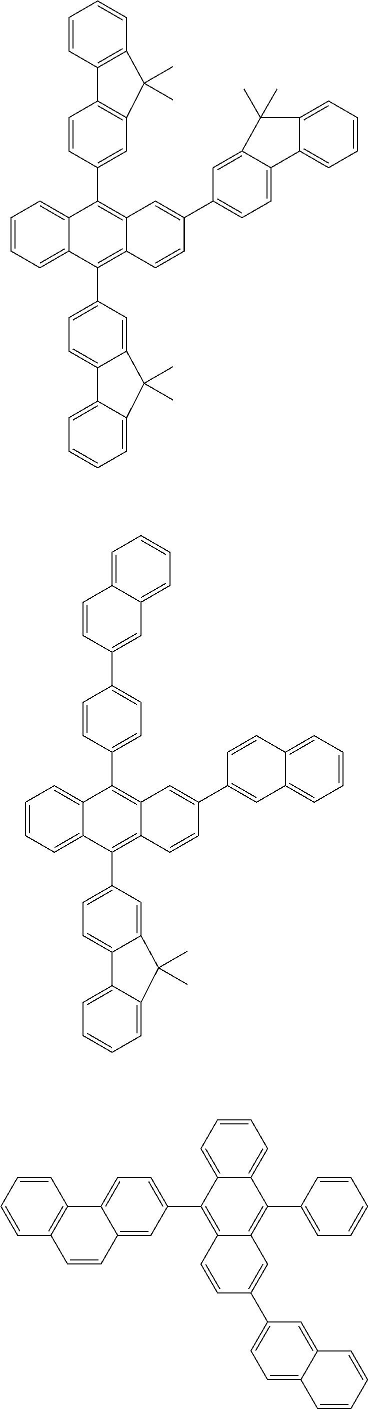

According to another embodiment of the present invention, the host may be an anthracene-based compound represented by Formula 401 below:

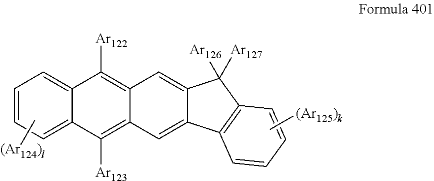

Ar₁₂₂ to Ar₁₂₅ in Formula 401 may be the same as the description provided in connection with Ar₁₁₃ of Formula 400.

Ar₁₂₆ and Ar₁₂₇ in Formula 401 may be each independently a C₁-C₁₀ alkyl group, for example, a methyl group, an ethyl group, or a propyl group.

k and l in Formula 401 may be each independently an integer of 0 to 4. For example, k and l may be 0, 1, or 2.

For example, the anthracene-based compound represented by Formula 401 below may be any one of the compounds illustrated below, but is not limited thereto.

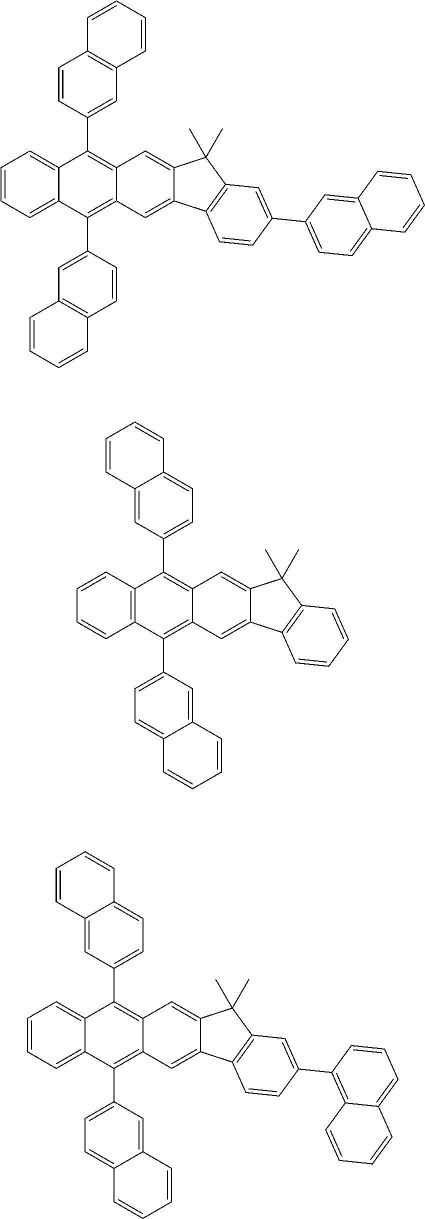

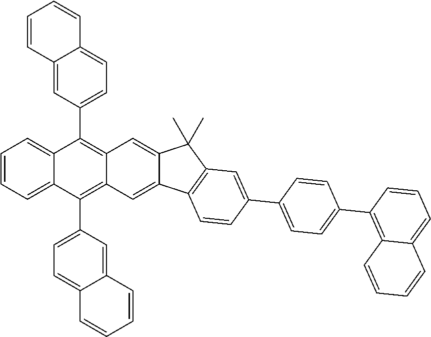 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

When the organic light-emitting device is a full-color organic light-emitting device, an EML may be patterned into a red EML, a green EML, and a blue EML.

Also, at least one of the red EML, the green EML or the blue EML may include dopants illustrated below (ppy indicates phenylpyridine).

For example, the compounds illustrated below may be used as a blue dopant, but the blue dopant is not limited thereto.

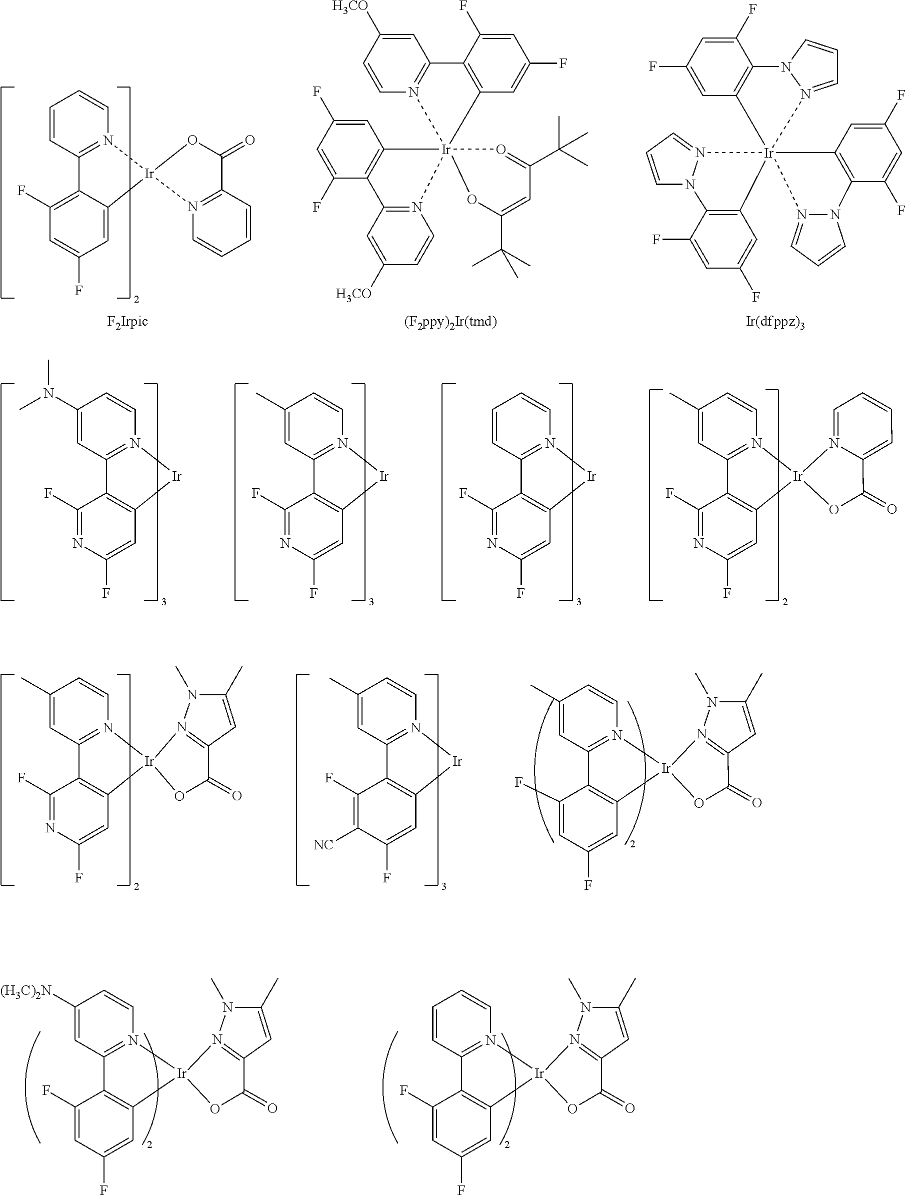

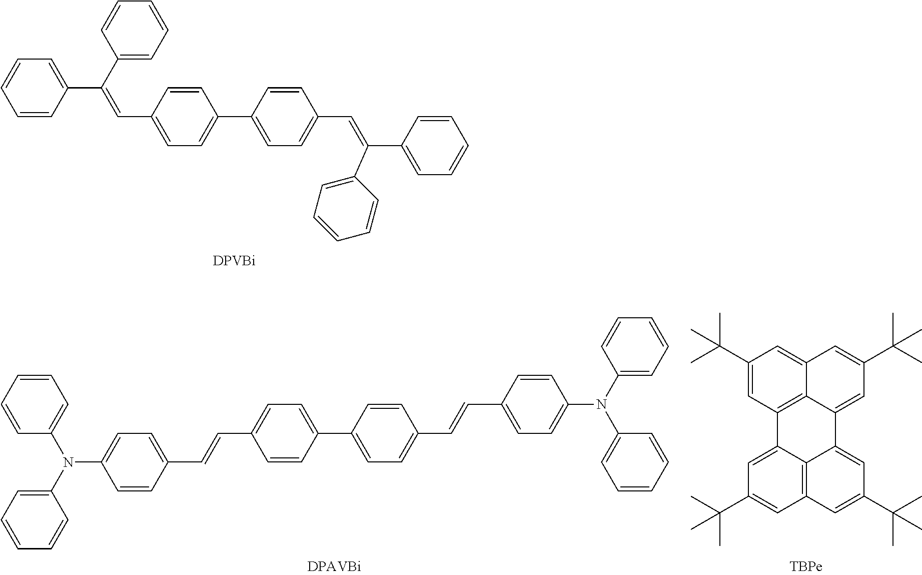

For example, compounds illustrated below may be used as a red dopant, but the red dopant is not limited thereto.

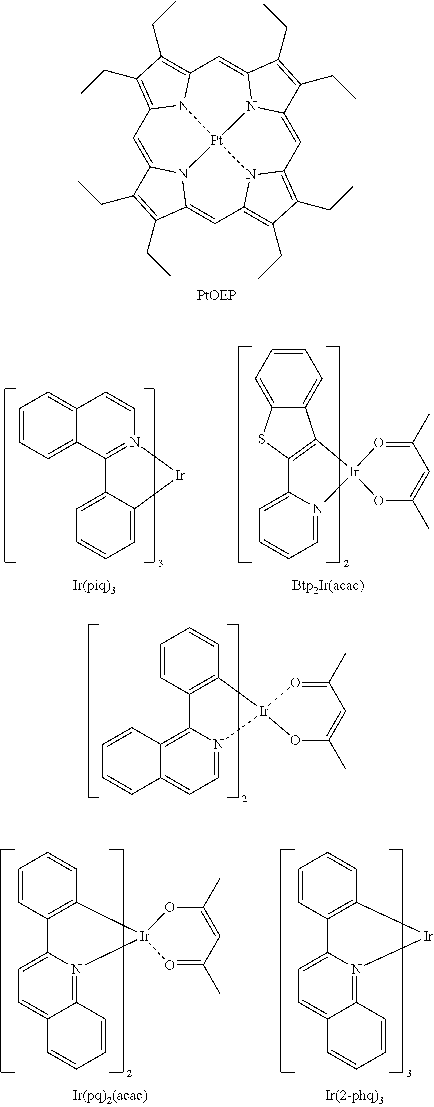

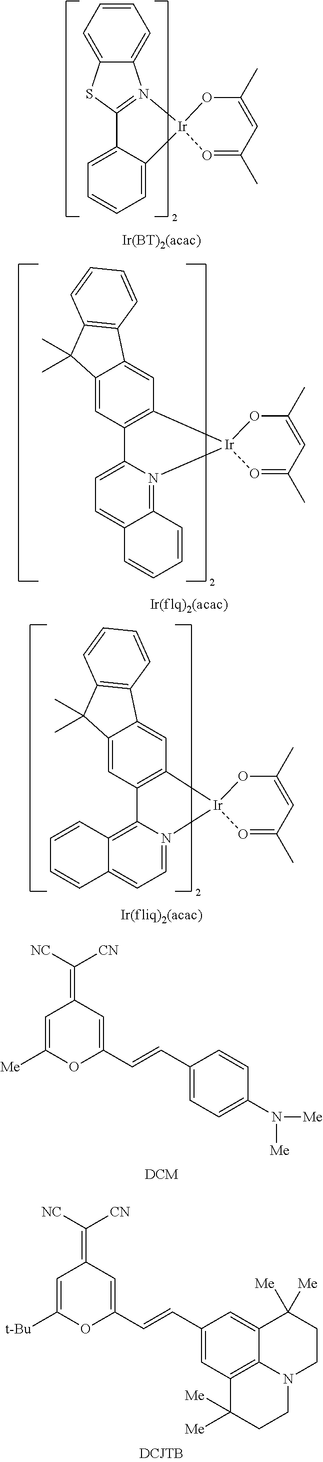

For example, compounds illustrated below may be used as a green dopant, but the green dopant is not limited thereto.

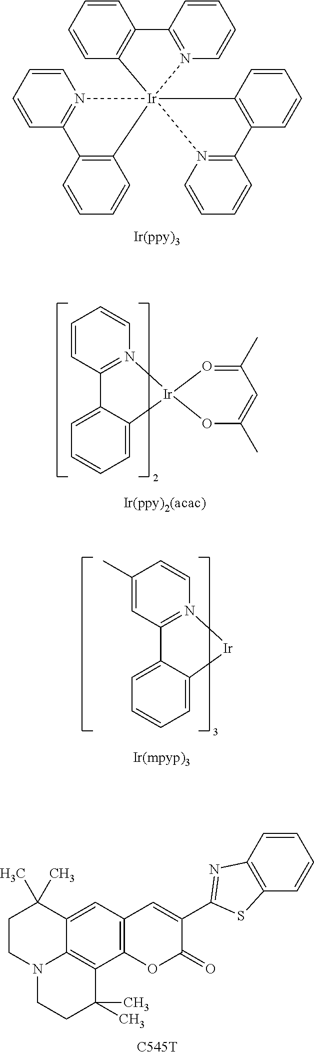

Also, a dopant included in the EML may be a Pd-complex or a Pt-complex, but is not limited thereto:

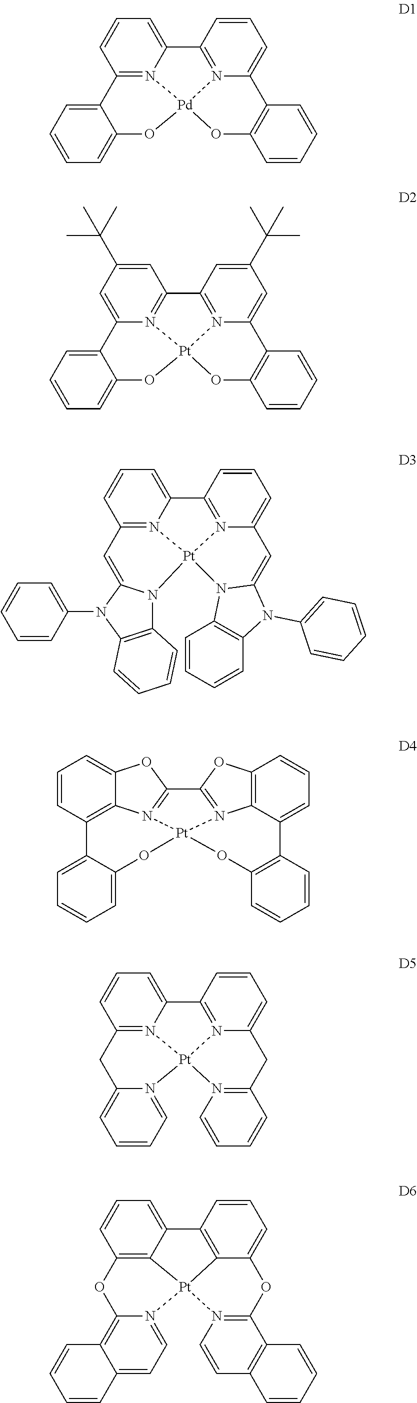

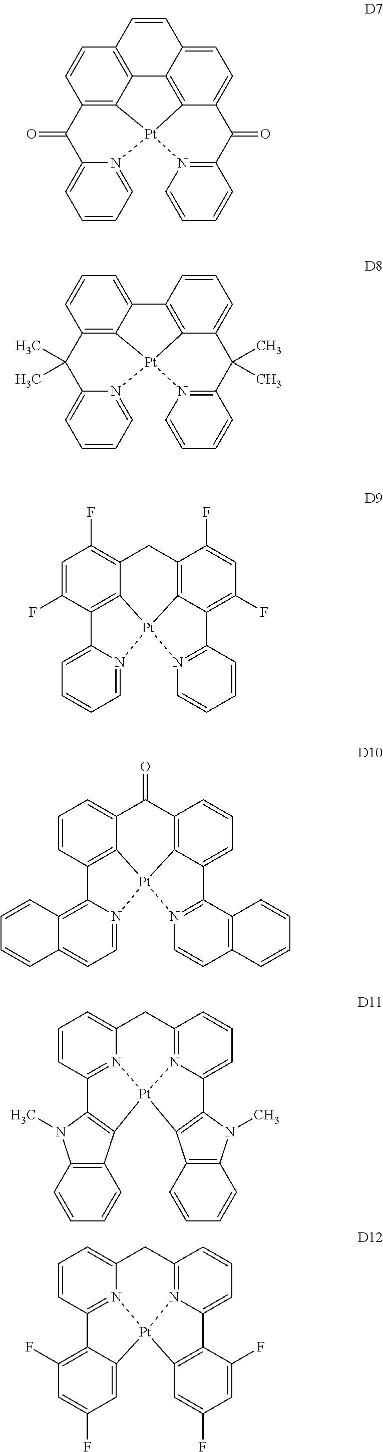

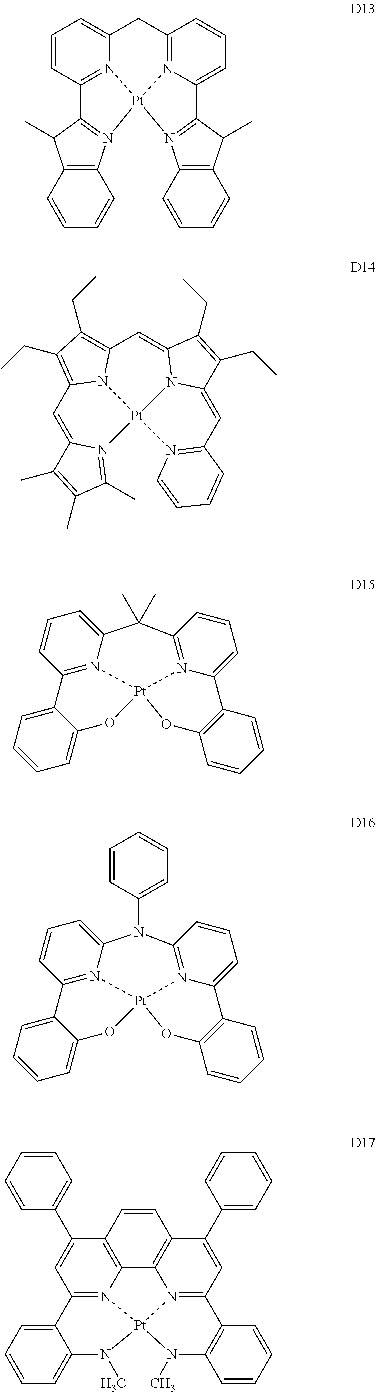

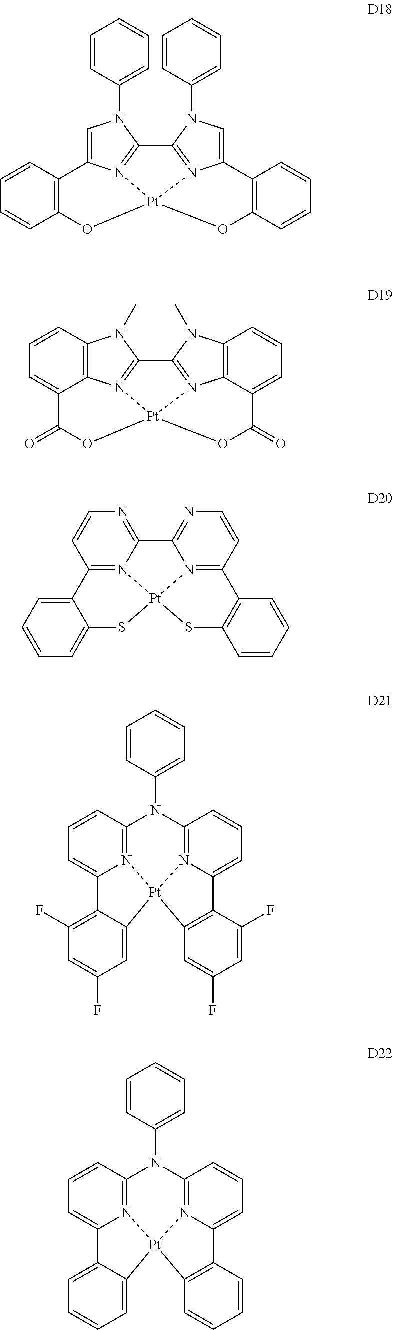

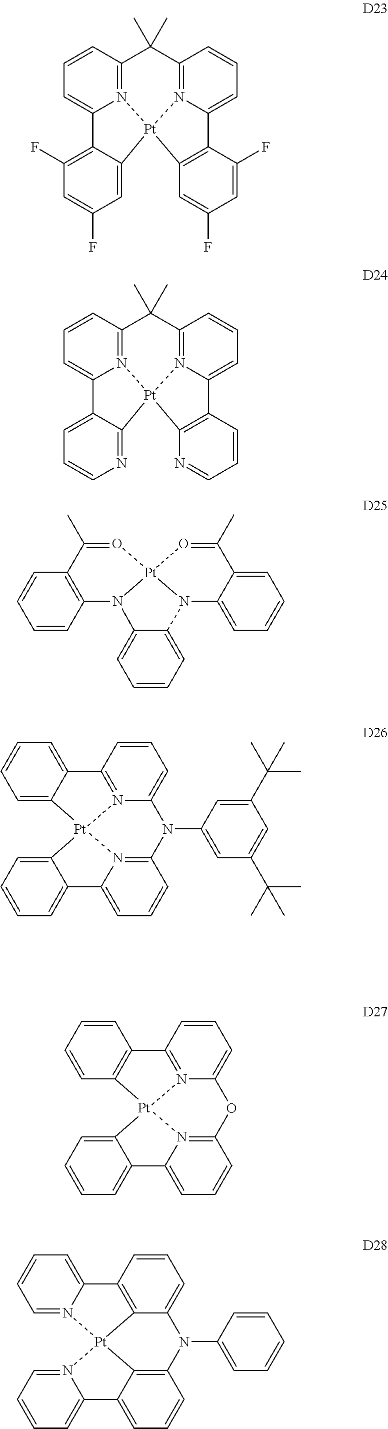

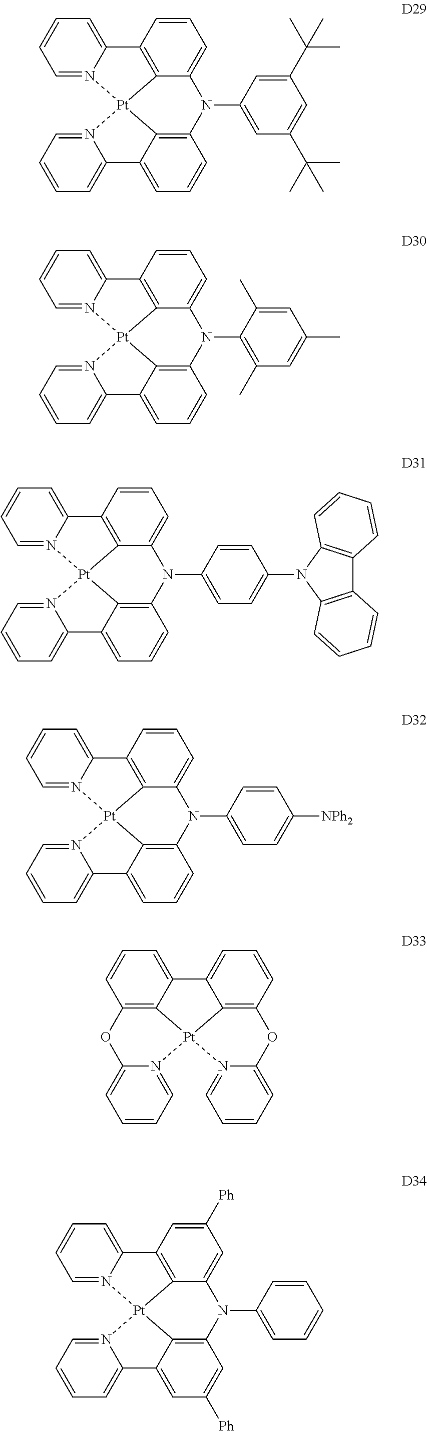

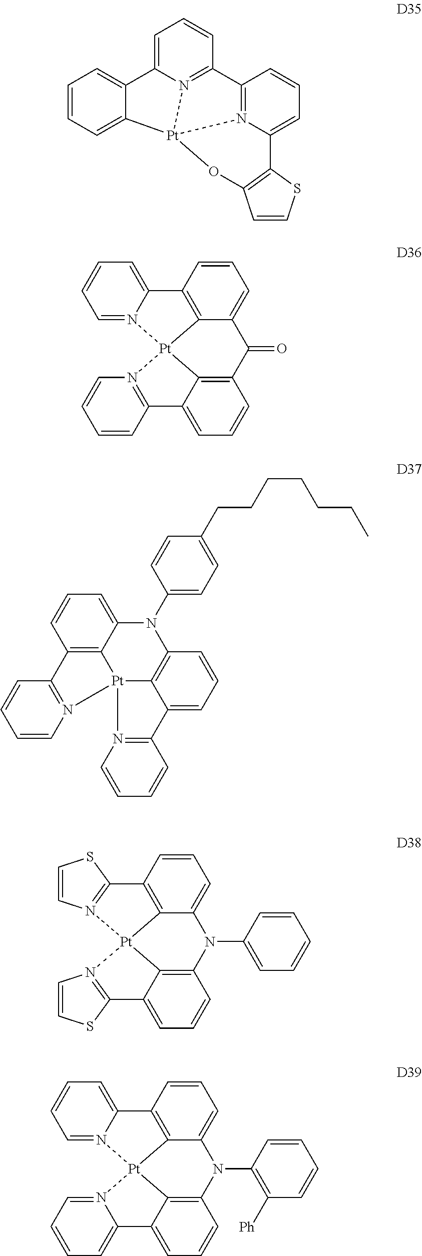

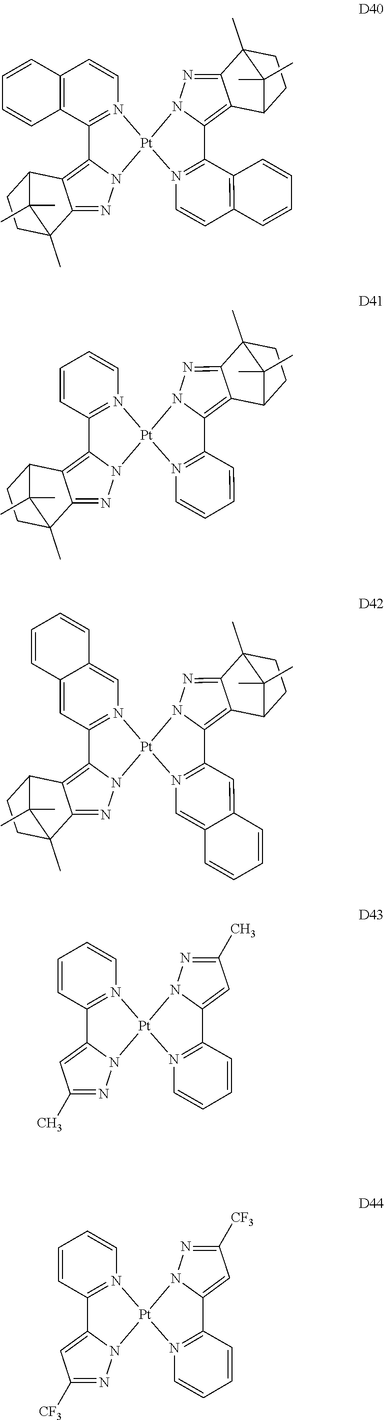

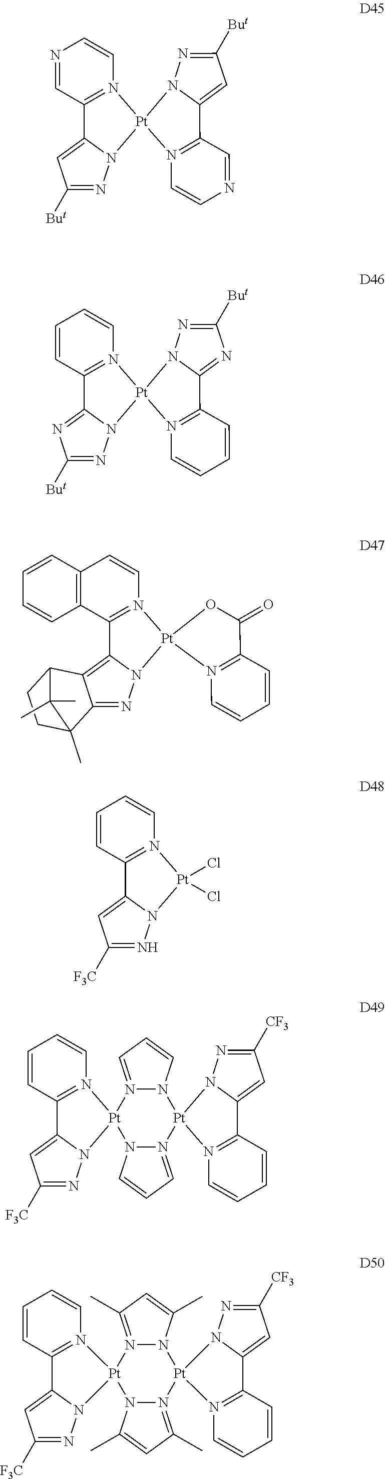

Also, a dopant included in the EML may be a Os-complex, but is not limited thereto:

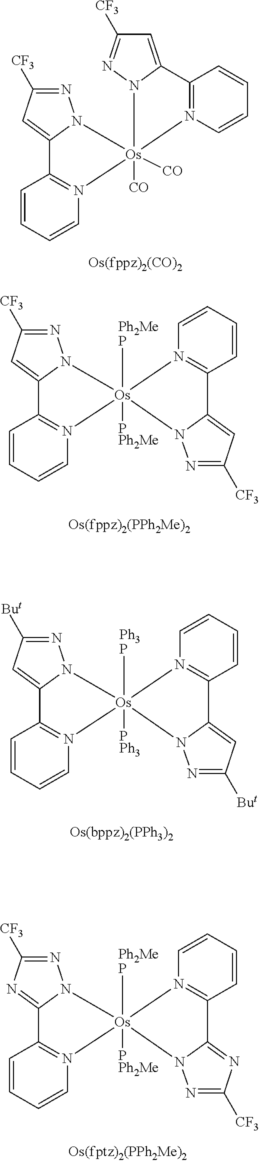

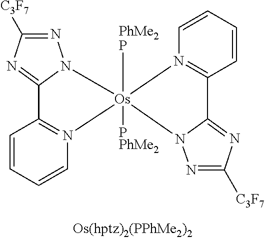

When the EML includes a host and a dopant, an amount of the dopant may be in a range of about 0.01 to about 15 parts by weight based on 100 parts by weight of the host, but is not limited thereto.

A thickness of the EML may be from about 100 Å to about 1000 Å, for example, about 200 Å to about 600 Å. In one embodiment, when the thickness of the EML is within this range, excellent emission characteristics are obtained without a substantial increase in driving voltage.

A layer, for example, a buffer layer, may be disposed between the EML and the electron transport layer. The layer may include the compound represented by Formula 1 according to an embodiment of the present invention.

Then, an electron transport layer (ETL) is formed on the EML or the layer by using various methods, such as vacuum deposition, spin coating, or casting. When the ETL is formed by vacuum deposition or spin coating, the deposition or coating conditions may be similar to those for the formation of the ETL, though the conditions for deposition or coating may vary according to the material that is used to form the EML. For use as an ETL material, to transport electrons injected from an electron injection electrode (cathode), the compound of Formula 1 according to an embodiment of the present invention or any suitable electron transport material may be used. Examples of suitable electron transport materials are a quinoline derivative, such as tris(8-quinolinolate)aluminum (Alq3), TAZ, Balq, beryllium bis (benzoquinolin-10-olate) (Bebq₂), ADN, Compound 203 to Compound 205 below, but are not limited thereto.

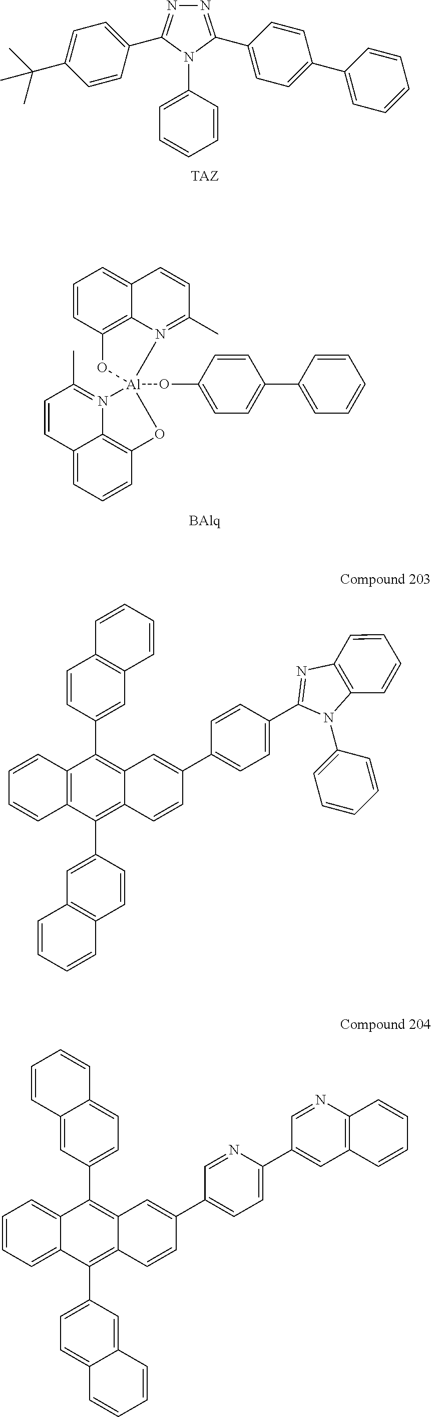

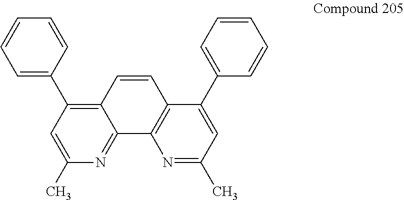 [SMILES: Cc1cc(-c2ccccc2)c2ccc3c(-c4ccccc4)cc(C)nc3c2n1]

A thickness of the ETL may be from about 100 Å to about 1000 Å, for example, about 150 Å to about 500 Å. In one embodiment, when the thickness of the ETL is within the ranges described above, excellent electron injection characteristics are obtained without a substantial increase in driving voltage.

Also, the electron transport layer may further include, in addition to the compound represented by Formula 1 according to an embodiment of the present invention or any suitable electron transport organic compound, a metal-containing material.

The metal-containing material may include a Li complex. Non-limiting examples of the Li complex are lithium quinolate (Compound 206: LiQ) or Compound 207 illustrated below.

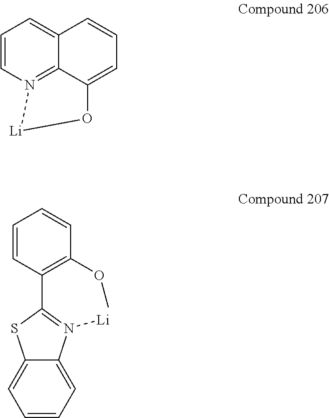

Also, an electron injection layer (EIL) may be formed on the ETL by depositing a material that allows electron to be easily provided from a cathode, and such a material is not limited, and may include the compound represented by Formula 1 according to an embodiment of the present invention.

As a material for forming the EIL, any suitable material that is used to form an EIL may be used. Examples thereof are LiF, NaCl, CsF, Li₂O, and BaO. The deposition conditions of the EIL may be similar to those used to form the HIL, although the deposition conditions may vary according to the material that is used to form the EIL.

A thickness of the EIL may be in a range of about 1 Å to about 100 Å, for example, about 3 Å to about 90 Å. In one embodiment, when the thickness of the EIL is within the ranges described above, excellent electron injection characteristics are obtained without a substantial increase in driving voltage.

A second electrode is disposed on the organic layer. The second electrode may be a cathode that is an electron injection electrode, and in this regard, as a metal for forming the second electrode, metal, alloy, an electric conductive compound, or a mixture thereof, each having a low work function, may be used. For example, lithium (Li), magnesium (Mg), aluminum (Al), aluminum-lithium (Al—Li), calcium (Ca), magnesium-indium (Mg—In), or magnesium-silver (Mg—Ag) may be formed as a thin film to form a transmissive electrode. Also, to obtain a top emission light-emitting device, a transmissive electrode formed of ITO or IZO may be used as the second electrode.

Hereinbefore, the organic light-emitting diode according to an embodiment of the present invention has been described in connection with FIG. 1.

Also, when the EML includes a phosphorescent dopant, to prevent the diffusion of a triplet exciton or hole into an electron transport layer, a hole blocking layer (HBL) may be formed between the ETL and the EML or between the E-functional layer and the EML by using various methods, such as vacuum deposition, spin coating, casting, or LB. When the HBL is formed by vacuum deposition or spin coating, the deposition or coating conditions may be similar to those for the formation of the EIL, though the conditions for deposition or coating may vary according to the material that is used to form the HBL. Any suitable hole blocking material may also be used herein, and examples thereof are an oxadiazol derivative, a triazole derivative, and a phenanthroline derivative. For example, BCP illustrated below may also be used as the hole blocking layer material.

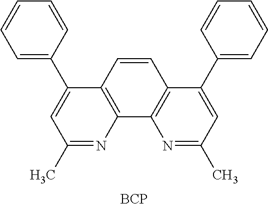

A thickness of the HBL may be from about 20 Å to about 1000 Å, for example, about 30 Å to about 300 Å. In one embodiment, when the thickness of the HBL is within this range, excellent emission characteristics are obtained without a substantial increase in driving voltage.

An organic light-emitting device according to an embodiment of the present invention may be used in various flat panel display apparatuses, such as a passive matrix organic light-emitting display apparatus or an active matrix organic light-emitting display apparatus. In particular, when the organic light-emitting diode is included in an active matrix organic light-emitting display apparatus, a first electrode disposed on a substrate acts as (or is patterned to correspond to) a pixel and may be electrically connected to a source electrode or a drain electrode of a thin film transistor. In addition, the organic light-emitting device may be included in a flat panel display apparatus that emits light in opposite directions.

Also, an organic layer according to an embodiment of the present invention may be formed by depositing the compound represented by Formulae 1 or 2 according to an embodiment of the present invention, or may be formed by using a wet method in which the compound represented by Formulae 1 or 2 according to an embodiment of the present invention is prepared in the form of a solution and then the solution of the compound is used for coating.

Hereinafter, one or more embodiments of the present invention will be described in more detail with reference to the following examples. These examples are not intended to limit the purpose and scope of the one or more embodiments of the present invention.

### SYNTHESIS EXAMPLE 1

### Synthesis of Compound 58

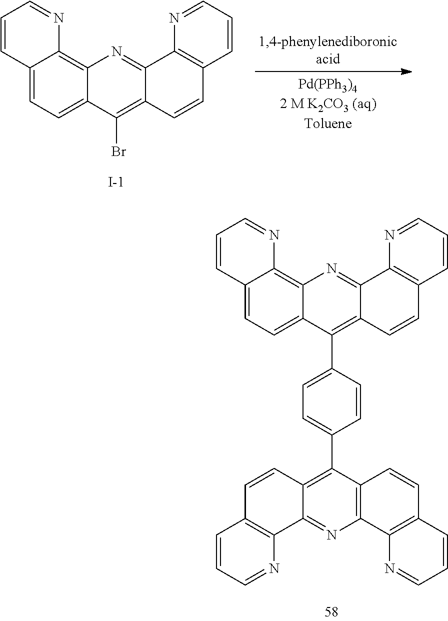 [SMILES: Brc1c2ccc3cccnc3c2nc2c1ccc1cccnc12 ; [I-] ; c1cnc2c(c1)ccc1c(-c3ccc(-c4c5ccc6cccnc6c5nc5c4ccc4cccnc45)cc3)c3ccc4cccnc4c3nc12]

5 g (13.88 mmol) of 7-bromoquinolino[8,7-b][1,10]phenanthroline, 1.10 g (6.66 mmol) of 1,4-phenylenediboronic acid, and 802 mg (0.69 mmol) of tetrakis(triphenylphosphine)palladium(0) were dissolved in 34 ml of 2 M K₂CO₃ (aq) and 50 nil of toluene, and then the mixture was stirred while refluxing at a temperature of 110° C. for 8 hours. When the reaction was completed, 40 ml of cold distilled water was added thereto, and the reaction solution was extracted by using ethylacetate. The extraction product was dried by using magnesium sulfate and filtered, and then, the solvent was removed therefrom by evaporation. Thereafter, 3.14 g (Yield: 74%) of Compound 58 (1,4-bis(quinolino[8,7-b][1,10]phenanthrolin-7-yl)benzene) was obtained by column chromatography.

¹H NMR (300 MHz, CDCl3), d (ppm): 9.00-8.75 (4H, m), 8.38-8.14 (4H, d), 7.93-7.87 (4H, s), 7.84-7.75 (8H, m), 7.47-7.39 (4H, t).

EI-MS, m/e, calcd for C44H24N6 636.21, found 636.25.

### SYNTHESIS EXAMPLE 2

### Synthesis of Compound 60

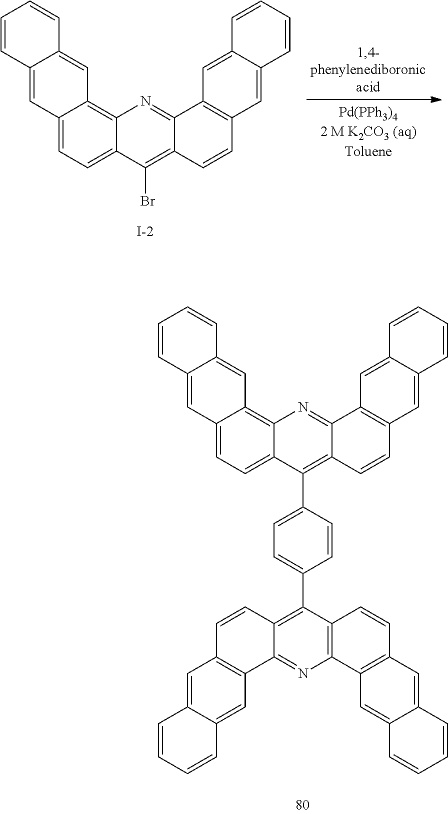

5 g (10.91 mmol) of 8-bromodinaphtho[2,3-c:2′,3′-h]acridine, 0.87 g (5.24 mmol) of 1,4-phenylenediboronic acid, and 630 mg (0.55 mmol) of tetrakis(triphenylphosphine)palladium(0) were dissolved in 27 ml of 2 M K₂CO₃(aq) and 50 ml of toluene, and then the mixture was stirred while refluxing at a temperature of 110° C. for 8 hours. When the reaction was completed, 40 ml of cold distilled water was added thereto, and the reaction solution was extracted by using ethylacetate. The extraction product was dried by using magnesium sulfate and filtered, and then, the solvent was removed therefrom by evaporation. Thereafter, 2.98 g (Yield: 68%) of Compound 60 (1,4-bis(dinaphtho[2,3-c:2′,3′-h]acridin-8-yl)benzene) was obtained by column chromatography.

¹H NMR (300 MHz, CDCl3), d (ppm): 9.05-8.99 (2H, m), 8.88-8.82 (2H, m), 8.72-8.67 (2H, m), 8.67-8.62 (2H, m), 8.45-8.39 (2H, m), 8.34-8.16 (6H, m), 8.15-8.08 (4H, m), 7.94-7.84 (6H, m), 7.83-7.74 (6H, m), 7.46-7.36 (4H, d).

EI-MS, m/e, calcd for C64H36N2 832.29, found 832.27.

### EXAMPLE 1

An anode was manufactured as follows: a corning 15 Ω/cm² ITO glass substrate for a top-emission device was cut to a size of 50 mm×50 mm×0.7 mm, and then, sonicated with isopropyl alcohol and pure water, each for 5 minutes, and then washed by irradiation of ultraviolet ray for 30 minutes and ozone, and the resultant glass substrate was provided to a vacuum deposition apparatus.

2-TNATA, which is a suitable hole injection material, was vacuum deposited on the substrate to form a HIL having a thickness of 600 Å, and then, 4,4′-bis[N-(1-naphthyl)-N-phenylamino]biphenyl (NPB), which is a suitable hole transportation compound, was vacuum deposited thereon to form a HTL having a thickness of 300 Å.

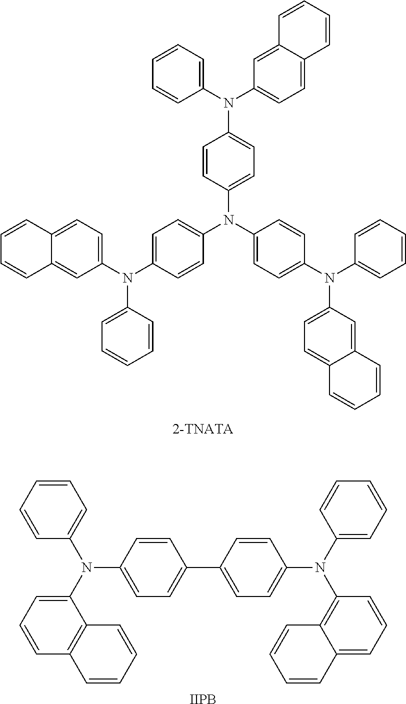

On the HTL, ADN, which is a suitable blue fluorescent host, and Compound 104, which is a suitable blue fluorescent dopant, were co-deposited at a weight ratio of 98:2 to form an EML having a thickness of 300 Å. Subsequently, Compound 42 (the synthesis of this compound is disclosed in EP 2,395,571, the content of which is incorporated herein by reference in its entirety) was co-deposited with Compound 206 on the EML to form an ETL having a thickness of 300 Å, and then, LiF, which is a halogenated alkali metal, was deposited on the ETL to form an EIL having a thickness of 10 Å, and Al was vacuum deposited to form a cathode having a thickness of 200 Å to form a LiF/Al electrode, thereby completing the manufacturing of an organic electroluminescent light-emitting device.

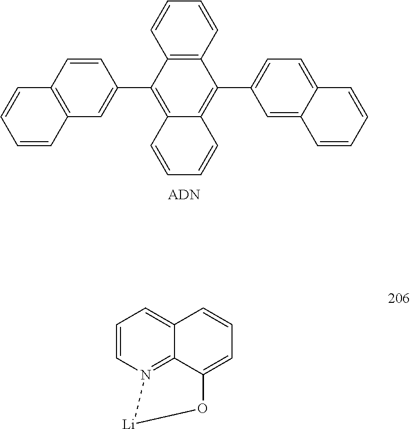

### EXAMPLE 2

An organic light-emitting device was manufactured in the same manner as in Example 1, except that in forming the ETL, Compound 52, which is a suitable electron transport material, was used instead of Compound 42.

### EXAMPLE 3

An organic light-emitting device was manufactured in the same manner as in Example 1, except that in forming the ETL, Compound 56, which is a suitable electron transport material, was used instead of Compound 42.

### EXAMPLE 4

An organic light-emitting device was manufactured in the same manner as in Example 1, except that in forming the ETL, Compound 58, which is a suitable electron transport material, was used instead of Compound 42.

### EXAMPLE 5

An organic light-emitting device was manufactured in the same manner as in Example 1, except that in forming the ETL, Compound 60, which is a suitable electron transport material, was used instead of Compound 42.

### EXAMPLE 6

An organic light-emitting device was manufactured in the same manner as in Example 1, except that as a blue dopant, Compound 106, which is a suitable blue dopant material, was used instead of Compound 104.

### EXAMPLE 7

An organic light-emitting device was manufactured in the same manner as in Example 1, except that as a blue dopant, Compound 116, which is a suitable blue dopant material, was used instead of Compound 104.

### EXAMPLE 8

An organic light-emitting device was manufactured in the same manner as in Example 1, except that as a blue dopant, Compound 145, which is a suitable blue dopant material, was used instead of Compound 104.

### EXAMPLE 9

An organic light-emitting device was manufactured in the same manner as in Example 1, except that as a blue dopant, Compound 153, which is a suitable blue dopant material, was used instead of Compound 104.

### EXAMPLE 10

An organic light-emitting device was manufactured in the same manner as in Example 1, except that as a blue dopant, Compound 161, which is a suitable blue dopant material, was used instead of Compound 104.

### COMPARATIVE EXAMPLE 1

An organic EL device was manufactured in the same manner as in Example 1, except that in forming the ETL, Compound 203 was used instead of Compound 42.

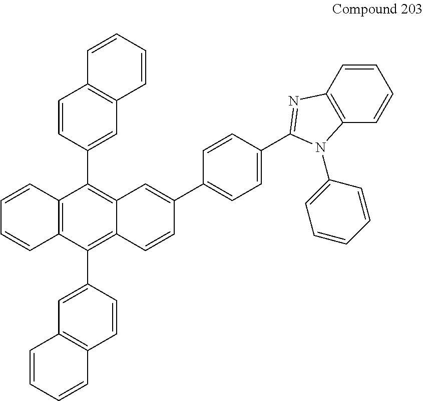 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

### COMPARATIVE EXAMPLE 2

An organic light-emitting device was manufactured in the same manner as in Example 1, except that as a blue phosphorescent dopant, Compound 500, which is a suitable blue phosphorescent dopant material, was used instead of Compound 104.

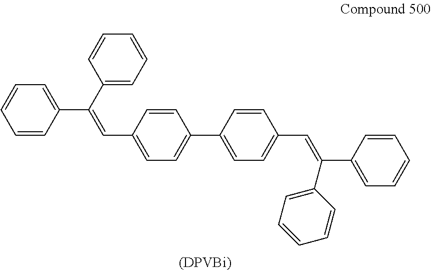 [SMILES: C(=C(c1ccccc1)c1ccccc1)c1ccc(-c2ccc(C=C(c3ccccc3)c3ccccc3)cc2)cc1 ; "(DPVBi)"]

### COMPARATIVE EXAMPLE 3

An organic light-emitting device was manufactured in the same manner as in Example 1, except that in forming the ETL, Compound 203 was used instead of Compound 42, and as a blue phosphorescent dopant, Compound 500 was used instead of Compound 203.

Characteristics and lifespan results of the respective devices of Examples are shown in Table 1.

TABLE 1

| | Driving | | | |
|---|---|---|---|---|
| Organic light- | Voltage | Brightness | | |
| emitting device | (V) | [cd/m2] | Efficiency (cd/A) | Lifespan |
| Experimental | 3.7 | 383 | 3.83 | three times |
| Example 1 | | | | increase |
| Experimental | 3.8 | 412 | 4.12 | three times |
| Example 2 | | | | increase |
| Experimental | 3.9 | 395 | 3.95 | three times |
| Example 3 | | | | increase |
| Experimental | 4.0 | 408 | 4.08 | three times |
| Example 4 | | | | increase |
| Experimental | 3.9 | 377 | 3.77 | three times |
| Example 5 | | | | increase |
| Experimental | 3.8 | 365 | 3.65 | 2.5 times |
| Example 6 | | | | increase |
| Experimental | 3.8 | 351 | 3.51 | 2.5 times |
| Example 7 | | | | increase |
| Experimental | 4.1 | 340 | 3.40 | 2.5 times |
| Example 8 | | | | increase |
| Experimental | 4.0 | 376 | 3.76 | 2.5 times |
| Example 9 | | | | increase |
| Experimental | 3.8 | 389 | 2.89 | 2.5 times |
| Example 10 | | | | increase |
| Comparative | 4.5 | 254 | 2.54 | Reference |
| Example 1 | | | | lifespan |
| Comparative | 4.4 | 241 | 2.41 | 1.5 times |
| Example 2 | | | | increase |
| Comparative | 4.7 | 223 | 2.23 | 0.5 times |
| Example 3 | | | | decrease |

FIG. 2 is a graph of lifespan of the organic light-emitting devices manufactured according to Example 1 and Comparative Example 1. Referring to FIG. 2, it was confirmed that an organic light-emitting device according to an embodiment of the present invention has a substantially long lifespan than the devices according to the Comparative Examples.

As described above, according to the one or more of the above embodiments of the present invention, the heterocyclic compound represented by Formula 1 is suitable for an electron injection layer, an electron transport layer, or a functional layer having an electron injection capability and an electron transport capability. When the heterocyclic compound is used, an organic light-emitting device having a long lifespan is obtained.

It should be understood that the example embodiments described therein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims, and equivalents thereof.

What is claimed is:

1. An organic light-emitting device comprising:
a first electrode;
a second electrode; and
an organic layer between the first electrode and the second electrode,
wherein the organic layer comprises:
an emission layer comprising a compound represented by Formula 2 below; and
a second layer comprising a heterocyclic compound represented by Formula 1 below either between the emission layer and the first electrode or between the emission layer and the second electrode: 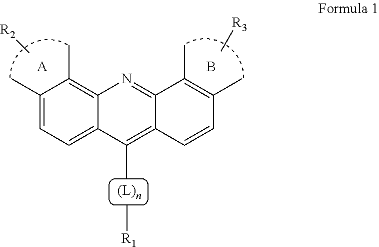
wherein in Formula 1,
R₁ to R₃ are each independently a hydrogen atom, a deuterium atom, a halogen atom, a cyano group, a substituted or unsubstituted C₁-C₆₀ alkyl group, a substituted or unsubstituted C₆-C₆₀ aryl group, a substituted or unsubstituted C₂-C₆₀ heteroaryl group, or a substituted or unsubstituted C₆-C₆₀ condensation polycyclic group;
L is a substituted or unsubstituted C₆-C₆₀ arylene group or a substituted or unsubstituted C₂-C₆₀ heteroarylene group;
n is an integer of 0 to 3; and
A and B are each independently a substituted or unsubstituted C₆-C₆₀ aryl group or a substituted or unsubstituted C₂-C₆₀ heteroaryl group, each of which is fused to the back bone of Formula 1; 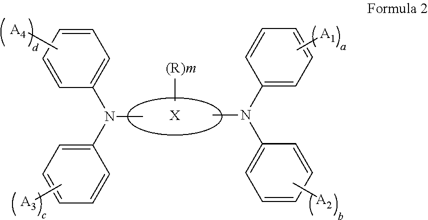
wherein in Formula 2,
A₁ to A₄, and R are each independently a hydrogen atom, a deuterium atom, a cyano group, a halogen atom, a substituted silyl group, a substituted or unsubstituted C₁-C₆₀ alkyl group, a substituted or unsubstituted C₆-C₆₀ aryl group, or a substituted or unsubstituted C₃-C₆₀ cycloalkyl group;
X is a substituted or unsubstituted C₆-C₆₀ arylene group, or a substituted or unsubstituted C₂-C₆₀ heteroarylene group; and
a, b, c, d and m are each independently an integer of 1 to 10.

2. The organic light-emitting device of claim 1, wherein
A and B are each independently a substituted or unsubstituted phenyl group, a substituted or unsubstituted naphthyl group, or a substituted or unsubstituted pyridine group.

3. The organic light-emitting device of claim 2, wherein
the substituted or unsubstituted naphthyl group is fused with the back bone of Formula 1 at site 2 and site 3 of Formula 1-1 below:

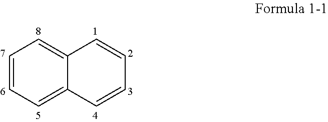

4. The organic light-emitting device of claim 2, wherein
the substituted or unsubstituted pyridine group is fused with the back bone of Formula 1 at site 2 and site 3 of Formula 1-2 below:

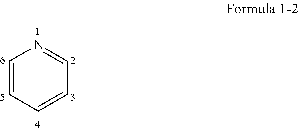

5. The organic light-emitting device of claim 1, wherein
R₂ and R₃ are each independently a hydrogen atom, a deuterium atom, or a group represented by Formula 2a below: 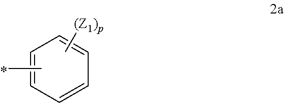
wherein in Formula 2a,
Z₁ is a hydrogen atom, a deuterium atom, a substituted or unsubstituted C₁ to C₂₀ alkyl group, a substituted or unsubstituted C₆ to C₂₀ aryl group, a substituted or unsubstituted C₂ to C₂₀ heteroaryl group, a substituted or unsubstituted C₆ to C₂₀ condensed polycyclic group, an amino group substituted with a C₆ to C₂₀ aryl group or a C₂ to C₂₀ heteroaryl group, a halogen atom, a cyano group, a nitro group, a hydroxyl group, or a carboxy group;
p is an integer of 1 to 5; and
* indicates a binding site.

6. The organic light-emitting device of claim 1, wherein
L is a phenylene group or a pyridine group.

7. The organic light-emitting device of claim 1, wherein
R₁ is a hydrogen atom, a deuterium atom, or a group represented by any one of Formulae 3a to 3g below: 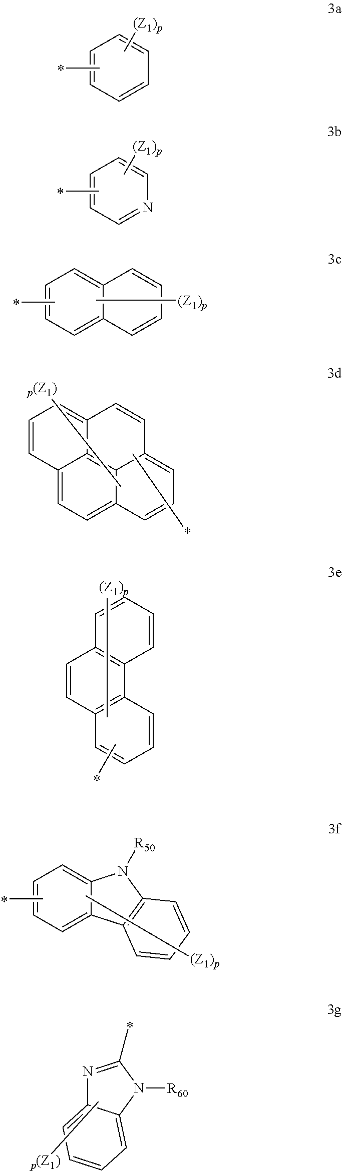
wherein in Formulae 3a to 3g,
Z₁, R₅₀, and R₆₀ are each independently a hydrogen atom, a deuterium atom, a substituted or unsubstituted C₁ to C₂₀ alkyl group, a substituted or unsubstituted C₆ to C₂₀ aryl group, a substituted or unsubstituted C₂ to C₂₀ heteroaryl group, a substituted or unsubstituted C₆ to C₂₀ condensed polycyclic group, an amino group substituted with a C₆ to C₂₀ aryl group or a C₂ to C₂₀ heteroaryl group, a halogen atom, a cyano group, a nitro group, a hydroxyl group, or a carboxy group;
p is an integer of 1 to 9; and
* indicates a binding site.

8. The organic light-emitting device of claim 1, wherein
R₁ is a compound represented by Formula 3 below:

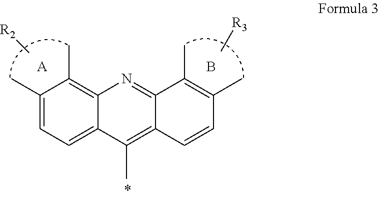

9. The organic light-emitting device of claim 1, wherein
the compound of Formula 1 is any one of the compounds below:

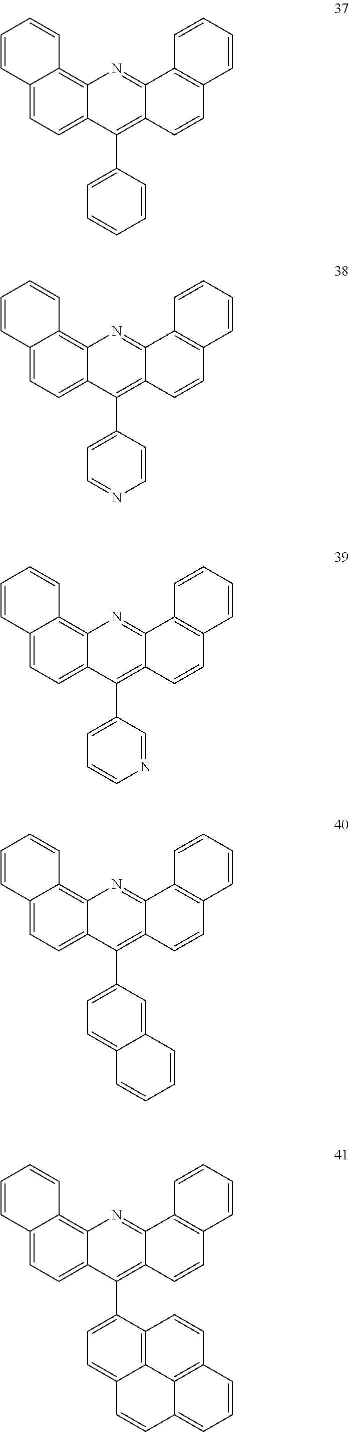 [SMILES: c1ccc(-c2c3ccc4ccccc4c3nc3c2ccc2ccccc23)cc1 ; c1ccc2c(c1)ccc1c(-c3ccncc3)c3ccc4ccccc4c3nc12 ; c1cncc(-c2c3ccc4ccccc4c3nc3c2ccc2ccccc23)c1 ; c1ccc2cc(-c3c4ccc5ccccc5c4nc4c3ccc3ccccc34)ccc2c1 ; c1ccc2c(c1)ccc1c(-c3ccc4ccc5cccc6ccc3c4c56)c3ccc4ccccc4c3nc12]

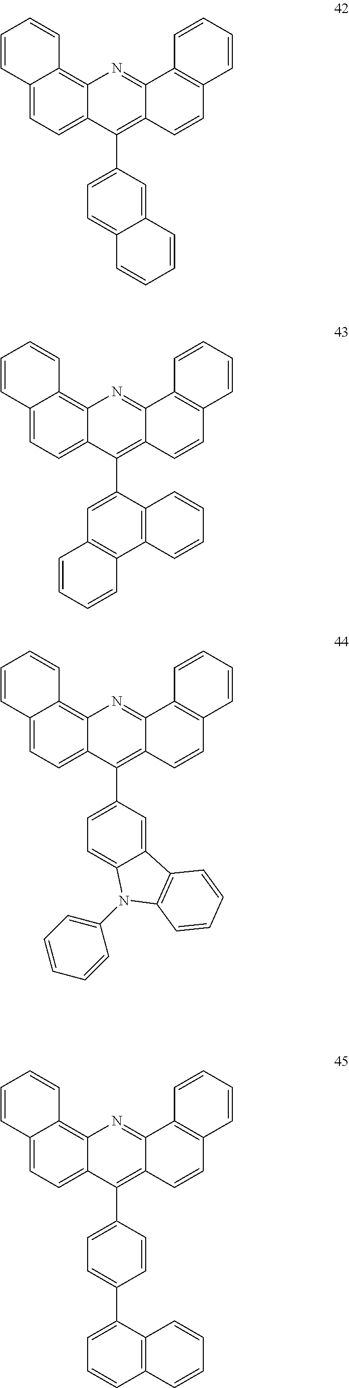 [SMILES: c1ccc2cc(-c3c4ccc5ccccc5c4nc4c3ccc3ccccc34)ccc2c1 ; c1ccc2c(c1)cc(-c1c3ccc4ccccc4c3nc3c1ccc1ccccc13)c1ccccc12 ; c1ccc(-n2c3ccccc3c3cc(-c4c5ccc6ccccc6c5nc5c4ccc4ccccc45)ccc32)cc1 ; c1ccc2c(-c3ccc(-c4c5ccc6ccccc6c5nc5c4ccc4ccccc45)cc3)cccc2c1]

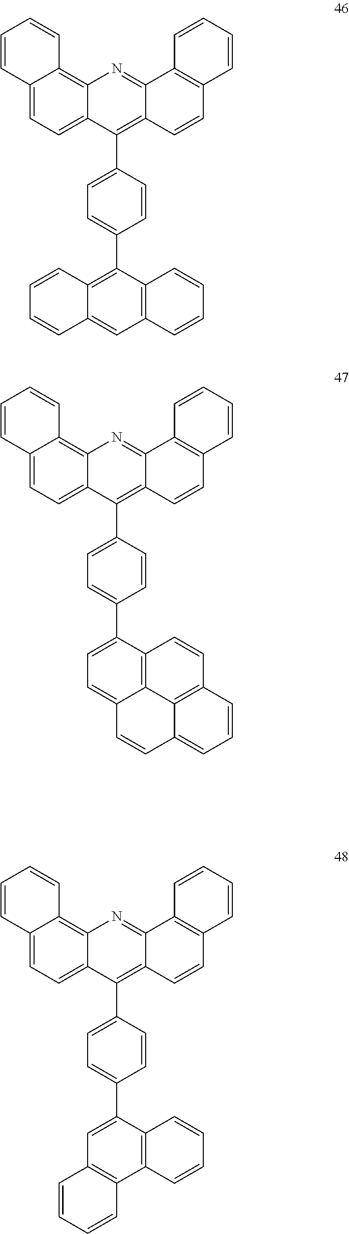 [SMILES: c1ccc2c(-c3ccc(-c4c5ccc6ccccc6c5nc5c4ccc4ccccc45)cc3)c3ccccc3cc2c1 ; c1ccc2c(c1)ccc1c(-c3ccc(-c4ccc5ccc6cccc7ccc4c5c67)cc3)c3ccc4ccccc4c3nc12 ; c1ccc2c(c1)cc(-c1ccc(-c3c4ccc5ccccc5c4nc4c3ccc3ccccc34)cc1)c1ccccc12]

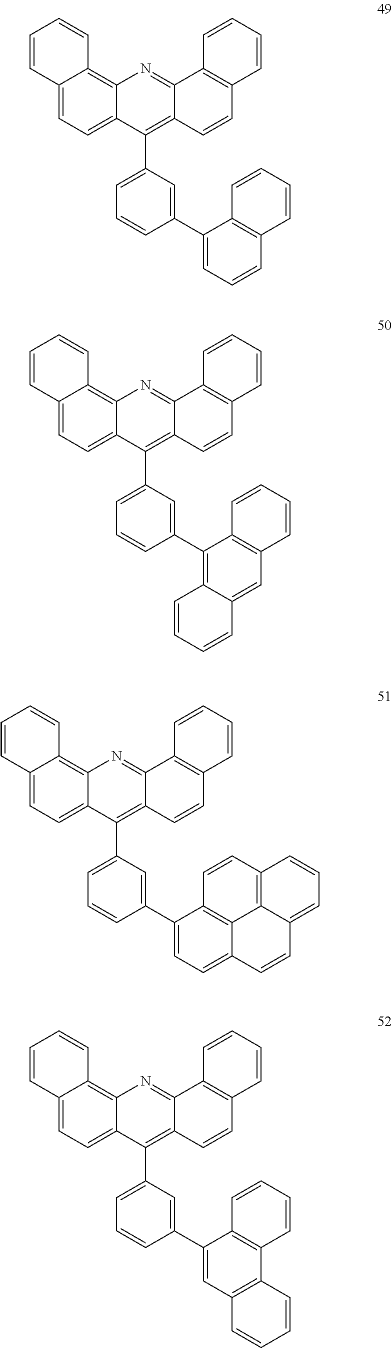 [SMILES: c1cc(-c2cccc3ccccc23)cc(-c2c3ccc4ccccc4c3nc3c2ccc2ccccc23)c1 ; c1cc(-c2c3ccccc3cc3ccccc23)cc(-c2c3ccc4ccccc4c3nc3c2ccc2ccccc23)c1 ; c1cc(-c2c3ccc4ccccc4c3nc3c2ccc2ccccc23)cc(-c2ccc3ccc4cccc5ccc2c3c45)c1 ; c1cc(-c2cc3ccccc3c3ccccc23)cc(-c2c3ccc4ccccc4c3nc3c2ccc2ccccc23)c1]

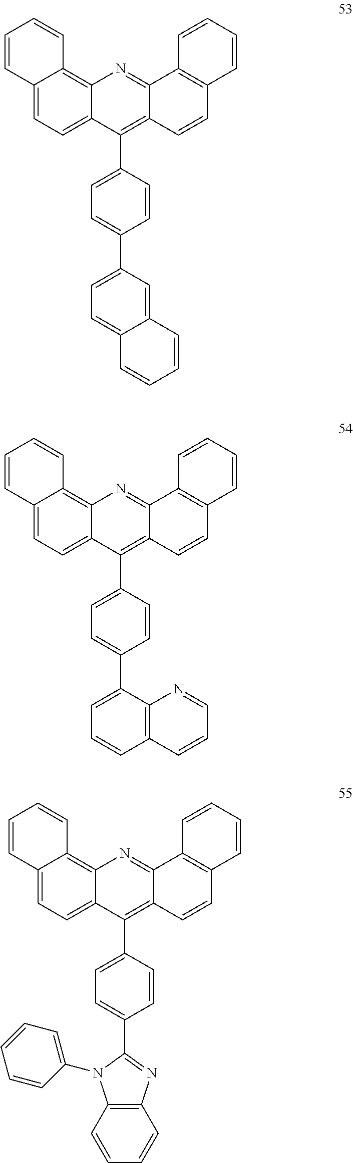 [SMILES: c1ccc2cc(-c3ccc(-c4c5ccc6ccccc6c5nc5c4ccc4ccccc45)cc3)ccc2c1 ; c1cnc2c(-c3ccc(-c4c5ccc6ccccc6c5nc5c4ccc4ccccc45)cc3)cccc2c1 ; c1ccc(-n2c(-c3ccc(-c4c5ccc6ccccc6c5nc5c4ccc4ccccc45)cc3)nc3ccccc32)cc1]

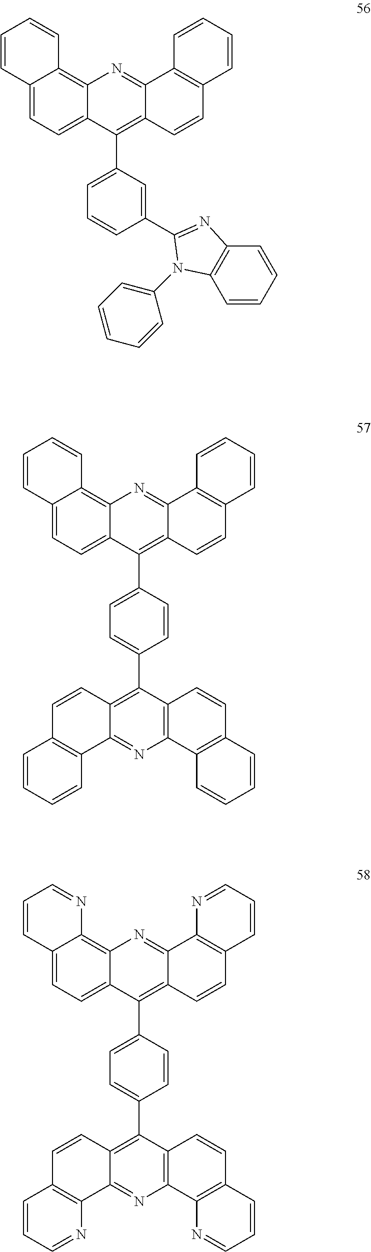 [SMILES: c1ccc(-n2c(-c3cccc(-c4c5ccc6ccccc6c5nc5c4ccc4ccccc45)c3)nc3ccccc32)cc1 ; c1ccc2c(c1)ccc1c(-c3ccc(-c4c5ccc6ccccc6c5nc5c4ccc4ccccc45)cc3)c3ccc4ccccc4c3nc12 ; c1cnc2c(c1)ccc1c(-c3ccc(-c4c5ccc6cccnc6c5nc5c4ccc4cccnc45)cc3)c3ccc4cccnc4c3nc12]

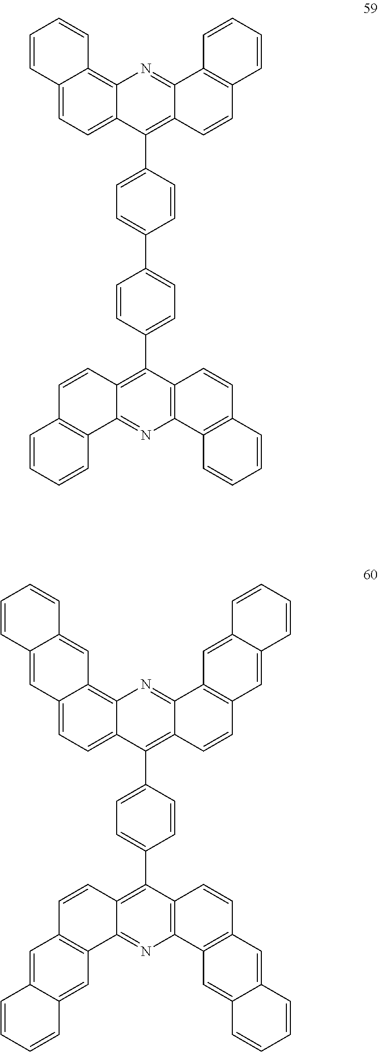 [SMILES: c1ccc2c(c1)ccc1c(-c3ccc(-c4ccc(-c5c6ccc7ccccc7c6nc6c5ccc5ccccc56)cc4)cc3)c3ccc4ccccc4c3nc12 ; c1ccc2cc3c(ccc4c(-c5ccc(-c6c7ccc8cc9ccccc9cc8c7nc7c6ccc6cc8ccccc8cc67)cc5)c5ccc6cc7ccccc7cc6c5nc43)cc2c1]

10. The organic light-emitting device of claim 1, wherein
X in Formula 2 is a substituted or unsubstituted pyrene, a substituted or unsubstituted anthracene, a substituted or unsubstituted phenanthroline, a substituted or unsubstituted benzopyrene, or a substituted or unsubstituted chrysene.

11. The organic light-emitting device of claim 1, wherein
A₁ to A₄ and R in Formula 2 are each independently a hydrogen atom, a deuterium atom, a halogen atom, a substituted silyl group, a substituted or unsubstituted C₁-C₆₀ alkyl group, a substituted or unsubstituted C₆-C₆₀ aryl group, a substituted or unsubstituted C₂-C₆₀ heteroaryl, or a substituted or unsubstituted C₆-C₆₀ condensation polycyclic group.

12. The organic light-emitting device of claim 1, wherein
at least one of A₁ to A₄ in Formula 2 is represented by Formula 4 below: 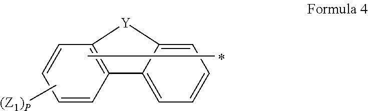
wherein in Formula 4,
Y indicates NR₁₁, —O—, or —S—;
Z₁ and R₁₁ are each independently a hydrogen atom, a deuterium atom, a cyano group, a halogen atom, a substituted or unsubstituted C₁-C₄₀ alkyl group, a substituted or unsubstituted C₆-C₄₀ aryl group, or a substituted or unsubstituted C₃-C₄₀ cycloalkyl group, and
p is an integer of 1 to 7; and
when the number of Z₁ is 2 or more, a plurality of Z₁ are different from or identical to each other; and
* indicates a binding site.

13. The organic light-emitting device of claim 1, wherein
the compound of Formula 2 is any one of the following compounds:

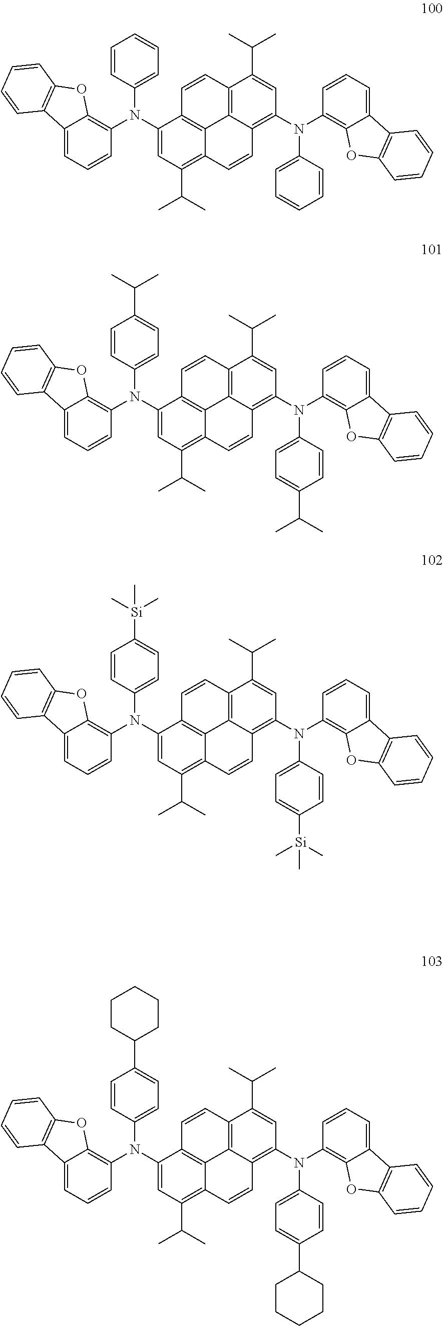 [SMILES: CC(C)c1cc(N(c2ccccc2)c2cccc3c2oc2ccccc23)c2ccc3c(C(C)C)cc(N(c4ccccc4)c4cccc5c4oc4ccccc45)c4ccc1c2c34 ; CC(C)c1ccc(N(c2cc(C(C)C)c3ccc4c(N(c5ccc(C(C)C)cc5)c5cccc6c5oc5ccccc56)cc(C(C)C)c5ccc2c3c54)c2cccc3c2oc2ccccc23)cc1 ; CC(C)c1cc(N(c2ccc([Si](C)(C)C)cc2)c2cccc3c2oc2ccccc23)c2ccc3c(C(C)C)cc(N(c4ccc([Si](C)(C)C)cc4)c4cccc5c4oc4ccccc45)c4ccc1c2c34 ; CC(C)c1cc(N(c2ccc(C3CCCCC3)cc2)c2cccc3c2oc2ccccc23)c2ccc3c(C(C)C)cc(N(c4ccc(C5CCCCC5)cc4)c4cccc5c4oc4ccccc45)c4ccc1c2c34]

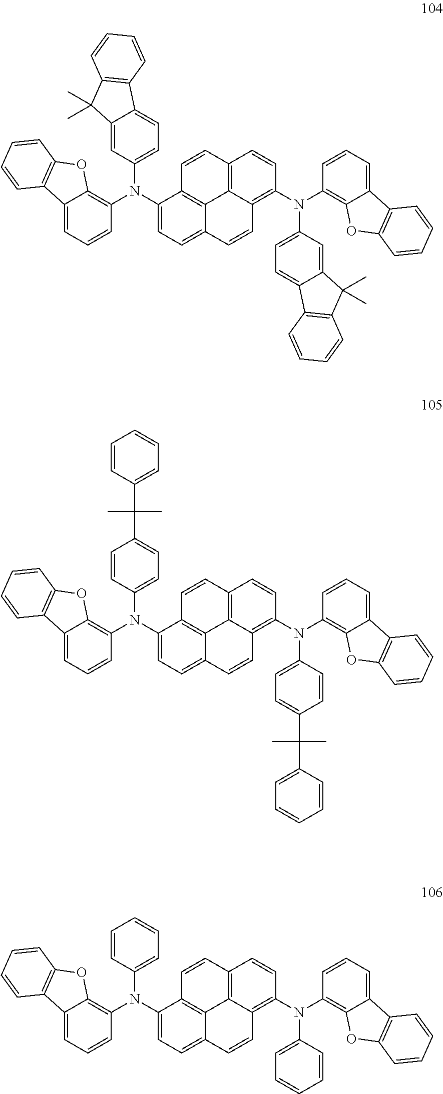 [SMILES: CC1(C)c2ccccc2-c2ccc(N(c3ccc4ccc5c(N(c6ccc7c(c6)C(C)(C)c6ccccc6-7)c6cccc7c6oc6ccccc67)ccc6ccc3c4c65)c3cccc4c3oc3ccccc34)cc21 ; CC(C)(c1ccccc1)c1ccc(N(c2ccc3ccc4c(N(c5ccc(C(C)(C)c6ccccc6)cc5)c5cccc6c5oc5ccccc56)ccc5ccc2c3c54)c2cccc3c2oc2ccccc23)cc1 ; c1ccc(N(c2ccc3ccc4c(N(c5ccccc5)c5cccc6c5oc5ccccc56)ccc5ccc2c3c54)c2cccc3c2oc2ccccc23)cc1]

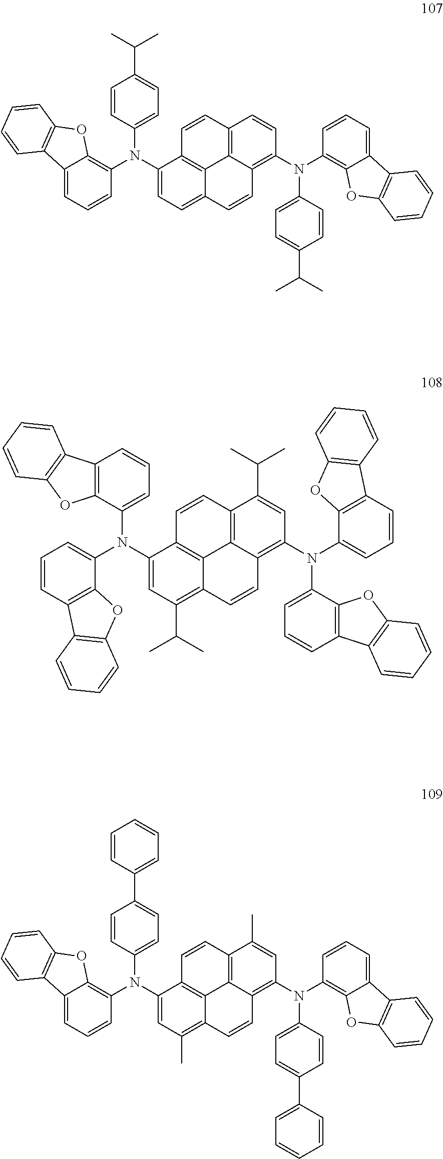 [SMILES: CC(C)c1ccc(N(c2ccc3ccc4c(N(c5ccc(C(C)C)cc5)c5cccc6c5oc5ccccc56)ccc5ccc2c3c54)c2cccc3c2oc2ccccc23)cc1 ; CC(C)c1cc(N(c2cccc3c2oc2ccccc23)c2cccc3c2oc2ccccc23)c2ccc3c(C(C)C)cc(N(c4cccc5c4oc4ccccc45)c4cccc5c4oc4ccccc45)c4ccc1c2c34 ; Cc1cc(N(c2ccc(-c3ccccc3)cc2)c2cccc3c2oc2ccccc23)c2ccc3c(C)cc(N(c4ccc(-c5ccccc5)cc4)c4cccc5c4oc4ccccc45)c4ccc1c2c34]

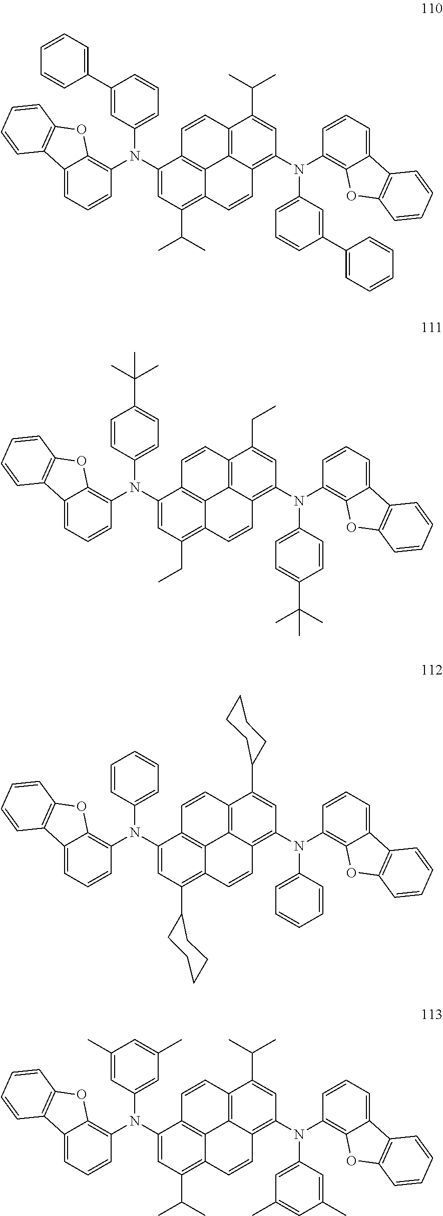 [SMILES: CC(C)c1cc(N(c2cccc(-c3ccccc3)c2)c2cccc3c2oc2ccccc23)c2ccc3c(C(C)C)cc(N(c4cccc(-c5ccccc5)c4)c4cccc5c4oc4ccccc45)c4ccc1c2c34 ; CCc1cc(N(c2ccc(C(C)(C)C)cc2)c2cccc3c2oc2ccccc23)c2ccc3c(CC)cc(N(c4ccc(C(C)(C)C)cc4)c4cccc5c4oc4ccccc45)c4ccc1c2c34 ; c1ccc(N(c2cc(C3CCCCC3)c3ccc4c(N(c5ccccc5)c5cccc6c5oc5ccccc56)cc(C5CCCCC5)c5ccc2c3c54)c2cccc3c2oc2ccccc23)cc1 ; Cc1cc(C)cc(N(c2cc(C(C)C)c3ccc4c(N(c5cc(C)cc(C)c5)c5cccc6c5oc5ccccc56)cc(C(C)C)c5ccc2c3c54)c2cccc3c2oc2ccccc23)c1]

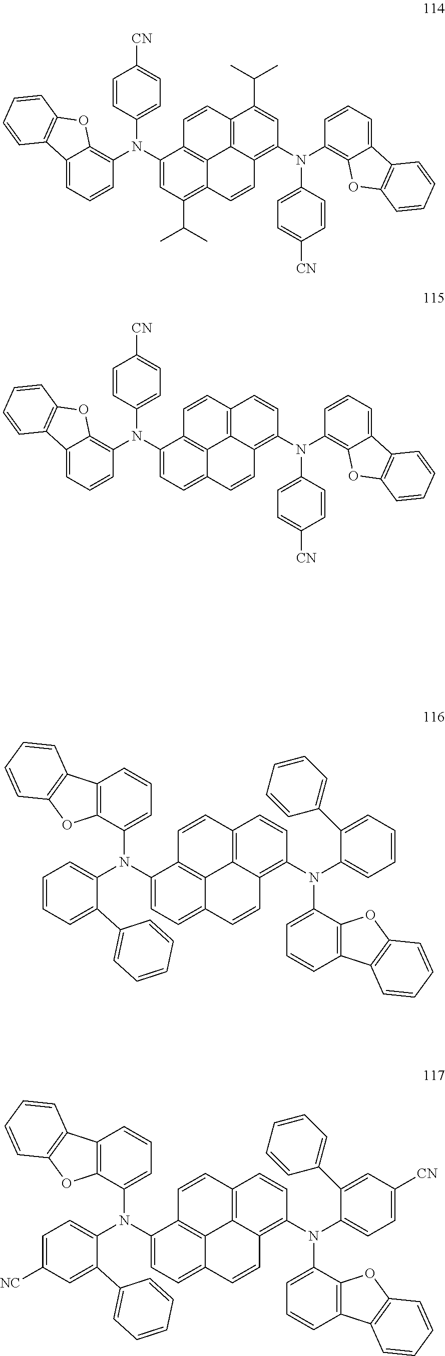 [SMILES: CC(C)c1cc(N(c2ccc(C#N)cc2)c2cccc3c2oc2ccccc23)c2ccc3c(C(C)C)cc(N(c4ccc(C#N)cc4)c4cccc5c4oc4ccccc45)c4ccc1c2c34 ; N#Cc1ccc(N(c2ccc3ccc4c(N(c5ccc(C#N)cc5)c5cccc6c5oc5ccccc56)ccc5ccc2c3c54)c2cccc3c2oc2ccccc23)cc1 ; c1ccc(-c2ccccc2N(c2ccc3ccc4c(N(c5ccccc5-c5ccccc5)c5cccc6c5oc5ccccc56)ccc5ccc2c3c54)c2cccc3c2oc2ccccc23)cc1 ; N#Cc1ccc(N(c2ccc3ccc4c(N(c5ccc(C#N)cc5-c5ccccc5)c5cccc6c5oc5ccccc56)ccc5ccc2c3c54)c2cccc3c2oc2ccccc23)c(-c2ccccc2)c1]

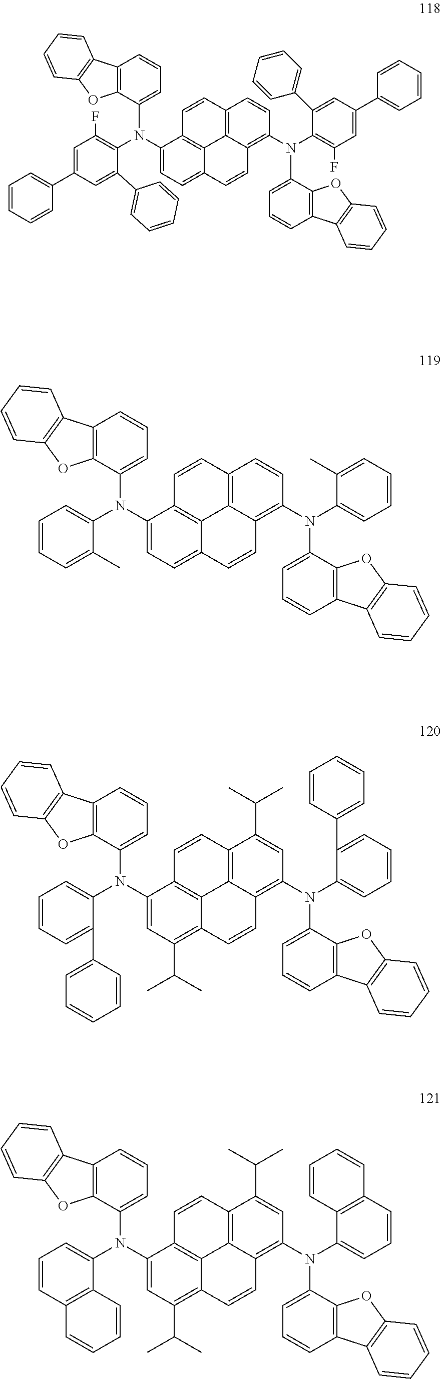 [SMILES: Fc1cc(-c2ccccc2)cc(-c2ccccc2)c1N(c1ccc2ccc3c(N(c4c(F)cc(-c5ccccc5)cc4-c4ccccc4)c4cccc5c4oc4ccccc45)ccc4ccc1c2c43)c1cccc2c1oc1ccccc12 ; Cc1ccccc1N(c1ccc2ccc3c(N(c4ccccc4C)c4cccc5c4oc4ccccc45)ccc4ccc1c2c43)c1cccc2c1oc1ccccc12 ; CC(C)c1cc(N(c2ccccc2-c2ccccc2)c2cccc3c2oc2ccccc23)c2ccc3c(C(C)C)cc(N(c4ccccc4-c4ccccc4)c4cccc5c4oc4ccccc45)c4ccc1c2c34 ; CC(C)c1cc(N(c2cccc3ccccc23)c2cccc3c2oc2ccccc23)c2ccc3c(C(C)C)cc(N(c4cccc5ccccc45)c4cccc5c4oc4ccccc45)c4ccc1c2c34]

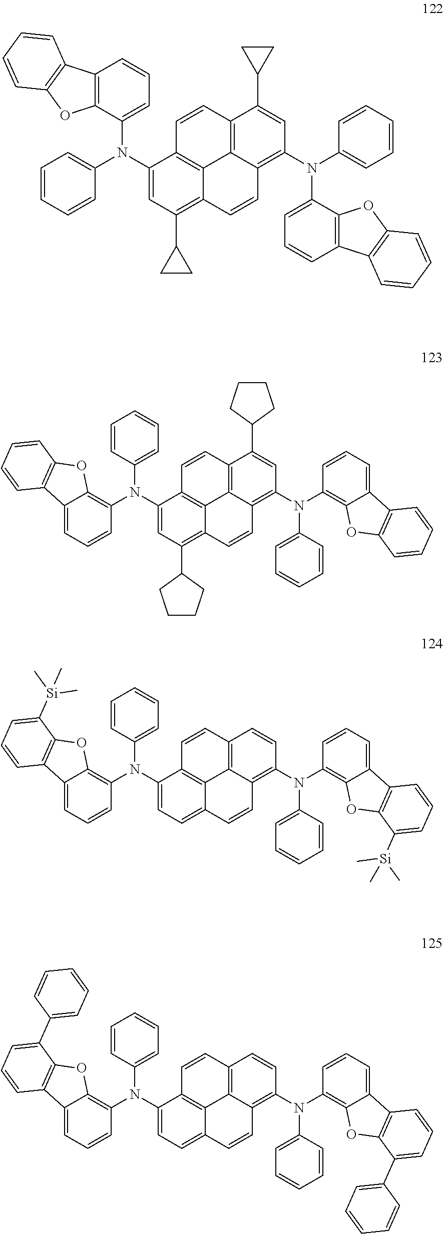 [SMILES: c1ccc(N(c2cc(C3CC3)c3ccc4c(N(c5ccccc5)c5cccc6c5oc5ccccc56)cc(C5CC5)c5ccc2c3c54)c2cccc3c2oc2ccccc23)cc1 ; c1ccc(N(c2cc(C3CCCC3)c3ccc4c(N(c5ccccc5)c5cccc6c5oc5ccccc56)cc(C5CCCC5)c5ccc2c3c54)c2cccc3c2oc2ccccc23)cc1 ; C[Si](C)(C)c1cccc2c1oc1c(N(c3ccccc3)c3ccc4ccc5c(N(c6ccccc6)c6cccc7c6oc6c([Si](C)(C)C)cccc67)ccc6ccc3c4c65)cccc12 ; c1ccc(-c2cccc3c2oc2c(N(c4ccccc4)c4ccc5ccc6c(N(c7ccccc7)c7cccc8c7oc7c(-c9ccccc9)cccc78)ccc7ccc4c5c76)cccc23)cc1]

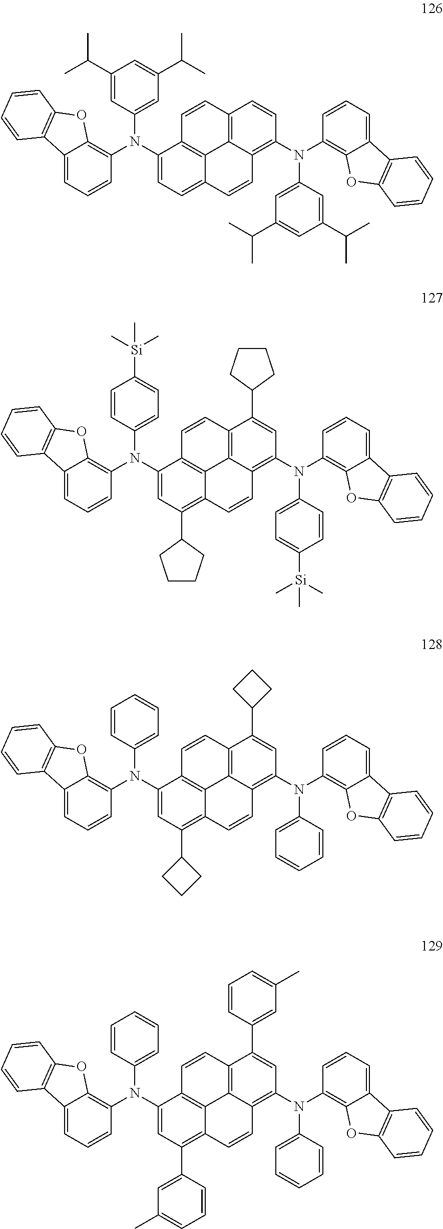 [SMILES: CC(C)c1cc(C(C)C)cc(N(c2ccc3ccc4c(N(c5cc(C(C)C)cc(C(C)C)c5)c5cccc6c5oc5ccccc56)ccc5ccc2c3c54)c2cccc3c2oc2ccccc23)c1 ; C[Si](C)(C)c1ccc(N(c2cc(C3CCCC3)c3ccc4c(N(c5ccc([Si](C)(C)C)cc5)c5cccc6c5oc5ccccc56)cc(C5CCCC5)c5ccc2c3c54)c2cccc3c2oc2ccccc23)cc1 ; c1ccc(N(c2cc(C3CCC3)c3ccc4c(N(c5ccccc5)c5cccc6c5oc5ccccc56)cc(C5CCC5)c5ccc2c3c54)c2cccc3c2oc2ccccc23)cc1 ; Cc1cccc(-c2cc(N(c3ccccc3)c3cccc4c3oc3ccccc34)c3ccc4c(-c5cccc(C)c5)cc(N(c5ccccc5)c5cccc6c5oc5ccccc56)c5ccc2c3c45)c1]

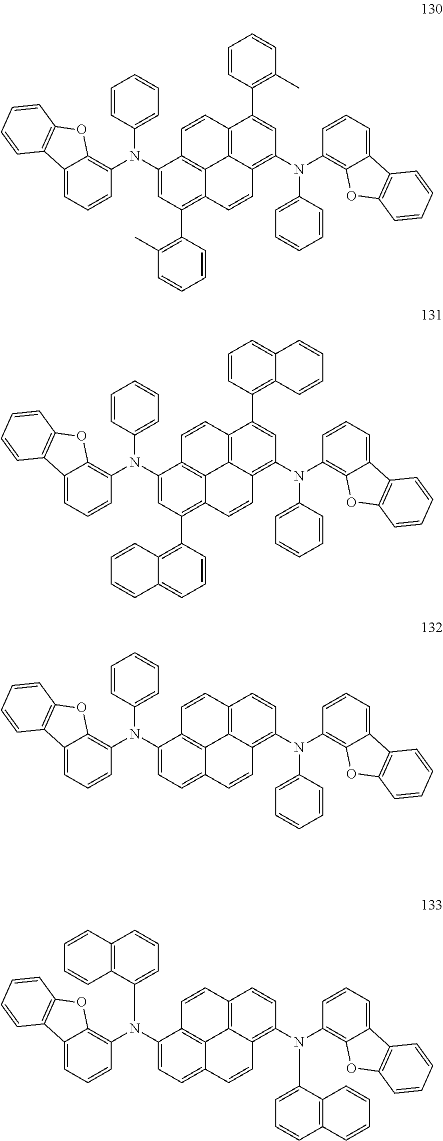 [SMILES: Cc1ccccc1-c1cc(N(c2ccccc2)c2cccc3c2oc2ccccc23)c2ccc3c(-c4ccccc4C)cc(N(c4ccccc4)c4cccc5c4oc4ccccc45)c4ccc1c2c34 ; c1ccc(N(c2cc(-c3cccc4ccccc34)c3ccc4c(N(c5ccccc5)c5cccc6c5oc5ccccc56)cc(-c5cccc6ccccc56)c5ccc2c3c54)c2cccc3c2oc2ccccc23)cc1 ; c1ccc(N(c2ccc3ccc4c(N(c5ccccc5)c5cccc6c5oc5ccccc56)ccc5ccc2c3c54)c2cccc3c2oc2ccccc23)cc1 ; c1ccc2c(N(c3ccc4ccc5c(N(c6cccc7ccccc67)c6cccc7c6oc6ccccc67)ccc6ccc3c4c65)c3cccc4c3oc3ccccc34)cccc2c1]

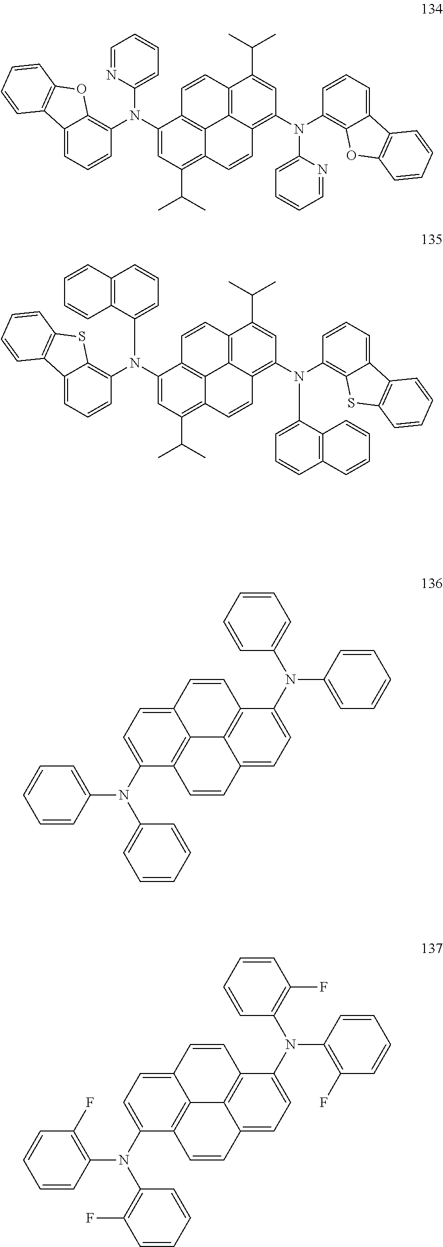 [SMILES: CC(C)c1cc(N(c2ccccn2)c2cccc3c2oc2ccccc23)c2ccc3c(C(C)C)cc(N(c4ccccn4)c4cccc5c4oc4ccccc45)c4ccc1c2c34 ; CC(C)c1cc(N(c2cccc3ccccc23)c2cccc3c2sc2ccccc23)c2ccc3c(C(C)C)cc(N(c4cccc5ccccc45)c4cccc5c4sc4ccccc45)c4ccc1c2c34 ; c1ccc(N(c2ccccc2)c2ccc3ccc4c(N(c5ccccc5)c5ccccc5)ccc5ccc2c3c54)cc1 ; Fc1ccccc1N(c1ccccc1F)c1ccc2ccc3c(N(c4ccccc4F)c4ccccc4F)ccc4ccc1c2c43]

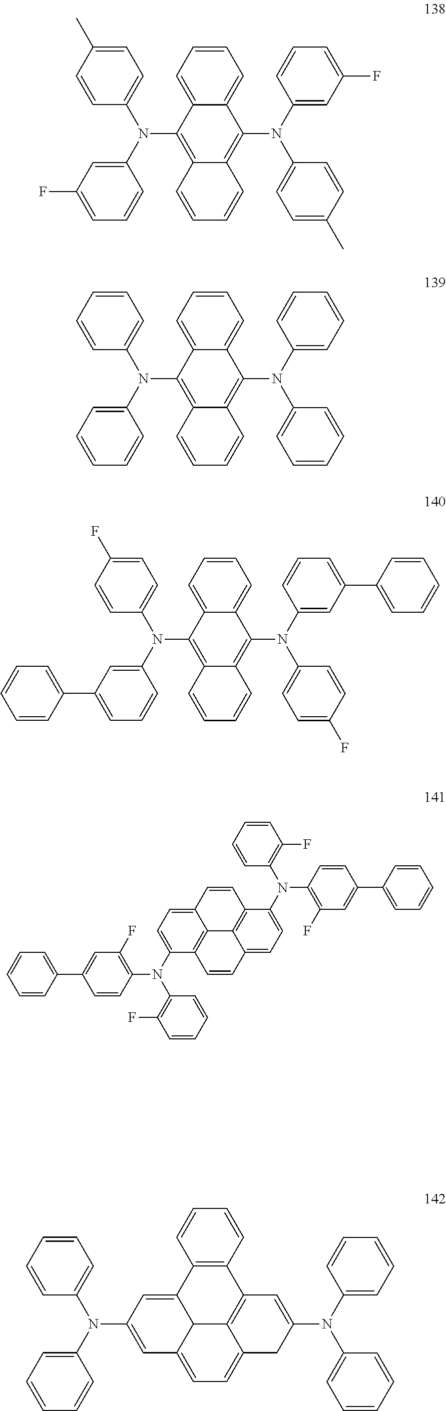

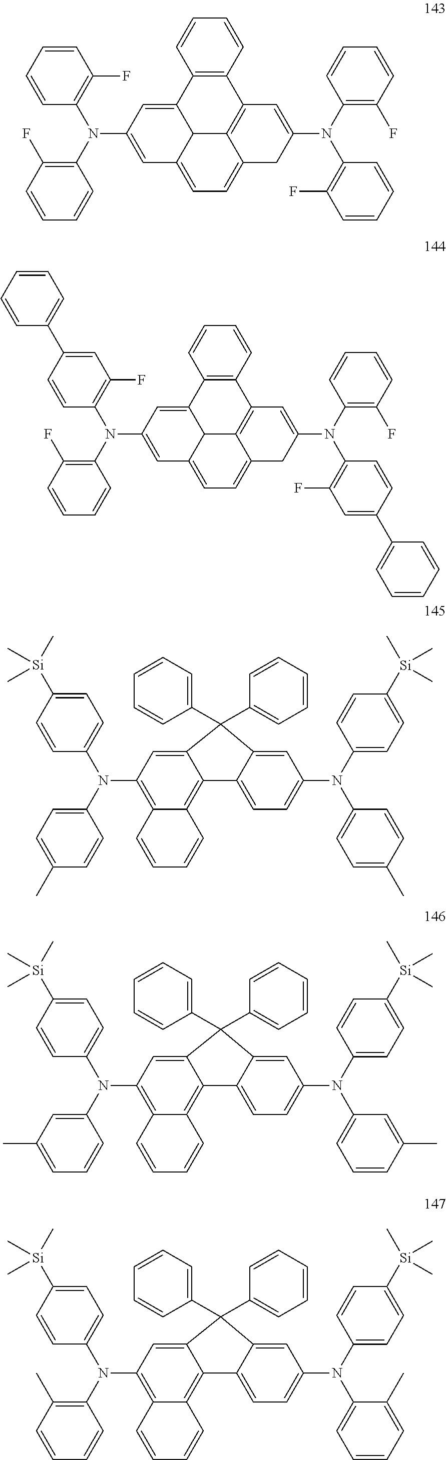

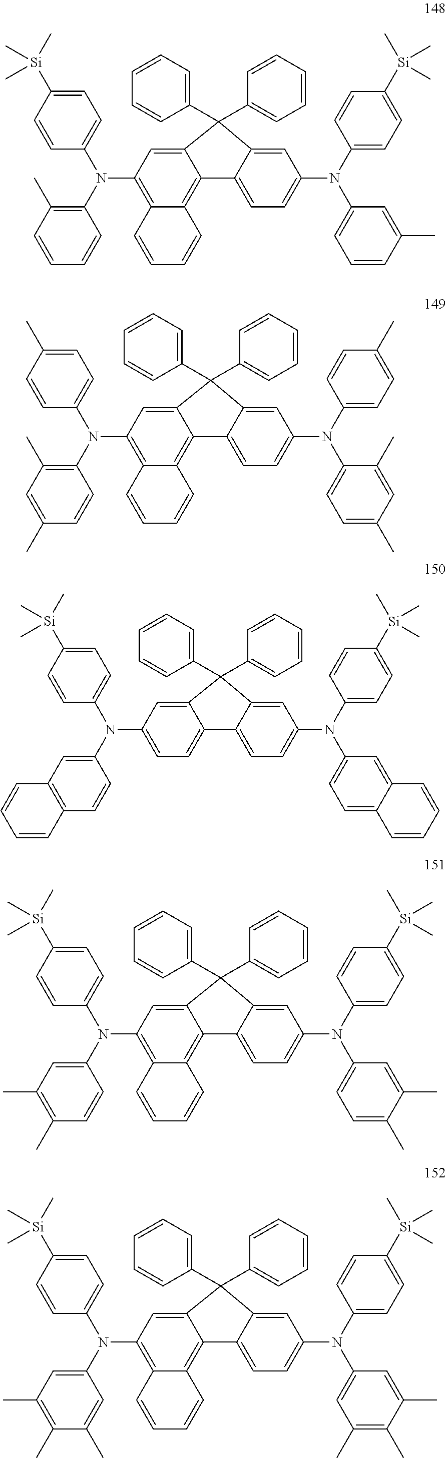

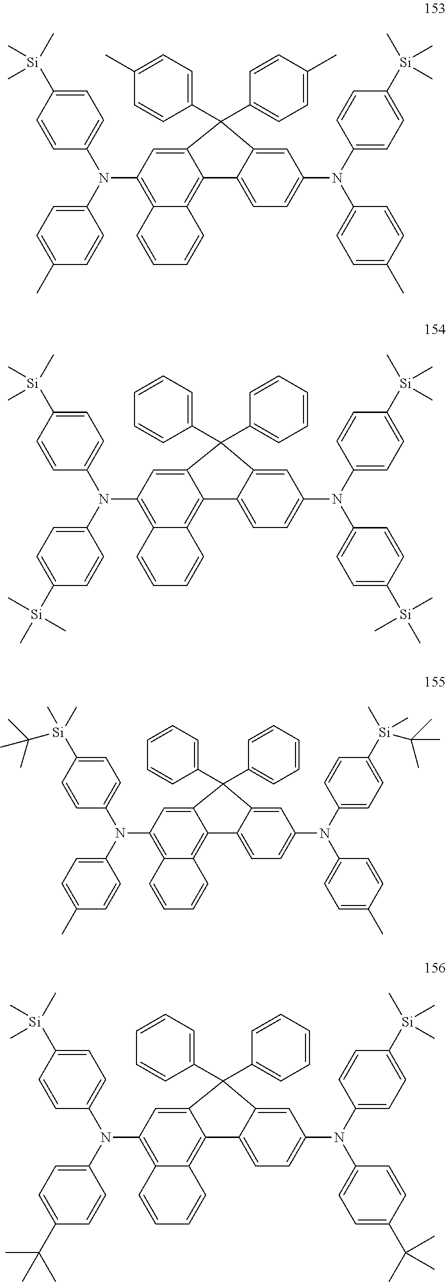

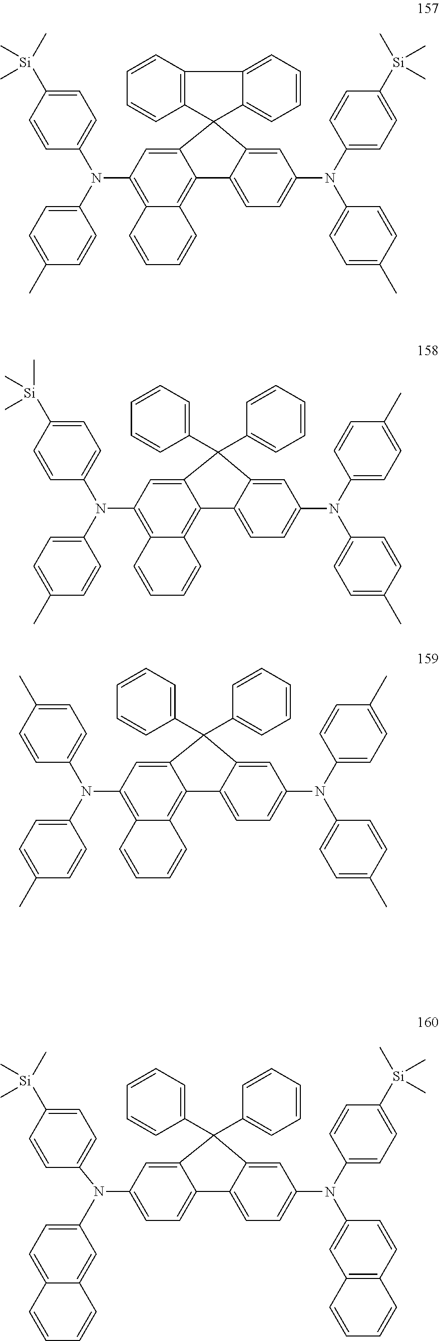

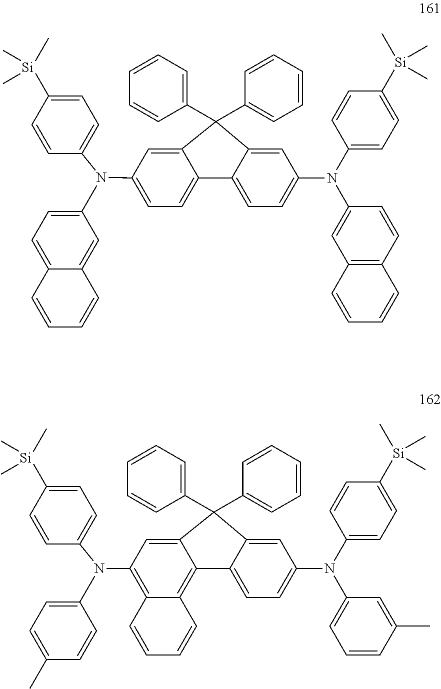

14. The organic light-emitting device of claim 1, wherein
the organic layer comprises a hole injection layer, a hole transport layer, or a functional layer having a hole injection capability and a hole transportation capability, and
the hole injection layer, the hole transport layer, or the functional layer having a hole injection capability and a hole transportation capability comprises a compound represented by Formula 300 below or a compound represented by Formula 350 below: 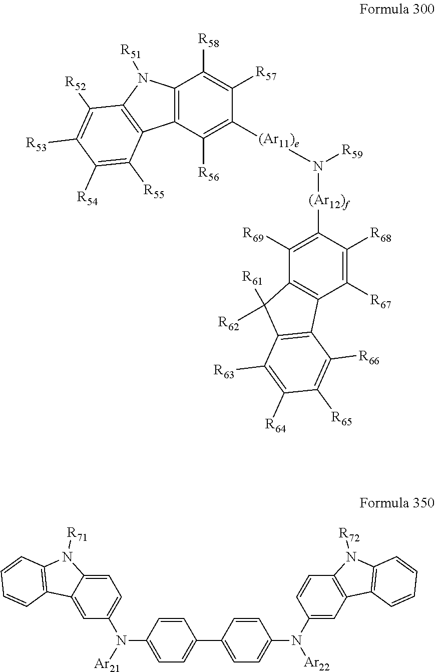
wherein in Formulae 300 and 350,
Ar₁₁, Ar₁₂ are each independently a substituted or unsubstituted C₆-C₆₀ arylene group;
Ar₂₁ and Ar₂₂ are each independently a substituted or unsubstituted C₆-C₆₀ aryl group;
e and f are each independently an integer of 0 to 5;
R₅₁-R₅₈, R₆₁-R₆₉ and R₇₁ and R₇₂ are each independently a hydrogen atom, a deuterium atom, a halogen group, a hydroxyl group, a cyano group, a nitro group, an amino group, an amidino group, a hydrazine, a hydrazone, a carboxylic group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₆-C₆₀ aryl group, a substituted or unsubstituted C₆-C₆₀ aryloxy, or a substituted or unsubstituted C₆-C₆₀ arylthio group; and
R₅₉ is a phenyl group; a naphthyl group; an anthryl group; a biphenyl group; a pyridyl group; or a phenyl group, a naphthyl group, an anthryl group, a biphenyl group, or a pyridyl group, each substituted with at least one selected from a deuterium atom, a halogen atom, a hydroxyl group, a cyano group, a nitro group, an amino group, an amidino group, a hydrazine, a hydrazone, a carboxylic group or a salt thereof, a sulfonic acid group or a salt thereof, a phosphoric acid group or a salt thereof, a substituted or unsubstituted C₁-C₂₀ alkyl group, or a substituted or unsubstituted C₁-C₂₀ alkoxy group.

15. The organic light-emitting device of claim 1, wherein
the organic layer comprises an emission layer, and a hole injection layer, a hole transport layer, or a functional layer having a hole injection capability and a hole transportation capability, and
the emission layer comprises a red layer, a green layer, a blue layer, and a white layer, wherein any one of the red, green, blue, and white layers comprises a phosphorescent compound.

16. The organic light-emitting device of claim 15, wherein
the hole injection layer, the hole transport layer, or the functional layer having a hole injection capability and a hole transport capability comprises a charge-generation material.

17. The organic light-emitting device of claim 16, wherein
the charge-generation material is a p-dopant, and the p-dopant is a quinone derivative, a metal oxide, or a cyano group-containing compound.

18. The organic light-emitting device of claim 1, wherein
the organic layer comprises an electron injection layer, an electron transport layer, or a functional layer having an electron injection capability and an electron transportation capability, and
the electron injection layer, the electron transport layer, or the functional layer having an electron injection capability and an electron transportation capability comprises a metal complex.

19. The organic light-emitting device of claim 1, wherein
the organic layer is formed by a wet process using the compound represented by Formula 1 or 2 in the organic layer.

20. A flat display apparatus comprising the organic light-emitting device of claim 1, wherein the first electrode of the organic light-emitting device is electrically connected to a source electrode or a drain electrode of a thin film transistor.
